(19) United States
(12) Patent Application Publication
(10) Pub. No.: US 2024/0237383 A1
(43) Pub. Date: Jul. 11, 2024

(54) ORGANIC ELECTROLUMINESCENT DEVICE

(71) Applicant: SFC CO., LTD., Cheongiu-si (KR)

(72) Inventors: Soon Wook Cha, Cheongju-si (KR); Ji Won Lee, Cheongju-si (KR); Tae Jung Yu, Cheongju-si (KR); Yong Woon Yang, Cheongju-si (KR)

(21) Appl. No.: 18/545,697

(22) Filed: Dec. 19, 2023

(30) Foreign Application Priority Data
Dec. 21, 2022 (KR) 10-2022-0180225

(51) Int. Cl. H10K 50/12; H10K 50/15; H10K 50/16; H10K 50/17; H10K 71/15; H10K 85/60; H10K 101/00

(52) U.S. Cl. CPC H10K 50/12; H10K 85/615; H10K 85/626; H10K 85/6574; H10K 50/15; H10K 50/16; H10K 50/171; H10K 71/15; H10K 2101/90

(57) ABSTRACT

An organic electroluminescent device including a first electrode, a second electrode, and an organic layer formed between the first electrode and the second electrode. The organic layer includes a light emitting layer formed using a solution containing an organic electroluminescent material and a solvent. The organic electroluminescent material includes a host and a dopant, and the host is one or more compounds represented by [Formula A] below.

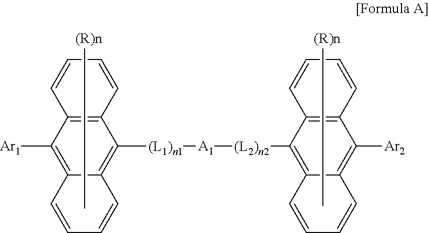

### TECHNICAL FIELD

The present disclosure relates to an organic electroluminescent device, and more specifically, to an organic electroluminescent device having improved operating characteristics of the device such as luminous efficiency, driving voltage, and lifespan by comprising an organic electroluminescent material with high solubility in solvents.

### BACKGROUND

Organic electroluminescent devices are display devices that use the self-luminescence phenomenon, and have advantages such as a large viewing angle, being thin and simple compared to liquid crystal displays, fast response speed, etc. so that they are being applied as full-color displays or lighting.

In general, an organic light emission phenomenon refers to a phenomenon that converts electrical energy into light energy using organic materials. Organic electroluminescent devices that utilize the organic light emission phenomenon usually have a structure comprising an anode, a cathode, and an organic layer between them. Here, the organic layer is often composed of a multilayer structure consisting of different materials in order to increase the luminous efficiency and stability of the organic electroluminescent devices. For example, it may be composed of a hole injection layer, a hole transport layer, a light emitting layer, an electron transport layer, an electron injection layer, etc. In the structure of such organic electroluminescent devices, when a voltage is applied between two electrodes, holes are injected from the anode and electrons from the cathode into the organic layer, and when the injected holes and electrons meet, an exciton is formed, and this exciton glows when it falls back to the ground state. Such organic electroluminescent devices are known to have characteristics such as self-luminescence, high brightness, high luminous efficiency, low driving voltage, wide viewing angle, high contrast, and high-speed response.

Currently, displays are becoming increasingly larger. When manufacturing a large display using a deposition process, there are disadvantages such as lower production yield and increased investment costs as a substrate becomes larger. Additionally, since the deposition process evaporates single-molecule materials under vacuum conditions and deposits them on the substrate, there is a limitation in that materials with a high glass transition temperature should be used so that decomposition does not occur at high evaporation temperatures.

Meanwhile, when a large display is manufactured by dissolving organic electroluminescent materials in a solvent to prepare a solution and then applying the solution on a substrate, there are advantages in that the process cost is lower than the deposition process, and the process steps are relatively simple. However, since the organic electroluminescent materials often have low solubility in solvents, it is difficult to secure the luminous efficiency, brightness, power efficiency, lifespan, and thermal stability of the device.

Therefore, there is a continuous need for the development of organic electroluminescent materials that can improve the luminous efficiency, brightness, power efficiency, lifespan, and thermal stability of the device while having high solubility in solvents.

### SUMMARY

### Technical Problem

The problem to be solved by the present disclosure is to provide an organic electroluminescent device having a lower driving voltage, improved luminous efficiency, and improved lifespan characteristics by using an organic electroluminescent material with high solubility in solvents.

The problem to be solved by the present disclosure is not limited to the problems mentioned above, and other problems not mentioned can be clearly understood by those skilled in the art from the description below.

### Technical Solution

[1] An organic electroluminescent device according to the present disclosure is an organic electroluminescent device comprising a first electrode, a second electrode, and an organic layer formed between the first electrode and the second electrode, wherein the organic layer comprises a light emitting layer formed using a solution containing an organic electroluminescent material and a solvent, the organic electroluminescent material comprises a host and a dopant, and the host may be one or more compounds represented by [Formula A] below:

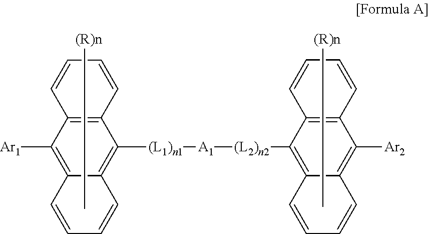

In [Formula A], L₁ to L₂ are the same as or different from each other, and each independently selected from the group consisting of a substituted or unsubstituted alkylene group having 1 to 20 carbon atoms, a substituted or unsubstituted arylene group having 6 to 30 carbon atoms, and a substituted or unsubstituted heteroarylene group having 3 to 30 carbon atoms,

R is the same as or different from each other, and each independently selected from the group consisting of a hydrogen atom, a deuterium atom, a substituted or unsubstituted alkyl group having 1 to 30 carbon atoms, a substituted or unsubstituted alkenyl group having 2 to 30 carbon atoms, a substituted or unsubstituted cycloalkyl group having 3 to 30 carbon atoms, a substituted or unsubstituted cycloalkenyl group having 5 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 6 to 30 carbon atoms, a substituted or unsubstituted alkylamine group having 1 to 30 carbon atoms, a substituted or unsubstituted arylamine group having 6 to 30 carbon atoms, a substituted or unsubstituted aryl group having 6 to 50 carbon atoms, a substituted or unsubstituted heteroaryl group having 3 to 50 carbon atoms, a substituted or unsubstituted alkylsilyl group having 1 to 30 carbon atoms, and a substituted or unsubstituted arylsilyl group having 6 to 30 carbon atoms,

Ar₁ and Ar₂ are the same as or different from each other, and each independently selected from the group consisting of a substituted or unsubstituted alkyl group having 1 to 30 carbon atoms, a substituted or unsubstituted cycloalkyl group having 3 to 30 carbon atoms, a substituted or unsubstituted aryl group having 6 to 50 carbon atoms, and a substituted or unsubstituted heteroaryl group having 3 to 50 carbon atoms, provided that at least one of Ar₁ and Ar₂ is not a substituted or unsubstituted aryl group having 6 to 50 carbon atoms,
n is an integer of 0 to 8, but when n is 2 or more, respective R is the same as or different from each other,
n1 and n2 are each independently an integer of 1 to 3, and
A₁ is a substituted or unsubstituted aryl group having 10 to 30 carbon atoms.
[2] In [1] above,
A₁ may be any one selected from groups represented by [Formula A-1] to [Formula A-4] below:

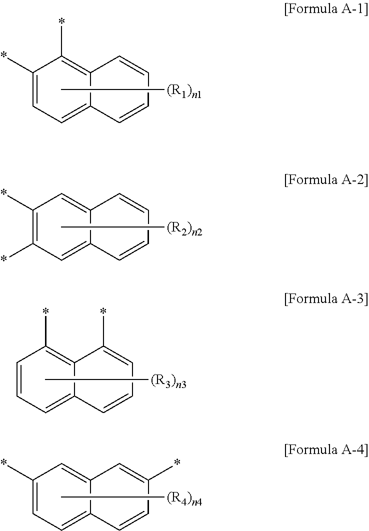

In [Formula A-1] to [Formula A-4],

R₁ to R₄ are the same as or different from each other, and each independently selected from the group consisting of a deuterium atom, a substituted or unsubstituted alkyl group having 1 to 30 carbon atoms, a substituted or unsubstituted alkenyl group having 2 to 30 carbon atoms, a substituted or unsubstituted cycloalkyl group having 3 to 30 carbon atoms, a substituted or unsubstituted cycloalkenyl group having 5 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 6 to 30 carbon atoms, a substituted or unsubstituted alkylamine group having 1 to 30 carbon atoms, a substituted or unsubstituted arylamine group having 6 to 30 carbon atoms, a substituted or unsubstituted aryl group having 6 to 50 carbon atoms, a substituted or unsubstituted heteroaryl group having 3 to 50 carbon atoms, a substituted or unsubstituted alkylsilyl group having 1 to 30 carbon atoms, and a substituted or unsubstituted arylsilyl group having 6 to 30 carbon atoms, and
n1 to n4 are integers of 0 to 6, but when n is 2 or more, respective R₁ to R₄ are the same as or different from each other.
[3] In [1] and [2] above,

At least one of Ar₁ and Ar₂ may be selected from groups represented by [Formula Ar-1] or [Formula Ar-2] below:

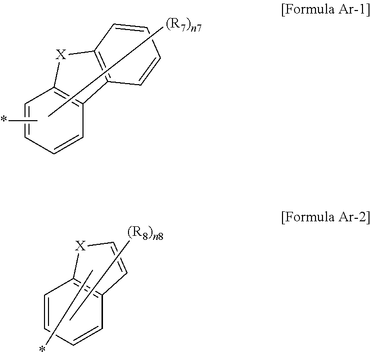

In [Formula Ar-1] and [Formula Ar-2],

X is selected from the group consisting of O, S, NR′, and Si(R′)₂,

R₇, R₈, and R′ are the same as or different from each other, and each independently selected from the group consisting of a hydrogen atom, a deuterium atom, a substituted or unsubstituted alkyl group having 1 to 30 carbon atoms, a substituted or unsubstituted alkenyl group having 2 to 30 carbon atoms, a substituted or unsubstituted cycloalkyl group having 3 to 30 carbon atoms, a substituted or unsubstituted cycloalkenyl group having 5 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 6 to 30 carbon atoms, a substituted or unsubstituted alkylamine group having 1 to 30 carbon atoms, a substituted or unsubstituted arylamine group having 6 to 30 carbon atoms, a substituted or unsubstituted aryl group having 6 to 50 carbon atoms, a substituted or unsubstituted heteroaryl group having 3 to 50 carbon atoms, a substituted or unsubstituted alkylsilyl group having 1 to 30 carbon atoms, and a substituted or unsubstituted arylsilyl group having 6 to 30 carbon atoms,
n7 is an integer of 0 to 7, and n8 is an integer of 0 to 5, but when n7 and n8 are 2 or more, respective R₇ and R₈ are the same as or different from each other.
[4] In [1] to [3] above,
L₁ and L₂ may each independently be a substituted or unsubstituted phenylene group.
[5] In [1] to [4] above,

The compound represented by [Formula A] above may be substituted with at least one deuterium.
[6] In [5] above,

The compound represented by [Formula A] above may have a degree of deuteration of 30% or more.
[7] In [1] to [6] above,

The compound represented by [Formula A] above may have a molecular weight of 650 or more.
[8] In [1] to [7] above,

The solvent may comprises at least one of a chlorine-based solvent, an ether-based solvent, an aromatic solvent, an aliphatic solvent, a ketone-based solvent, an ester-based solvent, an alcohol-based solvent, an amide-based solvent, and a benzoate-based solvent.
[9] In [1] to [8] above,

The host may be dissolved in an amount of 1% by weight or more in the solvent.
[10] In [1] to [9] above,

The host may be represented by any one of [1] to [36] below:

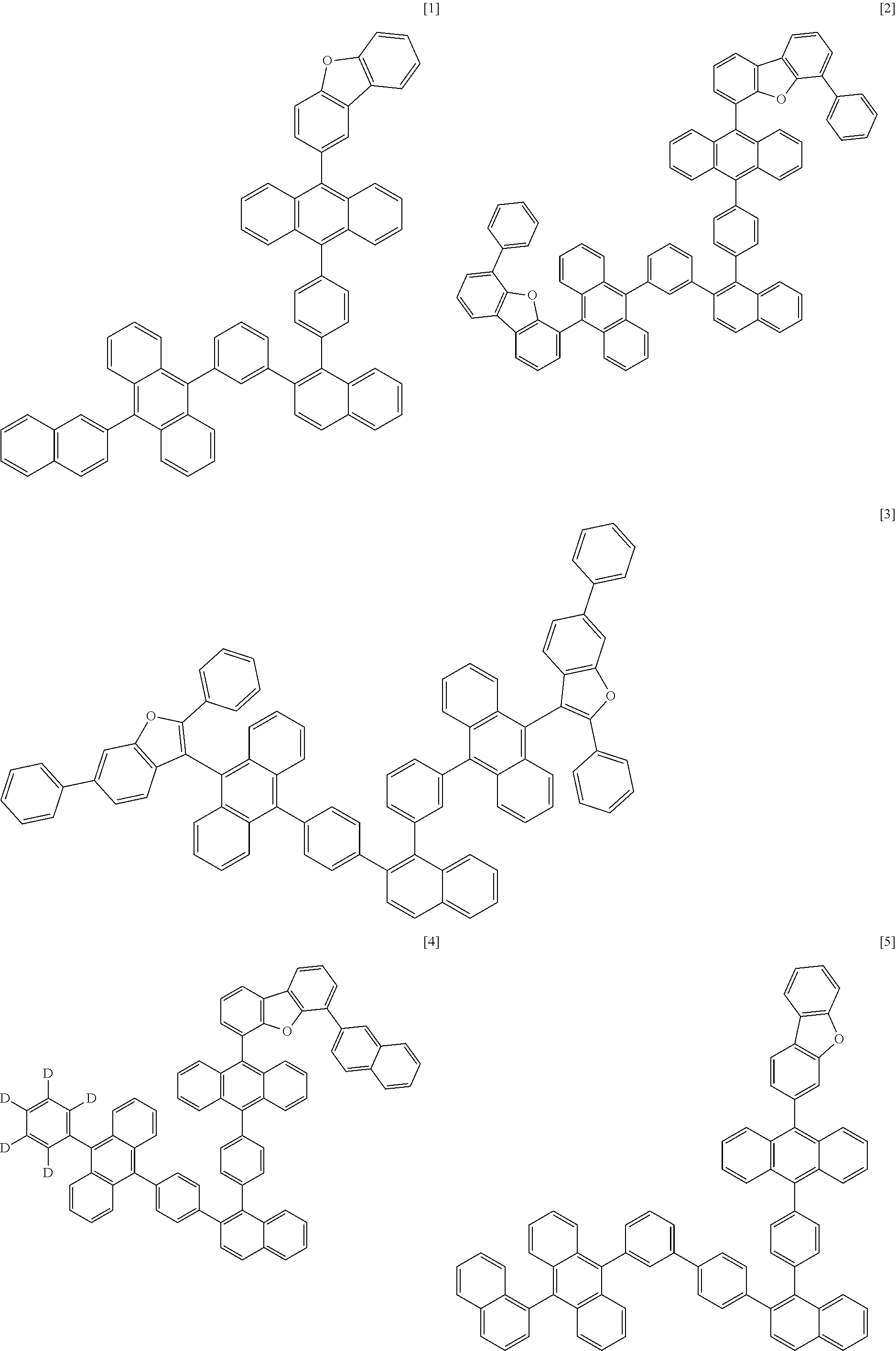

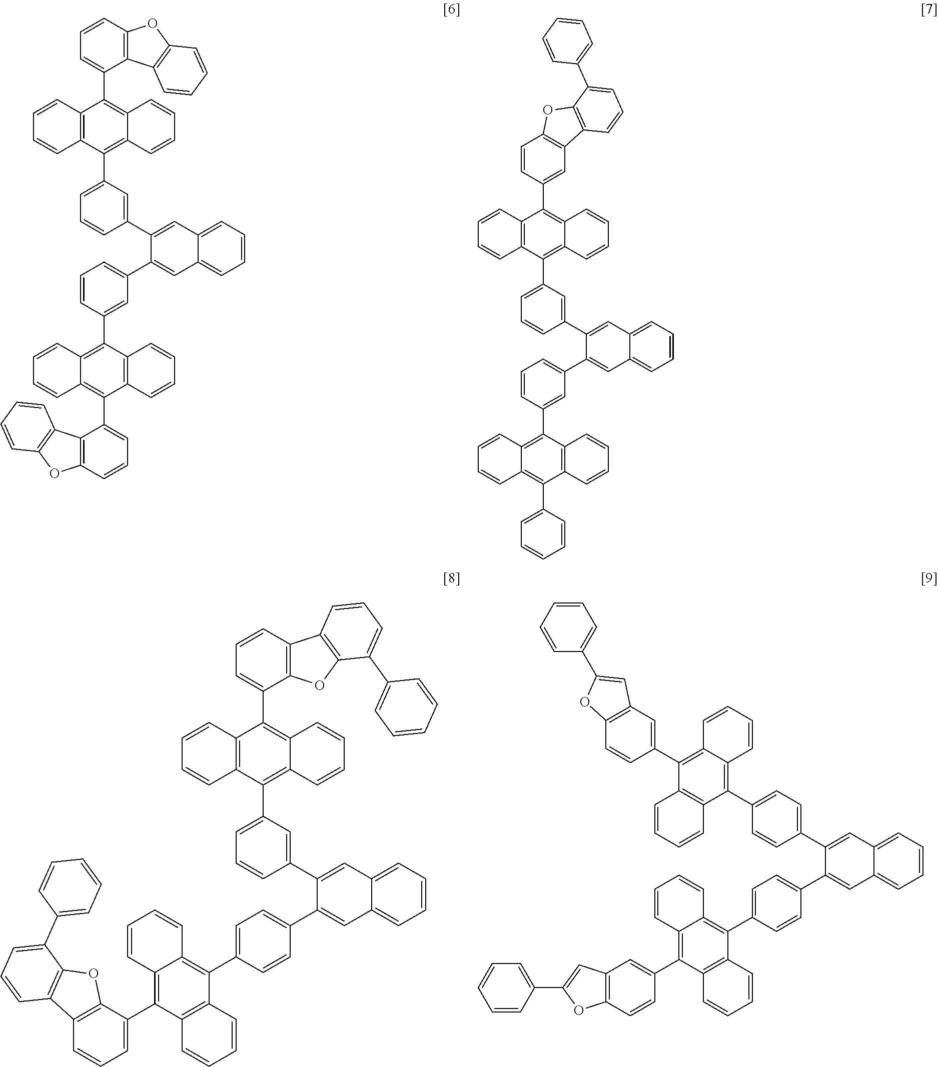

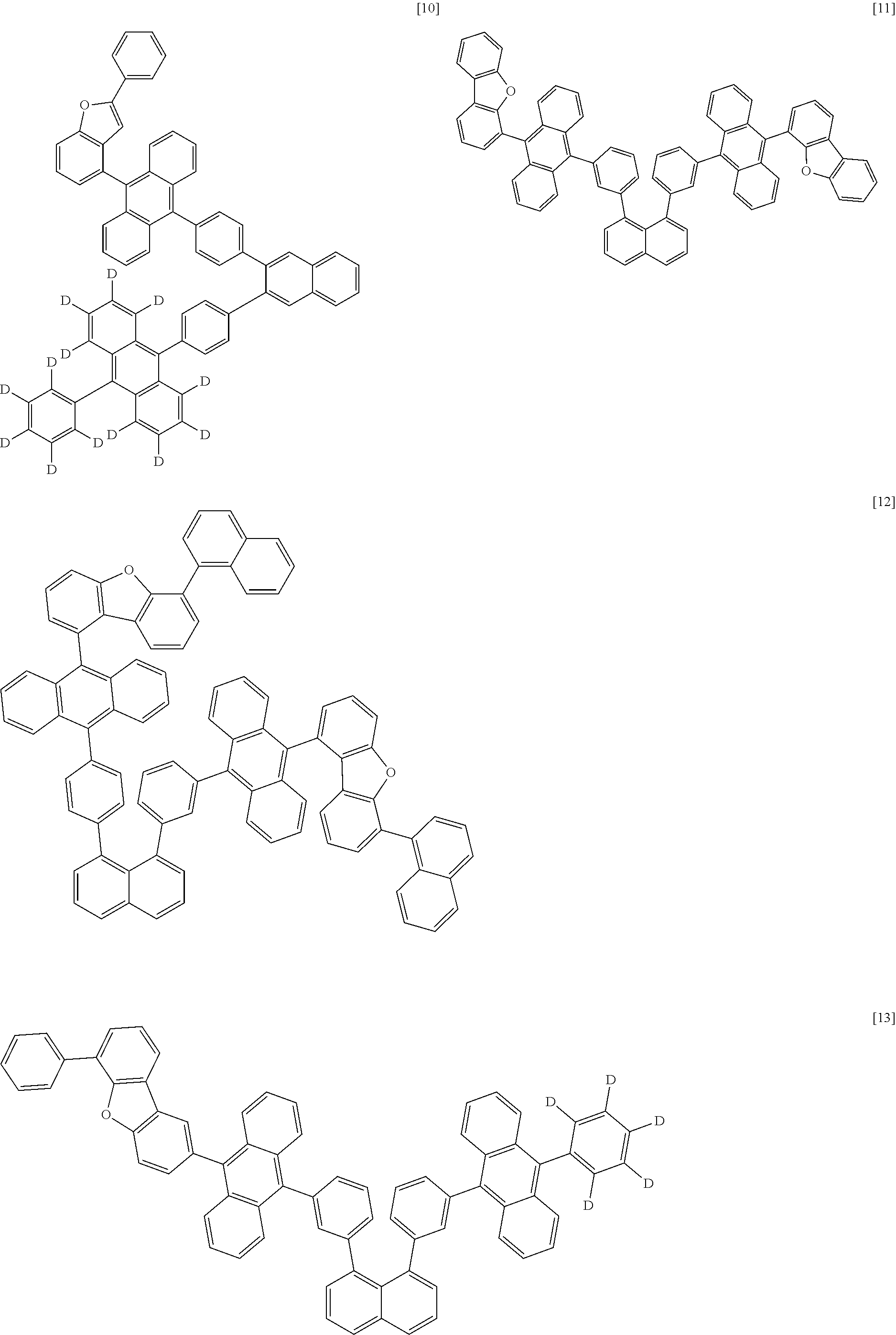

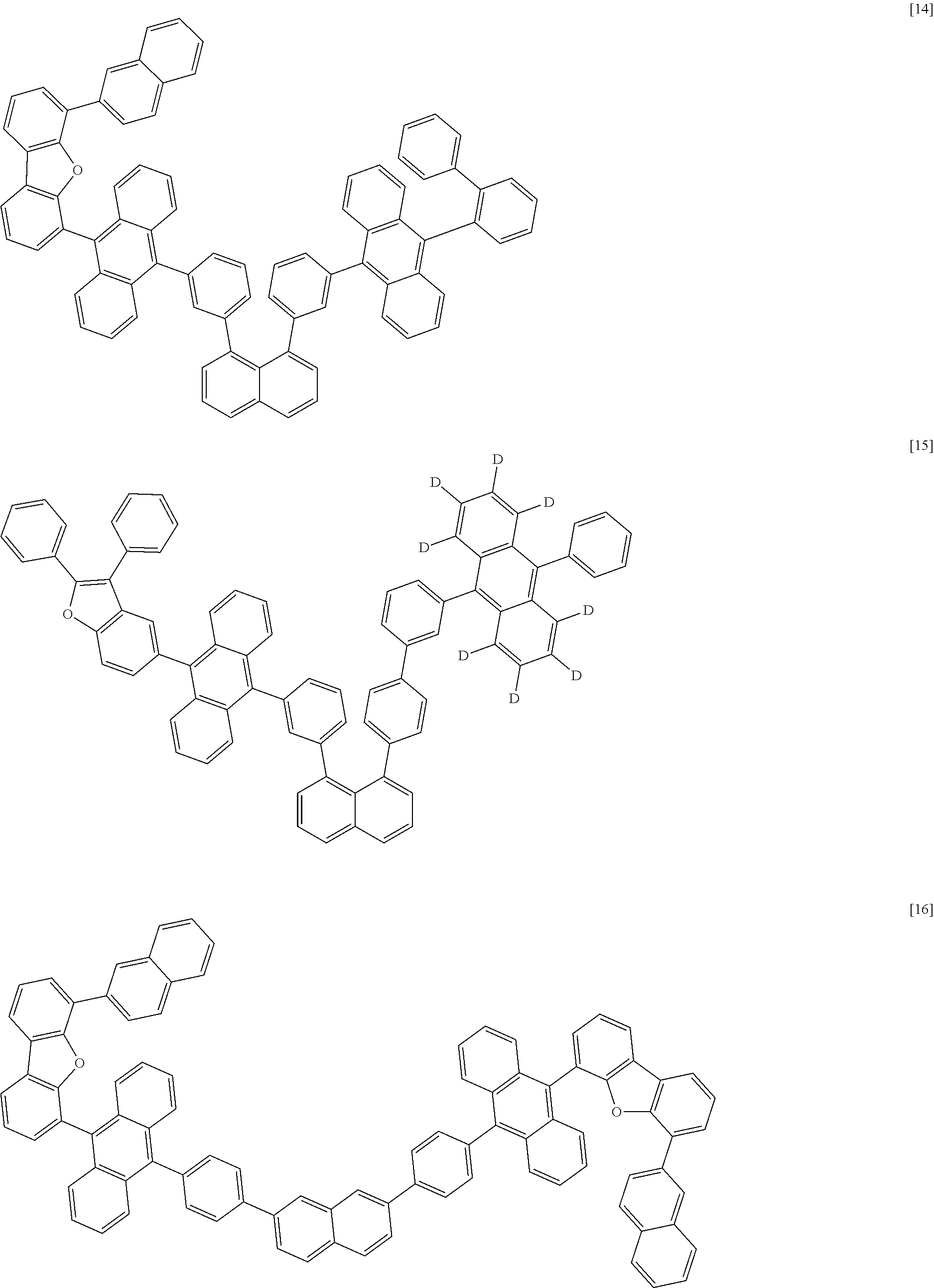

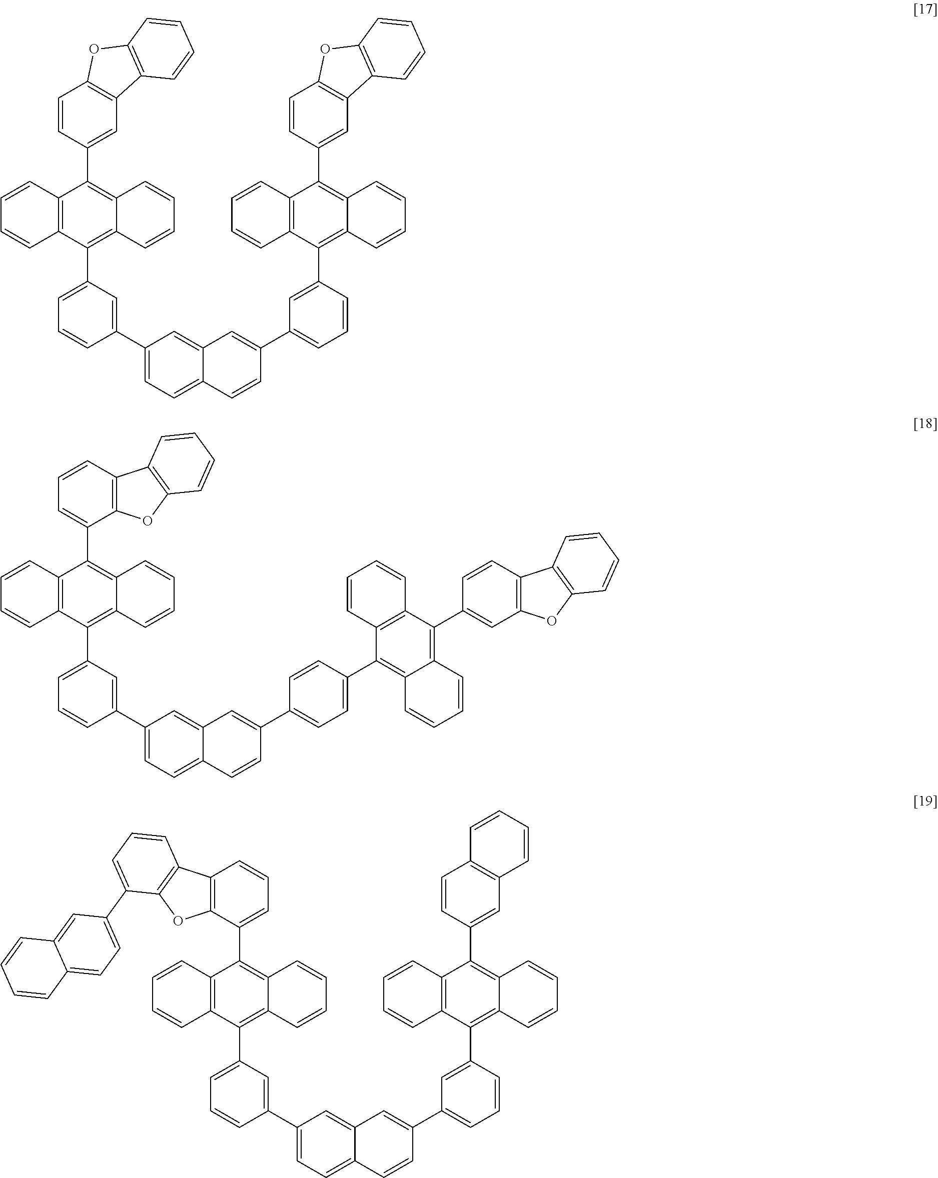

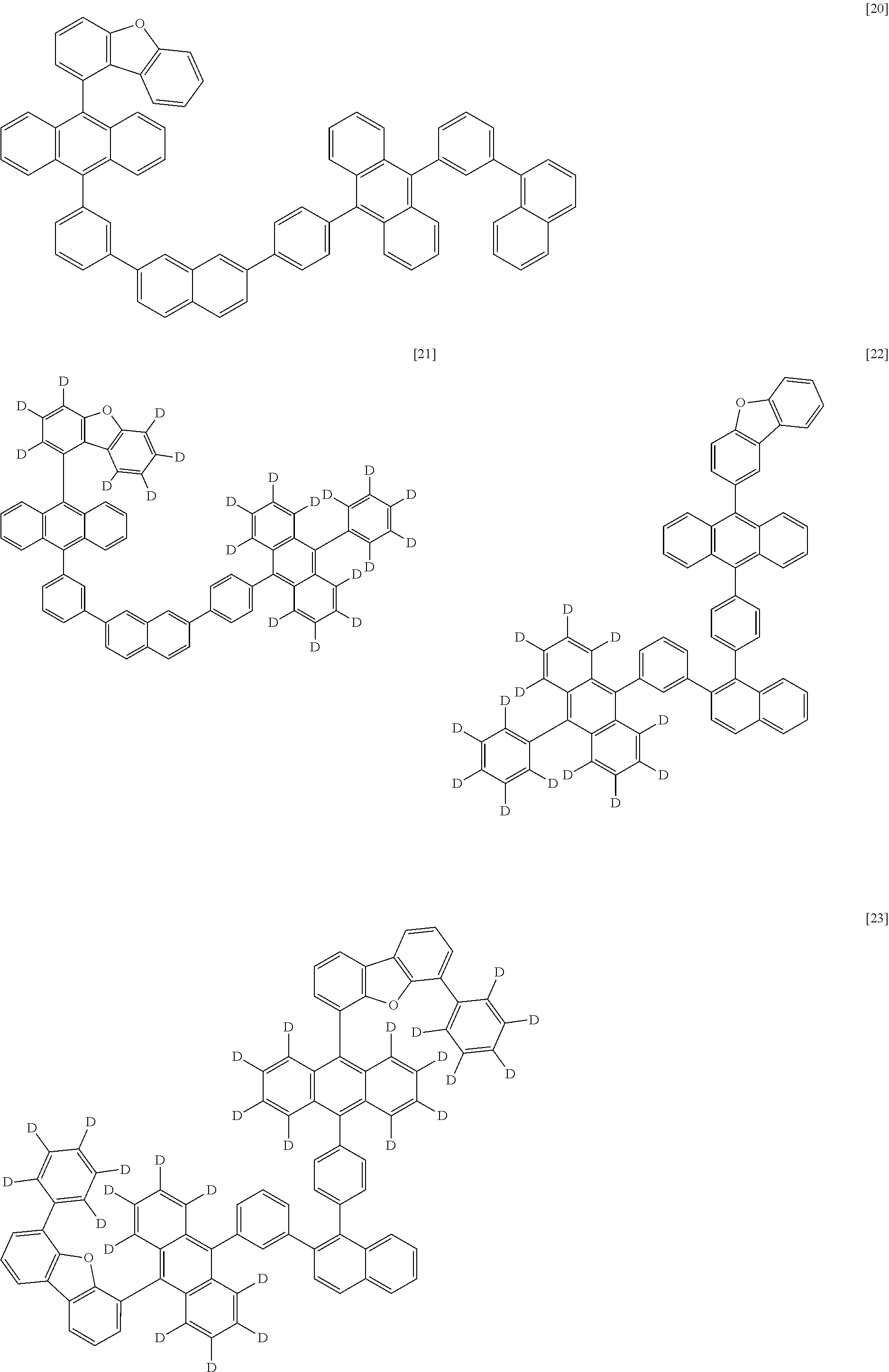

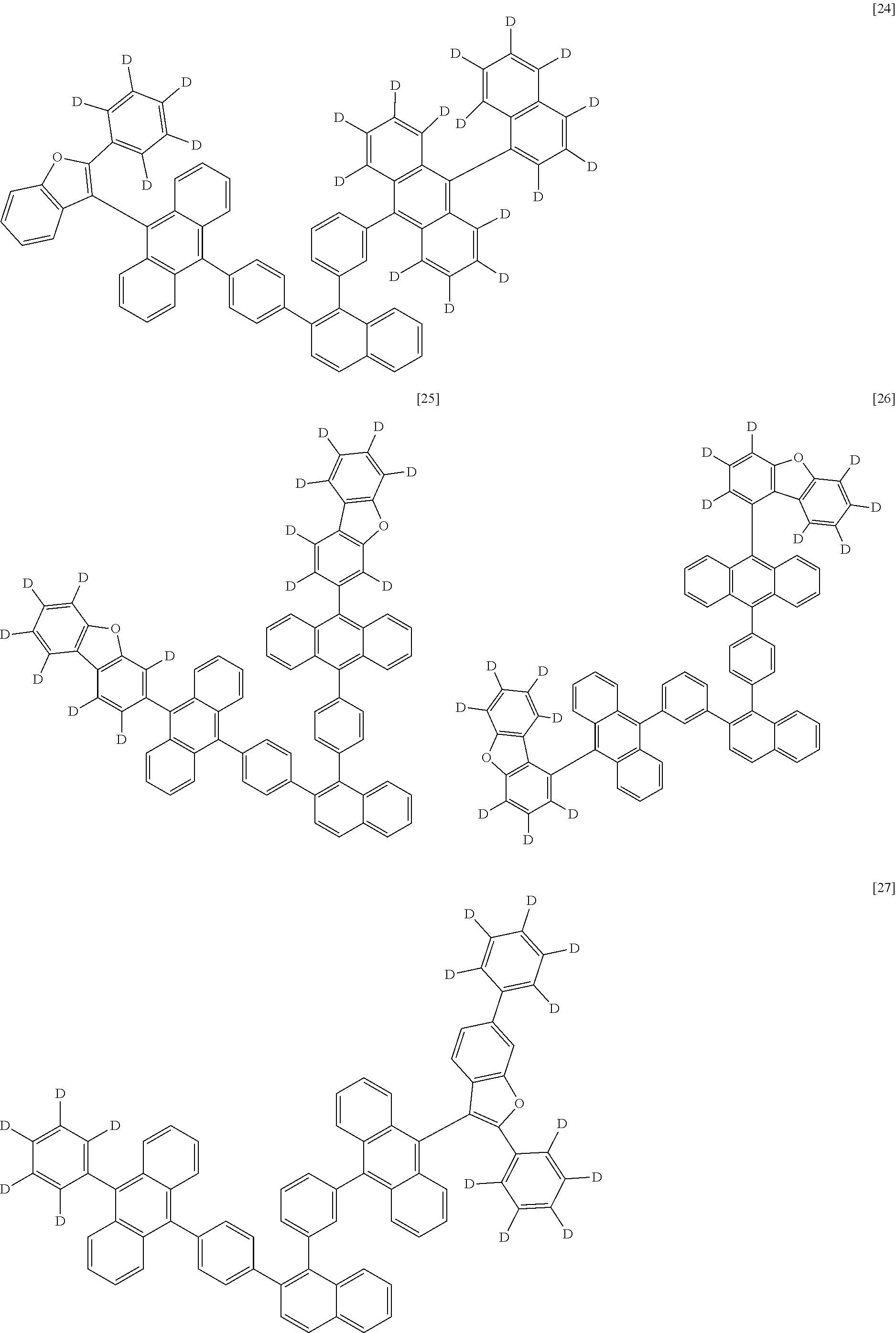

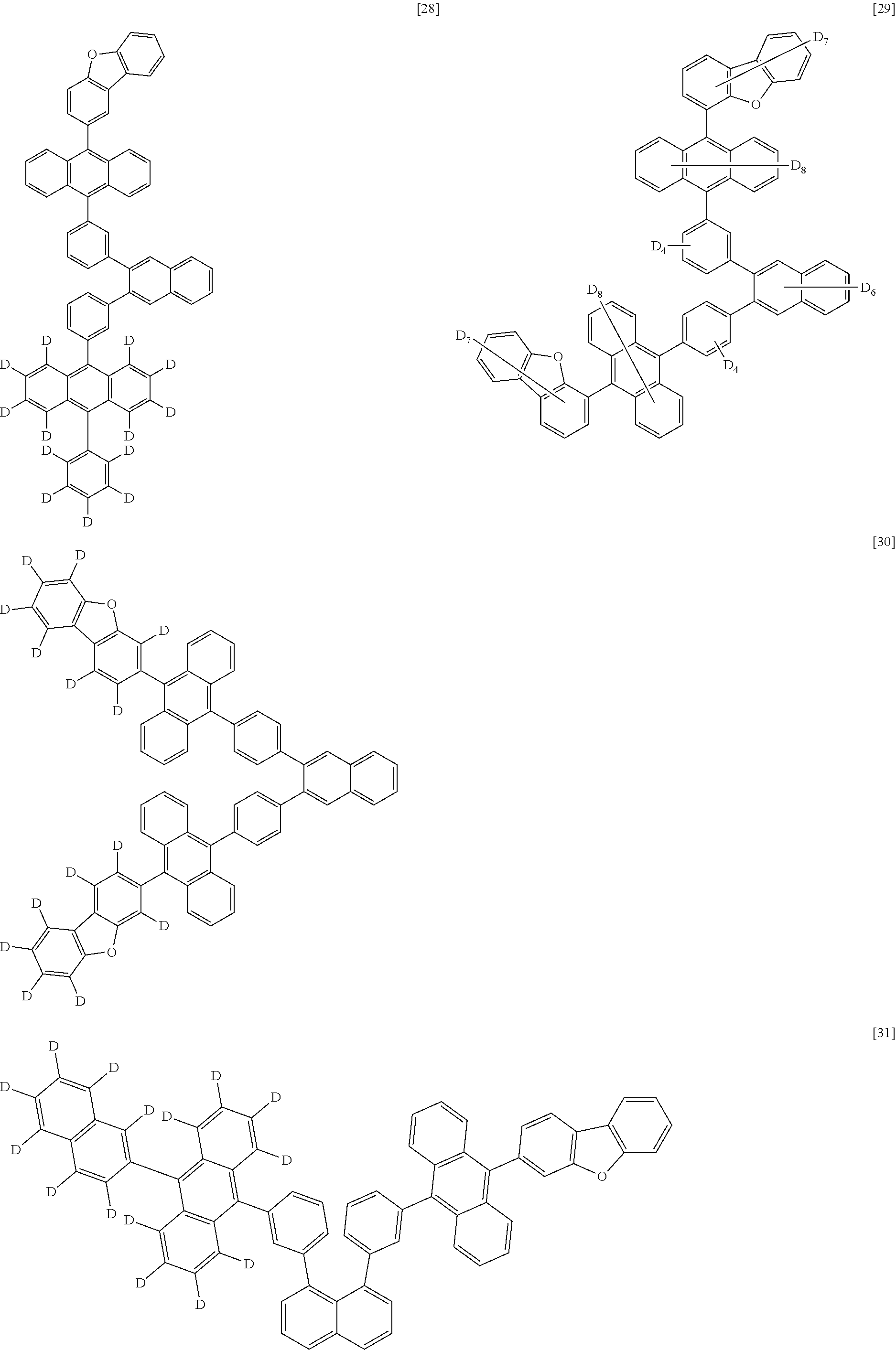

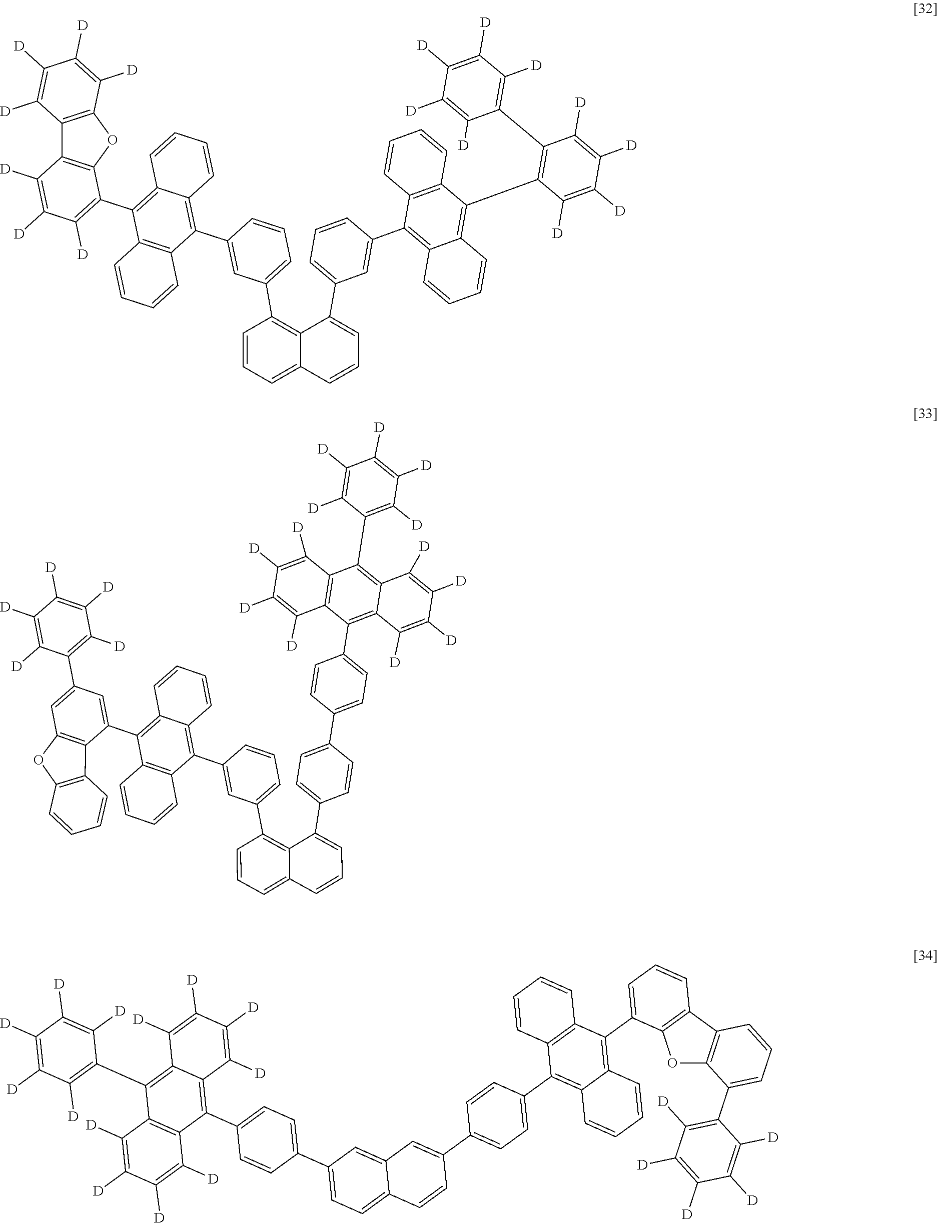

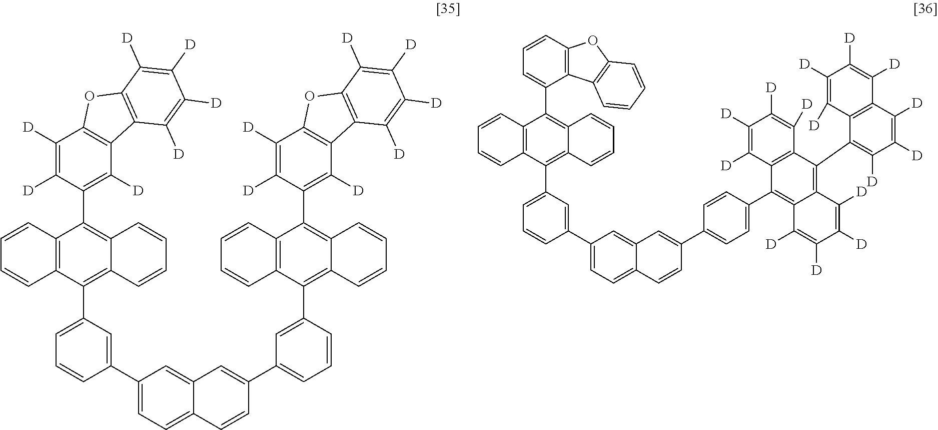 [SMILES: [2H]c1c([2H])c([2H])c2c(oc3c([2H])c([2H])c(-c4c5ccccc5c(-c5cccc(-c6ccc7ccc(-c8cccc(-c9c%10ccccc%10c(-c%10c([2H])c([2H])c%11oc%12c([2H])c([2H])c([2H])c([2H])c%12c%11c%10[2H])c%10ccccc9%10)c8)cc7c6)c5)c5ccccc45)c([2H])c32)c1[2H] ; [2H]c1c([2H])c([2H])c2c(-c3c4c([2H])c([2H])c([2H])c([2H])c4c(-c4ccc(-c5ccc6ccc(-c7cccc(-c8c9ccccc9c(-c9cccc%10oc%11ccccc%11c9%10)c9ccccc89)c7)cc6c5)cc4)c4c([2H])c([2H])c([2H])c([2H])c34)c([2H])c([2H])c([2H])c2c1[2H]]

[11] In [1] to [10] above,

The dopant may be a boron-based compound represented by [Formula B-1] or [Formula B-2] below:

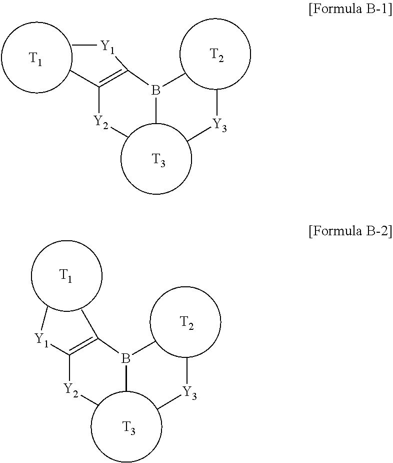

In [Formula B-1] and [Formula B-2],
T₁ to T₃ above are respectively the same as or different from each other and are each independently a substituted or unsubstituted aromatic ring having 6 to 50 carbon atoms, or a substituted or unsubstituted aromatic heterocycle having 2 to 40 carbon atoms,
Y₁ is any one selected from N—R₁, CR₁₂R₁₃, O, S, and SiR₁₄R₁₅,
Y₂ is any one selected from N—R₁₆, CR₁₇R₁₈, O, S, and SiR₁₉R₂₀,
Y₃ is any one selected from N—R₂₁, CR₂₂R₂₃, O, S, and SiR₂₄R₂₅,

R₁₁ to R₂₅ above are respectively the same as or different from each other, and are each independently any one selected from hydrogen, deuterium, a substituted or unsubstituted alkyl group having 1 to 30 carbon atoms, a substituted or unsubstituted aryl group having 6 to 50 carbon atoms, a substituted or unsubstituted cycloalkyl group having 3 to 30 carbon atoms, a substituted or unsubstituted heteroaryl group having 2 to 50 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 5 to 30 carbon atoms, a substituted or unsubstituted alkylamine group having 1 to 30 carbon atoms, a substituted or unsubstituted arylamine group having 5 to 30 carbon atoms, a substituted or unsubstituted alkylsilyl group having 1 to 30 carbon atoms, a substituted or unsubstituted arylsilyl group having 5 to 30 carbon atoms, a cyano group, and a halogen group, and R₁₁ to R₂₅ above may be each combined with one or more rings selected from T₁ to T₃ above to additionally form an alicyclic or aromatic mono- or polycyclic ring.
[12] In [1] to [11] above,

The organic layer may comprises at least one of a hole injection layer, a hole transport layer, a functional layer having both a hole injection function and a hole transport function at the same time, an electron transport layer, and an electron injection layer in addition to a light emitting layer.
[13] In [1] to [12] above,

The organic layer may be formed by any one of a spin coating method, a dip coating method, a doctor blade coating method, a spray coating method, a roll coating method, inkjet printing, and screen printing.

### Advantageous Effects

The organic electroluminescent device according to the present disclosure can be manufactured using an organic electroluminescent material with high solubility in solvents, and has excellent operating characteristics and lifespan characteristics of the device such as luminous efficiency and driving voltage.

### BRIEF DESCRIPTION OF DRAWING

FIG. 1 is a schematic cross-sectional view of an organic electroluminescent device according to one embodiment of the present disclosure.

### DETAILED DESCRIPTION

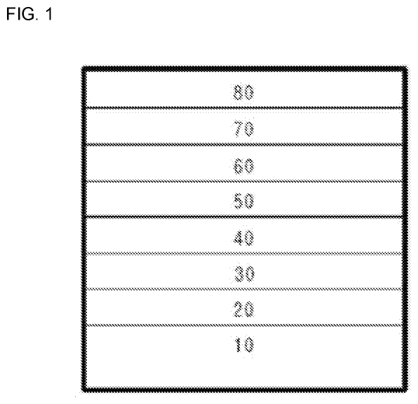

Referring to FIG. 1, an organic electroluminescent device according to one embodiment of the present disclosure may comprise a first electrode 20, a second electrode 80 opposing the first electrode 20, and an organic layer formed between the first electrode 20 and the second electrode 80.

For example, the first electrode 20 may be an anode, and the second electrode 80 may be a cathode. The organic layer may comprise a light emitting layer 50 formed using a solution containing an organic electroluminescent material and a solvent. The organic layer may further comprise at least one of a hole injection layer 30, a hole transport layer 40, a functional layer having both a hole injection function and a hole transport function at the same time, an electron transport layer 60, and an electron injection layer 70 as needed in addition to a light emitting layer, and may further comprise a single or a plurality of intermediate layers besides them.

The organic layer may be formed by a deposition process or a solution process.

The deposition process may refer to, for example, a method of forming a thin film by evaporating a material through a method such as heating in a vacuum or low pressure state. The solution process may refer to, for example, a method of forming a thin film by mixing a material with a solvent to form a solution and then applying the solution through a method such as a spin coating method, a dip coating method, a doctor blade coating method, a spray coating method, a roll coating method, inkjet printing, screen printing, and the like.

The hole injection layer (HIL) 30 may be provided between the first electrode 20 and the hole transport layer 40. The hole injection layer 30 may comprise, for example, poly(3,4-ethylenedioxythiophene):poly(styrenesulfonate) (AI4083), 4,4′,4″-tris[2-naphthyl(phenyl)amino]triphenylamine (2-TNATA), N,N′-di(1-naphthyl)-N,N′-diphenylbenzidine (NPD), N,N′-diphenyl-N,N′-bis(3-methylphenyl)-(1,1′-biphenyl)-4,4′-diamine (TPD), N,N′-diphenyl-N,N′-bis-[4-(phenyl-m-tolyl-amino)-phenyl]-biphenyl-4,4′-diamine (DNTPD), and 4,4′,4″-tri(N-carbazolyl)triphenylamine (TCTA), and 4,4′,4″-tris-(3-methylphenylphenylamino)triphenylamine (m-MTDATA), which are copper phthalocyanines or starburst type amines, but is not limited thereto and may comprise materials commonly used as the hole injection layer in the art.

The hole transport layer (HTL) 40 may be provided between the hole injection layer 30 and the light emitting layer 50. The hole transport layer 40 may comprise an electron donating material with a low ionization potential. More specifically, the hole transport layer 40 may comprise diamine, triamine or tetraamine derivatives with triphenylamine as the basic skeleton, for example, N,N′-bis(3-methylphenyl)-N,N′-diphenyl-[1,1′-biphenyl]-4,4′-diamine (TPD), N,N′-di(naphthalen-1-yl)-N,N′-diphenylbenzidine (a-NPD), poly[(9,9-dioctylfluorenyl-2,7-diyl)-co-(4,4′-(N-(4-sec-butylphenyl)diphenylamine)](TFB), etc.

The electron transport layer (ETL) 60 may be provided between the second electrode 80 and the light emitting layer 50. The electron transport layer 60 may comprise, for example, oxadiazole derivatives, triazine derivatives, Liq, Alq₃, etc.

The electron injection layer (EIL) 70 may be provided between the second electrode 80 and the electron transport layer 60. The electron injection layer 70 may comprise, for example, Liq, LiF, NaCl, CsF, Li₂O, BaO, etc., but is not limited thereto and may comprise materials commonly used as an electron injection layer in the art.

The light emitting layer 50 may be provided between the hole transport layer 40 and the electron transport layer 60. The light emitting layer 50 may be formed using a solution containing an organic electroluminescent material and a solvent.

The organic electroluminescent material may comprise a host and a dopant, and the host may be one or more compounds represented by [Formula A] below:

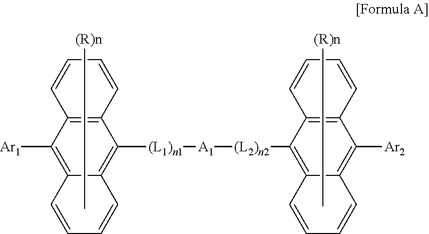

In [Formula A],

L₁ to L₂ are the same as or different from each other, and each independently selected from the group consisting of a substituted or unsubstituted alkylene group having 1 to 20 carbon atoms, a substituted or unsubstituted arylene group having 6 to 30 carbon atoms, and a substituted or unsubstituted heteroarylene group having 3 to 30 carbon atoms,

R is the same as or different from each other, and each independently selected from the group consisting of a hydrogen atom, a deuterium atom, a substituted or unsubstituted alkyl group having 1 to 30 carbon atoms, a substituted or unsubstituted alkenyl group having 2 to 30 carbon atoms, a substituted or unsubstituted cycloalkyl group having 3 to 30 carbon atoms, a substituted or unsubstituted cycloalkenyl group having 5 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 6 to 30 carbon atoms, a substituted or unsubstituted alkylamine group having 1 to 30 carbon atoms, a substituted or unsubstituted arylamine group having 6 to 30 carbon atoms, a substituted or unsubstituted aryl group having 6 to 50 carbon atoms, a substituted or unsubstituted heteroaryl group having 3 to 50 carbon atoms, a substituted or unsubstituted alkylsilyl group having 1 to 30 carbon atoms, and a substituted or unsubstituted arylsilyl group having 6 to 30 carbon atoms,

Ar₁ and Ar₂ are the same as or different from each other, and each independently selected from the group consisting of a substituted or unsubstituted alkyl group having 1 to 30 carbon atoms, a substituted or unsubstituted cycloalkyl group having 3 to 30 carbon atoms, a substituted or unsubstituted aryl group having 6 to 50 carbon atoms, and a substituted or unsubstituted heteroaryl group having 3 to 50 carbon atoms, provided that at least one of Ar₁ and Ar₂ is not a substituted or unsubstituted aryl group having 6 to 50 carbon atoms,
n is an integer of 0 to 8, but when n is 2 or more, respective R is the same as or different from each other,
n1 and n2 are each independently an integer of 1 to 3, and
A₁ is a substituted or unsubstituted aryl group having 10 to 30 carbon atoms.

In one embodiment of the present disclosure, A₁ of [Formula A] may be any one selected from groups represented by [Formula A-1] to [Formula A-4] below:

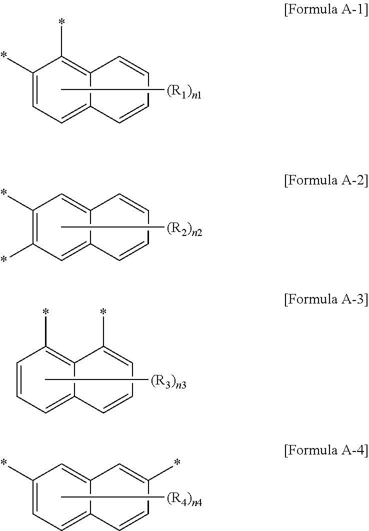

In [Formula A-1] to [Formula A-4],

R₁ to R₄ are the same as or different from each other, and each independently selected from the group consisting of a deuterium atom, a substituted or unsubstituted alkyl group having 1 to 30 carbon atoms, a substituted or unsubstituted alkenyl group having 2 to 30 carbon atoms, a substituted or unsubstituted cycloalkyl group having 3 to 30 carbon atoms, a substituted or unsubstituted cycloalkenyl group having 5 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 6 to 30 carbon atoms, a substituted or unsubstituted alkylamine group having 1 to 30 carbon atoms, a substituted or unsubstituted arylamine group having 6 to 30 carbon atoms, a substituted or unsubstituted aryl group having 6 to 50 carbon atoms, a substituted or unsubstituted heteroaryl group having 3 to 50 carbon atoms, a substituted or unsubstituted alkylsilyl group having 1 to 30 carbon atoms, and a substituted or unsubstituted arylsilyl group having 6 to 30 carbon atoms,
n1 to n4 are integers of 0 to 6, but when n is 2 or more, respective R₁ to R₄ are the same as or different from each other.

In one embodiment of the present disclosure, at least one of Ar₁ and Ar₂ of [Formula A] may be any one of groups represented by [Formula Ar-1] or [Formula Ar-2] below:

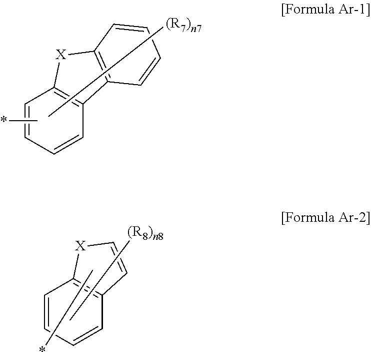

In [Formula Ar-1] and [Formula Ar-2],

X is selected from the group consisting of O, S, NR′, and Si(R′)₂,

R₇, R₈, and R′ are the same as or different from each other, and each independently selected from the group consisting of a hydrogen atom, a deuterium atom, a substituted or unsubstituted alkyl group having 1 to 30 carbon atoms, a substituted or unsubstituted alkenyl group having 2 to 30 carbon atoms, a substituted or unsubstituted cycloalkyl group having 3 to 30 carbon atoms, a substituted or unsubstituted cycloalkenyl group having 5 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 6 to 30 carbon atoms, a substituted or unsubstituted alkylamine group having 1 to 30 carbon atoms, a substituted or unsubstituted arylamine group having 6 to 30 carbon atoms, a substituted or unsubstituted aryl group having 6 to 50 carbon atoms, a substituted or unsubstituted heteroaryl group having 3 to 50 carbon atoms, a substituted or unsubstituted alkylsilyl group having 1 to 30 carbon atoms, and a substituted or unsubstituted arylsilyl group having 6 to 30 carbon atoms,
n7 is an integer of 0 to 7, and n8 is an integer of 0 to 5, but when n7 and n8 are 2 or more, respective R₇ and R₈ are the same as or different from each other.

In one embodiment of the present disclosure, Ar₁ and Ar₂ are each independently any one of groups represented by [Formula Ar-1] or [Formula Ar-2], or Ar₁ and Ar₂ are each independently a group represented by [Formula Ar-1].

In one embodiment of the present disclosure, X may be O or S.

In one embodiment of the present disclosure, L₁ and L₂ of [Formula A] may each independently be a substituted or unsubstituted phenylene group.

“Substituted” in the “substituted or unsubstituted” means being substituted with one or more substituents selected from the group consisting of deuterium, a cyano group, a halogen group, a hydroxy group, a nitro group, an alkyl group having 1 to 24 carbon atoms, an alkynyl group having 1 to 24 carbon atoms, a cycloalkyl group having 3 to 24 carbon atoms, a heteroalkyl group having 1 to 24 carbon atoms, an aryl group having 6 to 24 carbon atoms, an arylalkyl group having 7 to 24 carbon atoms, an alkylaryl group having 7 to 24 carbon atoms, a heteroaryl group having 2 to 24 carbon atoms, a heteroarylalkyl group having 2 to 24 carbon atoms, an alkoxy group having 1 to 24 carbon atoms, an alkylamino group having 1 to 24 carbon atoms, a diarylamino group having 12 to 24 carbon atoms, a diheteroarylamino group having 2 to 24 carbon atoms, an aryl(heteroaryl)amino group having 7 to 24 carbon atoms, an alkylsilyl group having 1 to 24 carbon atoms, an arylsilyl group having 6 to 24 carbon atoms, an aryloxy group having 6 to 24 carbon atoms, and an arylthionyl group having 6 to 24 carbon atoms.

In addition, considering the range of the alkyl group or aryl group in the “substituted or unsubstituted alkyl group having 1 to 30 carbon atoms”, “substituted or unsubstituted aryl group having 6 to 50 carbon atoms”, etc., the ranges of the carbon numbers of the alkyl group having 1 to 30 carbon atoms and the aryl group having 6 to 50 carbon atoms each refer to the total number of carbon atoms constituting the alkyl portion or the aryl portion when the substituent is viewed as an unsubstituted substituent without considering the portion on which the substituent is substituted. For example, a phenyl group substituted with a butyl group at the para position should be viewed as corresponding to an aryl group having 6 carbon atoms substituted with a butyl group having 4 carbon atoms.

The aryl group of the compound represented by [Formula A] above refers to an aromatic system consisting of a hydrocarbon containing one or more rings. When the aryl group has a substituent, it may be fused with neighboring substituents each other to additionally form a ring.

Specific examples of the aryl group may include aromatic groups such as a phenyl group, an o-biphenyl group, a m-biphenyl group, a p-biphenyl group, an o-terphenyl group, a m-terphenyl group, a p-terphenyl group, a naphthyl group, an anthryl group, a phenanthryl group, a pyrenyl group, an indenyl group, a fluorenyl group, a tetrahydronaphthyl group, a perylenyl group, a chrysenyl group, a naphthacenyl group, a fluoranthenyl group, a triphenylenyl group, etc.

The heteroaryl group of the compound represented by [Formula A] above refers to a ring aromatic system having 2 to 24 carbon atoms which contains 1, 2, or 3 heteroatoms selected from N, O, P, Si, S, Ge, Se, or Te, and in which the remaining ring atoms are carbon, and the rings may be fused to form a ring. In addition, one or more hydrogen atoms of the heteroaryl group can be substituted with the same substituent as that of the aryl group.

Specific examples of the heteroaryl group may include a furanyl group, a benzofuranyl group, a dibenzofuranyl group, a thiophenyl group, a benzothiophenyl group, a dibenzothiophenyl group, a pyrrolyl group, an indolyl group, a carbazolyl group, a pyridinyl group, a quinolinyl group, an imidazolyl group, a benzimidazolyl group, an oxazolyl group, a benzoxazolyl group, a triazinyl group, a triazolyl group, a piperidinyl group, an acridinyl group, a phenoxazinyl group, a thiazole group, a benzothiazole group, a pyrimidiryl group, a pyrazinyl group, etc.

The alkyl group of the compound represented by [Formula A] above is a straight-chain type or branched-chain type, and specific examples thereof may include methyl, ethyl, propyl, isopropyl, isobutyl, sec-butyl, tert-butyl, pentyl, iso-amyl, hexyl, etc., and one or more hydrogen atoms in the alkyl group can be substituted with the same substituent as that of the aryl group.

The heteroalkyl group of the compound represented by [Formula A] above refers to one in which one or more carbon atoms in the main chain of the alkyl group, preferably 1 to 5 carbon atoms, are substituted with a hetero atom such as an oxygen atom, a sulfur atom, a nitrogen atom, a phosphorus atom, etc., and one or more hydrogen atoms of the heteroalkyl group can be substituted with the same substituent as that of the alkyl group.

“Cyclo” in the cycloalkyl group of the compound represented by [Formula A] above refers to a substituent with a structure that can form a single ring or multiple rings of a saturated hydrocarbon in the alkyl group. For example, specific examples of the cycloalkyl group may include cyclopropyl, cyclobutyl, cyclopentyl, cyclohexyl, methylcyclopentyl, methylcyclohexyl, ethylcyclopentyl, ethylcyclohexyl, adamantyl, dicyclophentadienyl, decahydronaphthyl, norbornyl, bornyl, isobornyl, etc. One or more hydrogen atoms of the cycloalkyl group can be substituted with the same substituent as that of the aryl group.

The alkoxy group of the compound represented by [Formula A] above is a substituent in which an oxygen atom is bonded to the end of an alkyl group or cycloalkyl group, and specific examples thereof may include methoxy, ethoxy, propoxy, isobutyloxy, sec-butyloxy, pentyloxy, iso-amyloxy, and hexyloxy, and one or more hydrogen atoms of the alkoxy group can be substituted with the same substituent as that of the aryl group.

Specific examples of the arylalkyl group of the compound represented by [Formula A] above may include phenylmethyl(benzyl), phenylethyl, phenylpropyl, naphthylmethyl, naphthylethyl, etc., and one or more hydrogen atoms of the arylalkyl group can be substituted with the same substituent as that of the aryl group.

Specific examples of the alkylsilyl group of the compound represented by [Formula A] above may include trimethylsilyl, triethylsilyl, and methylcyclobutylsilyl, and one or more hydrogen atoms of the alkylsilyl group can be substituted with the same substituent as that of the aryl group.

Specific examples of the arylsilyl group of the compound represented by [Formula A] above may include triphenylsilyl, diphenylmethylsilyl, and diphenylvinylsilyl, and one or more hydrogen atoms of the arylsilyl group can be substituted with the same substituent as that of the aryl group.

The alkenyl group of the compound represented by [Formula A] above refers to an alkyl substituent containing one carbon-carbon double bond made up of two carbon atoms, and the alkynyl group also refers to an alkyl substituent containing one carbon triple bond made up of two carbon atoms.

The diarylamino group of the compound represented by [Formula A] above refers to an amine group in which two identical or different aryl groups described above are bonded to a nitrogen atom, the diheteroarylamino group of the compound of the present disclosure refers to an amine group in which two identical or different heteroaryl groups are bonded to a nitrogen atom, and the aryl(heteroaryl)amino group refers to an amine group in which the aryl group and heteroaryl group are bonded to a nitrogen atom, respectively.

In one embodiment of the present disclosure, the compound represented by [Formula A] may be substituted with at least one deuterium. When the compound represented by [Formula A] above is substituted with at least one deuterium, the solubility of the compound represented by [Formula A] in a solvent may increase. The compound represented by [Formula A] may have a degree of deuteration of preferably 15% or more, and more preferably 30% or more, 40% or more, or 50% or more.

When deuterium is substituted in the compound represented by [Formula A] above, the ground state energy is lowered compared to the C—H bond, and as the binding force increases, heat resistance is further improved and the effect of improving lifespan may be exhibited.

In one embodiment of the present disclosure, the compound represented by [Formula A] above may have a molecular weight of 650 or more, preferably 700 or more, more preferably 750 or more, and even more preferably 800 or more.

The lower the molecular weight of the compound represented by [Formula A] above, a phenomenon in which adjacent pixels are contaminated during the inkjet process, that is, the interference effect may occur, and the higher the molecular weight of the compound represented by [Formula A] above, the effect of increasing the solubility in the solvent may be exhibited.

According to one embodiment of the present disclosure, a preferred compound of the host may be any one selected from compounds [1] to [36] below:

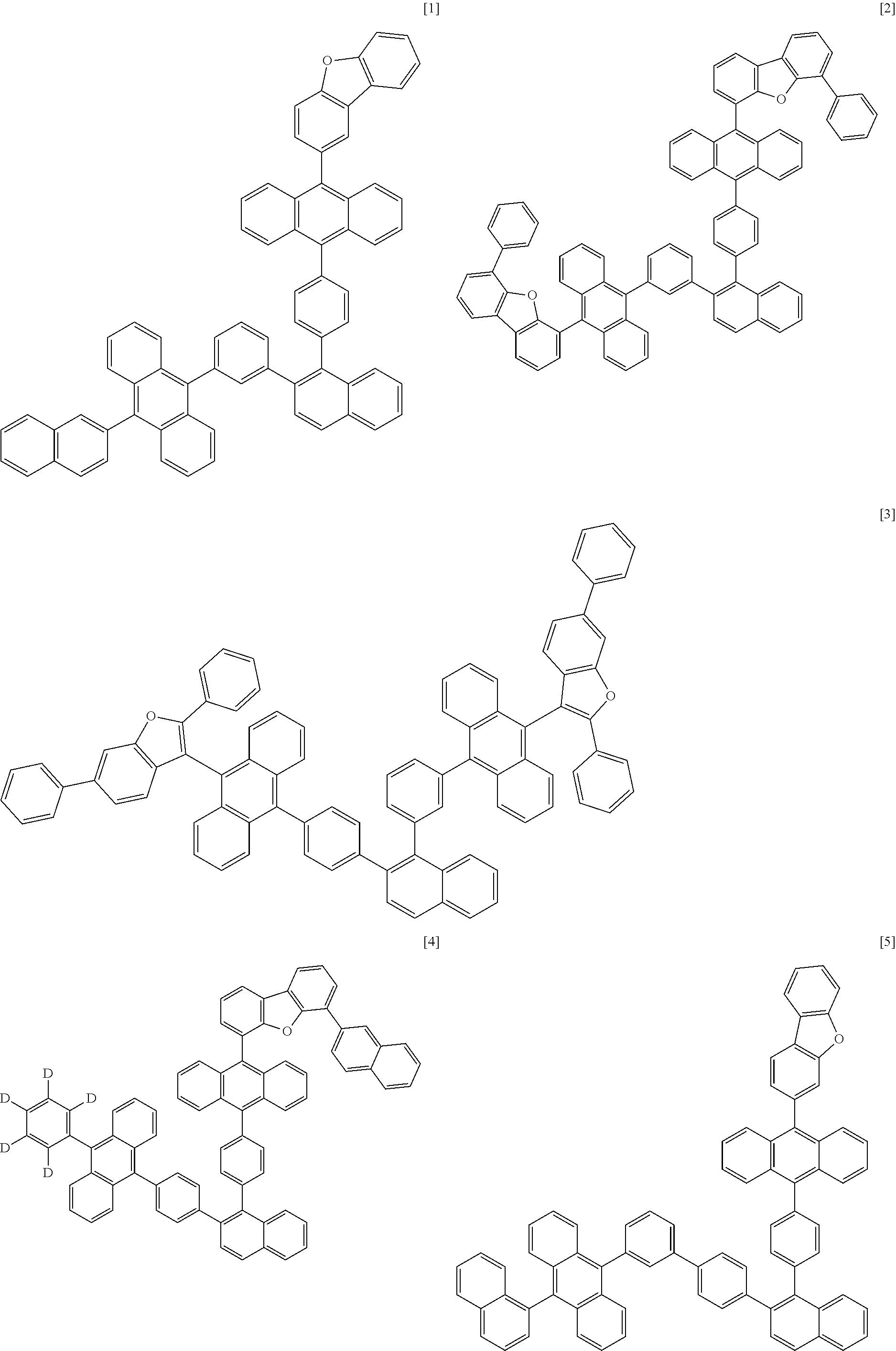

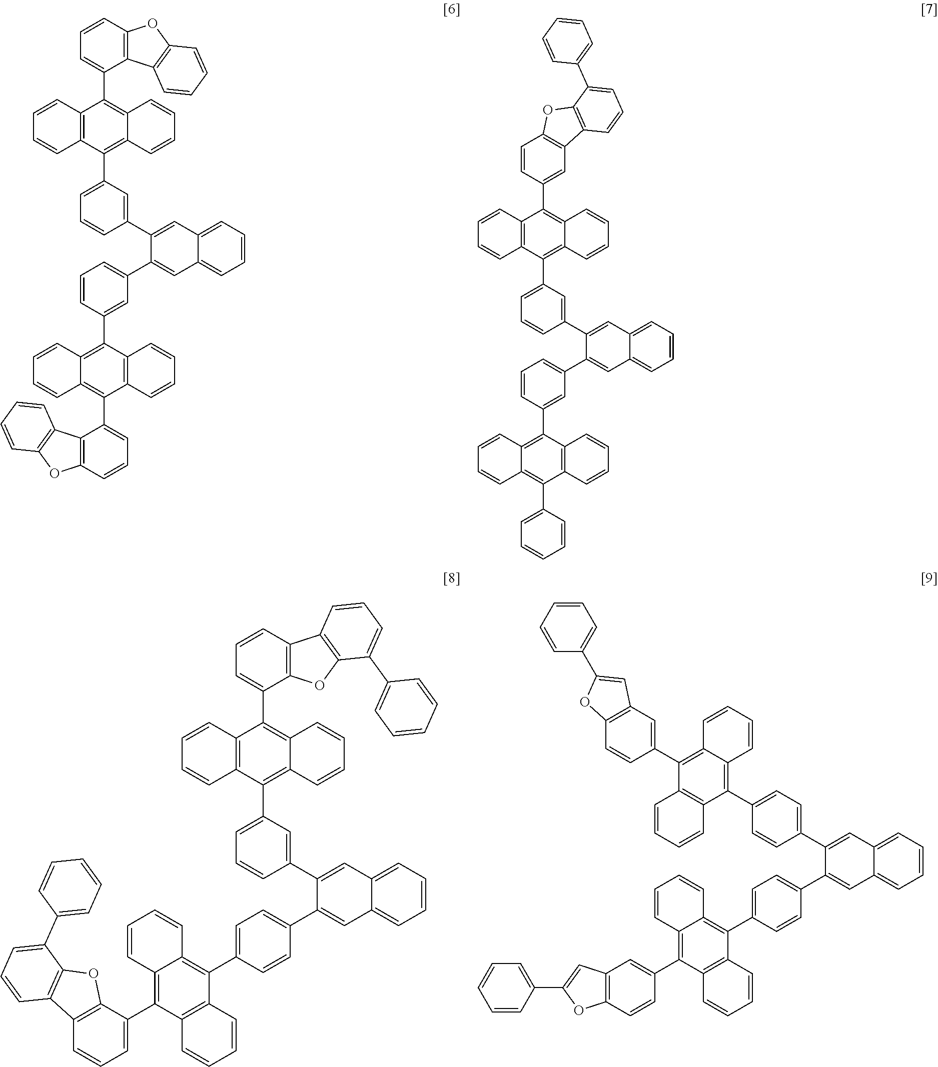

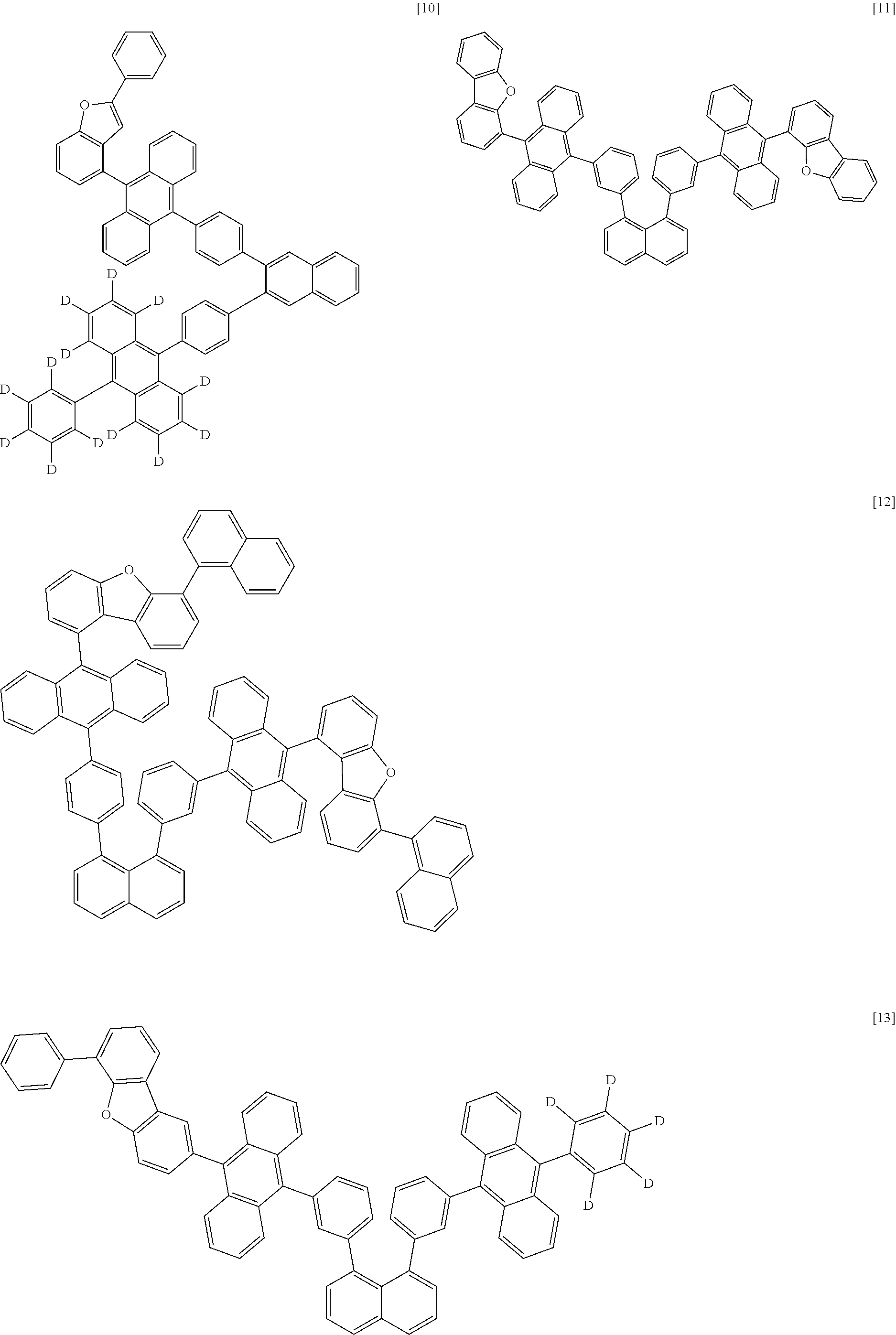

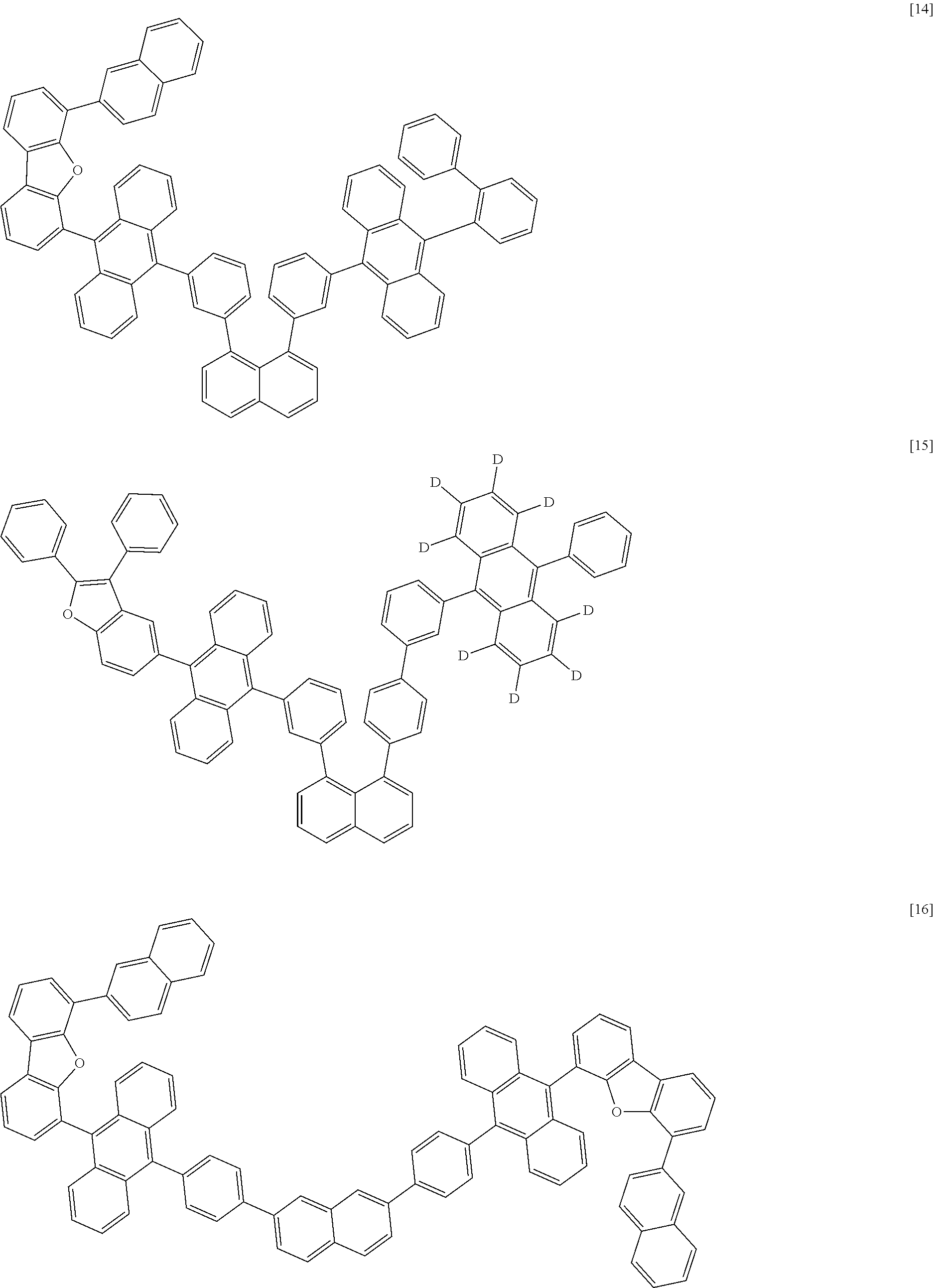

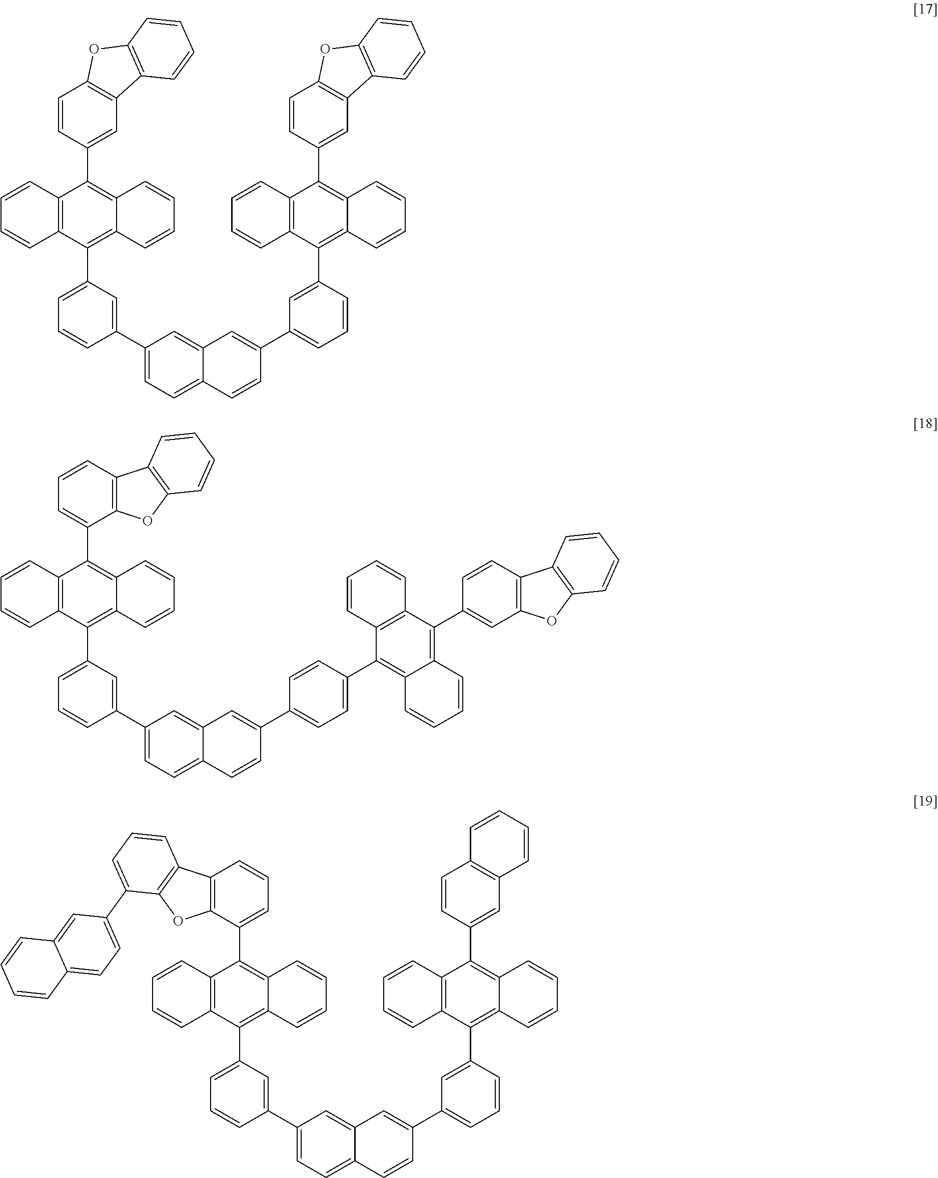

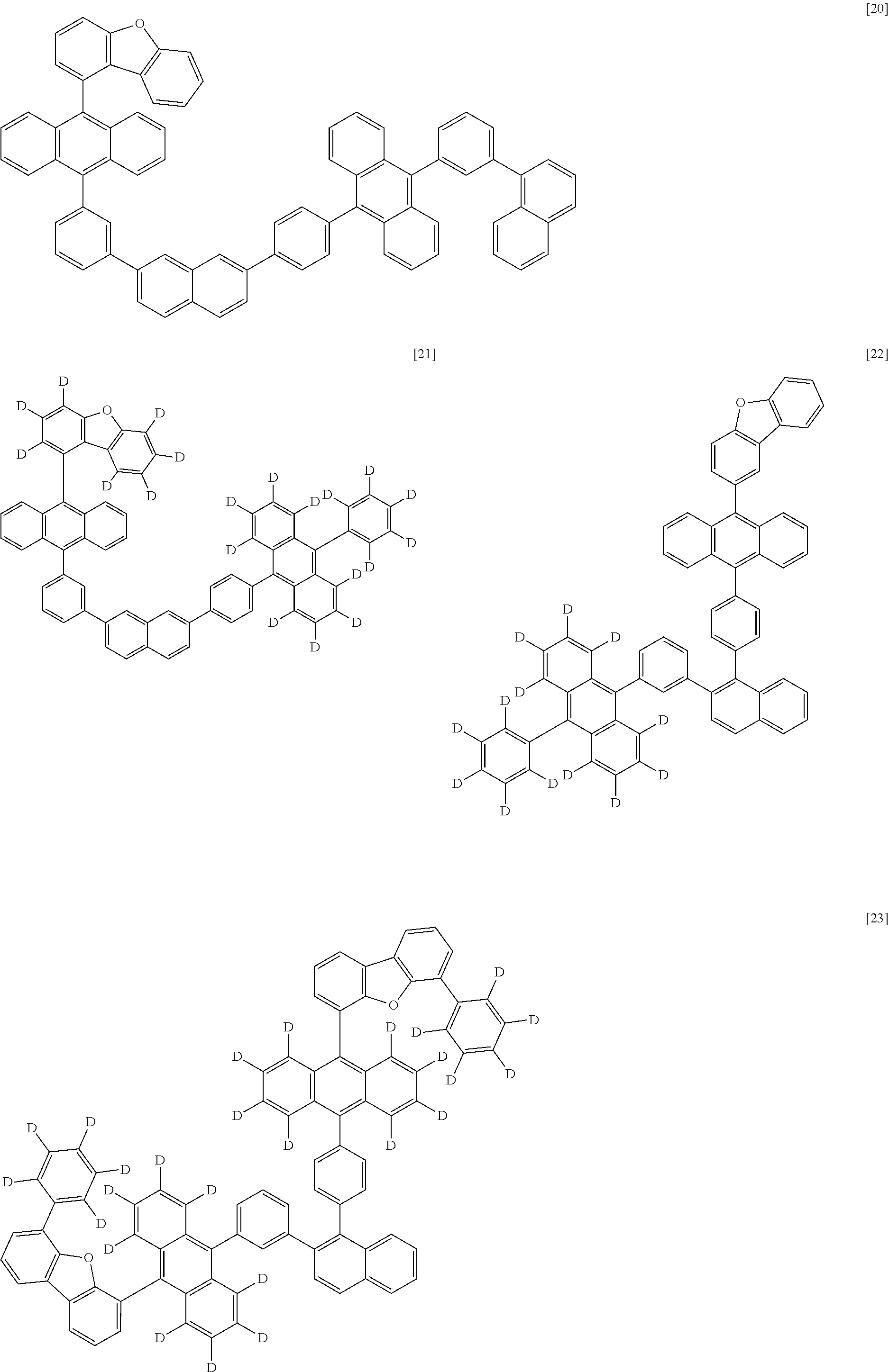

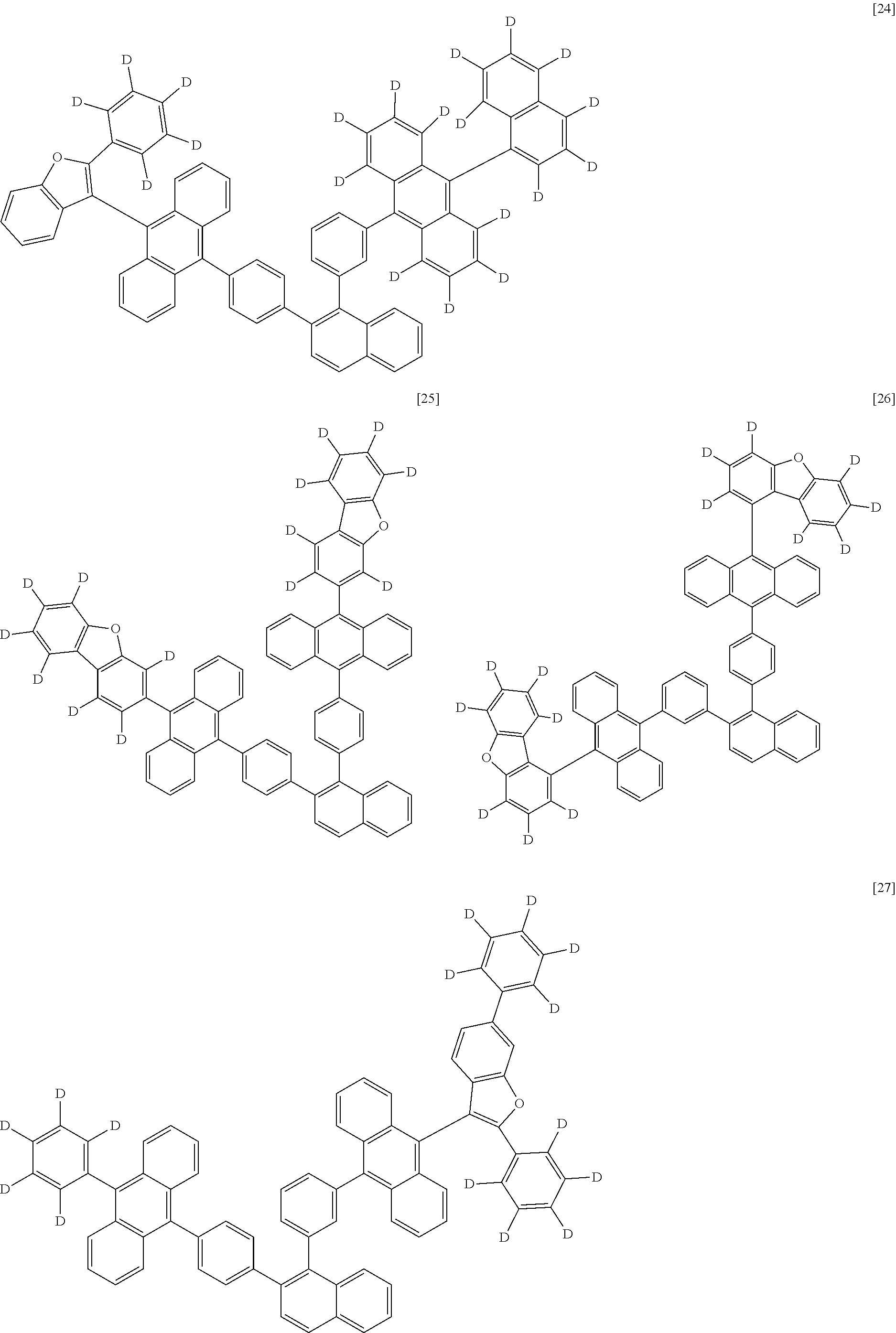

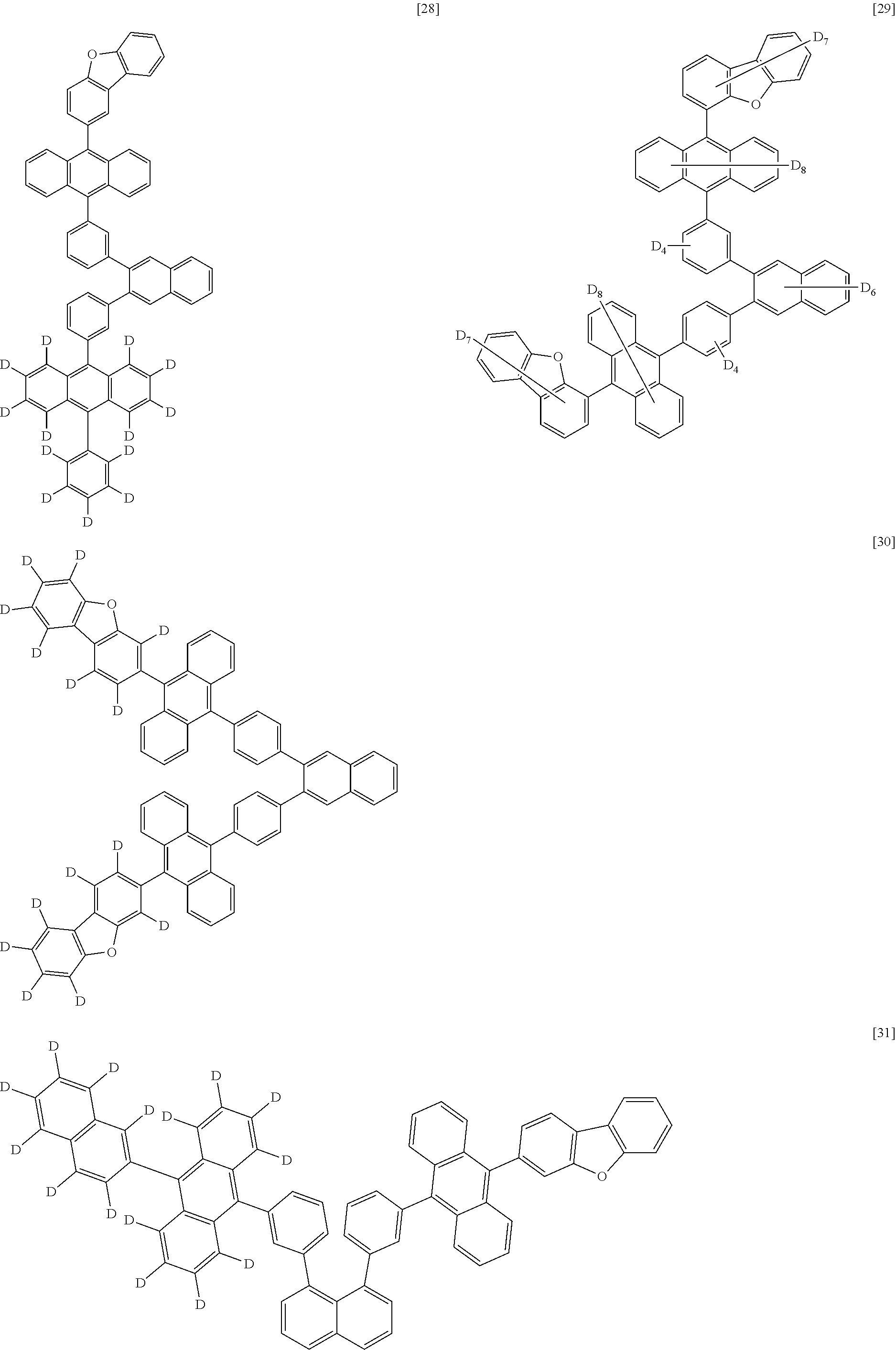

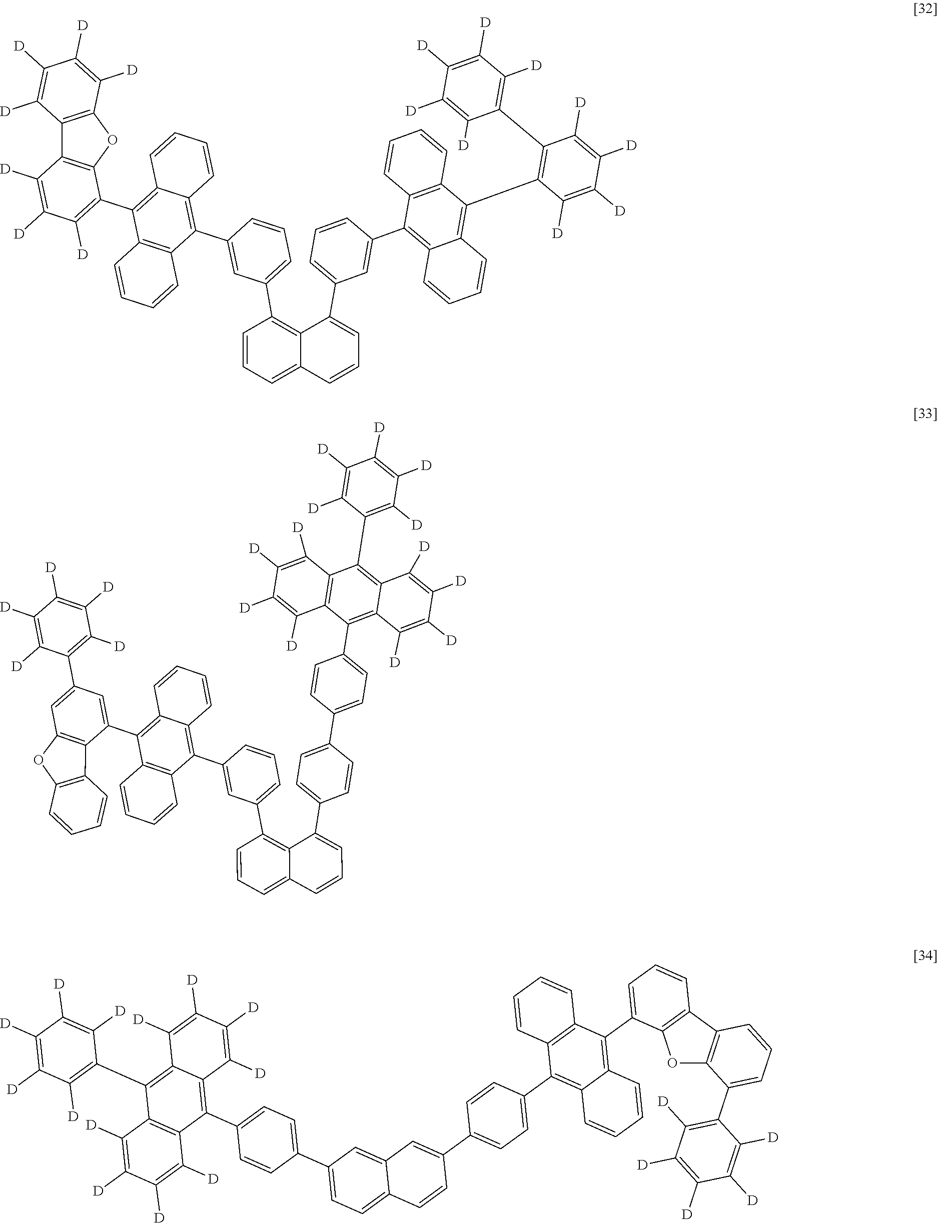

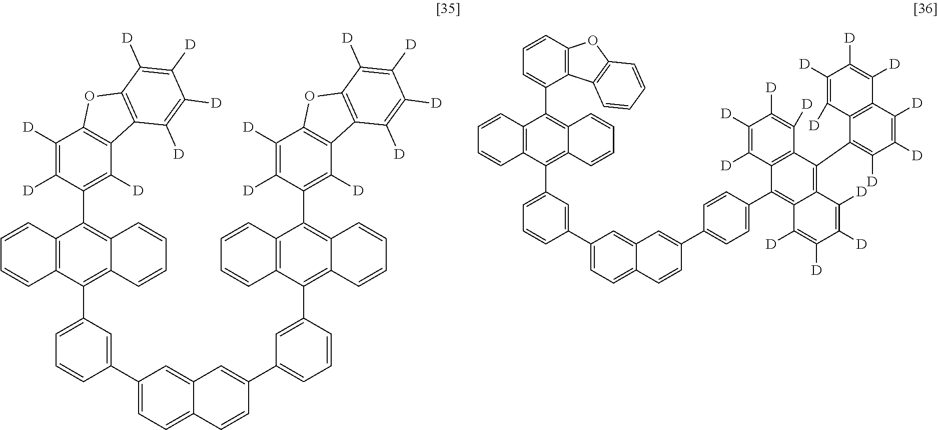 [SMILES: [2H]c1c([2H])c([2H])c2c(oc3c([2H])c([2H])c(-c4c5ccccc5c(-c5cccc(-c6ccc7ccc(-c8cccc(-c9c%10ccccc%10c(-c%10c([2H])c([2H])c%11oc%12c([2H])c([2H])c([2H])c([2H])c%12c%11c%10[2H])c%10ccccc9%10)c8)cc7c6)c5)c5ccccc45)c([2H])c32)c1[2H] ; [2H]c1c([2H])c([2H])c2c(-c3c4c([2H])c([2H])c([2H])c([2H])c4c(-c4ccc(-c5ccc6ccc(-c7cccc(-c8c9ccccc9c(-c9cccc%10oc%11ccccc%11c9%10)c9ccccc89)c7)cc6c5)cc4)c4c([2H])c([2H])c([2H])c([2H])c34)c([2H])c([2H])c([2H])c2c1[2H]]

As the host, one type of compound may be used, or two or more types of compounds may be used together.

The solubility of the host in the solvent may be 0.1% by weight or more to 50% by weight or less, or 0.5% by weight or more to 20% by weight or less, preferably 1% by weight or more, and more preferably 2% by weight or more.

The solvent may comprise at least one of a chlorine-based solvent, an ether-based solvent, an aromatic solvent, an aliphatic solvent, a ketone-based solvent, an ester-based solvent, an alcohol-based solvent, an amide-based solvent, and a benzoate-based solvent. The solvent may be a single pure substance or a mixture, preferably a benzoate-based solvent.

For example, the chlorine-based solvent may include chloroform, methylene chloride, or chlorobenzene, the ether-based solvent may include tetrahydrofuran or dioxane, the aromatic solvent may include toluene, xylene, or trimethylbenzene, the aliphatic solvent may include cyclohexane, n-pentane, or n-hexane, the ketone-based solvent may include acetone, methyl ethyl ketone, or cyclohexanone, the ester-based solvent may include ethyl acetate or butyl acetate, the alcohol-based solvent may include methanol, ethanol, propanol, or cyclohexanol, the amide-based solvent may include N,N-dimethylformamide, and the benzoate-based solvent may include methyl benzoate, ethyl benzoate, or butyl benzoate.

One type of the solvent may be used alone, or two or more types of solvents may be mixed and used.

The solvent may have a boiling point of 60° C. to 300° C., preferably 130° C. to 300° C. but is not limited thereto.

The solvent may have a viscosity of 1 cP to 10 cP, preferably 2 cP to 8 cP, but is not limited thereto.

A solution containing the compound represented by [Formula A] above and the solvent may be suitable for manufacturing an organic electroluminescent device using a solution process.

The solution may further contain a fluorescent dopant or a phosphorescent dopant.

The fluorescent dopant may comprise, for example, a pyrene-based compound, a deuterium-substituted pyrene-based compound, an arylamine, a deuterium-substituted arylamine, a peryl-based compound, a deuterium-substituted peryl-based compound, a pyrrole-based compound, a deuterium-substituted pyrrole-based compound, a boron-based compound, a fluorene-based compound, a deuterium-substituted fluorene-based compound, a hydrazone-based compound, a deuterium-substituted hydrazone-based compound, a carbazole-based compound, a deuterium-substituted carbazole-based compound, a stilbene-based compound, a deuterium-substituted stilbene-based compound, a starburst-based compound, a deuterium-substituted starburst-based compound, an oxadiazole-based compound, a deuterium-substituted oxadiazole-based compound, coumarin, and deuterium-substituted coumarin, but may not be limited thereto.

The phosphorescent dopant may include, for example, iridium, platinum, osmium, titanium, zirconium, hafnium, europium, terbium, thulium, iron, cobalt, nickel, ruthenium, rhodium, palladium, or an organometallic compound containing combinations thereof, but is not limited thereto.

The dopant may be a boron-based compound represented by [Formula B-1] or [Formula B-2] below:

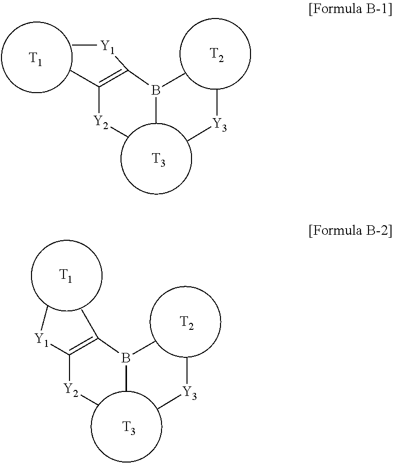

In [Formula B-1] and [Formula B-2],

T₁ to T₃ above are respectively the same as or different from each other and are each independently a substituted or unsubstituted aromatic ring having 6 to 50 carbon atoms, or a substituted or unsubstituted aromatic heterocycle having 2 to 40 carbon atoms,
Y₁ is any one selected from N—R₁, CR₁₂R₁₃, O, S, and SiR₁₄R₁₅,
Y₂ is any one selected from N—R₁₆, CR₁₇R₁₈, O, S, and SiR₁₉R₂₀,
Y₃ is any one selected from N—R₂₁, CR₂₂R₂₃, O, S, and SiR₂₄R₂₅,

R₁ to R₂₅ above are respectively the same as or different from each other, and are each independently any one selected from hydrogen, deuterium, a substituted or unsubstituted alkyl group having 1 to 30 carbon atoms, a substituted or unsubstituted aryl group having 6 to 50 carbon atoms, a substituted or unsubstituted cycloalkyl group having 3 to 30 carbon atoms, a substituted or unsubstituted heteroaryl group having 2 to 50 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 5 to 30 carbon atoms, a substituted or unsubstituted alkylamine group having 1 to 30 carbon atoms, a substituted or unsubstituted arylamine group having 5 to 30 carbon atoms, a substituted or unsubstituted alkylsilyl group having 1 to 30 carbon atoms, a substituted or unsubstituted arylsilyl group having 5 to 30 carbon atoms, a cyano group, and a halogen group,

R₁ to R₂₅ above may be each combined with one or more rings selected from T₁ to T₃ above to additionally form an alicyclic or aromatic mono- or polycyclic ring,

In the compound represented by any one of [Formula B-1] and [Formula B-2] above, details regarding the substituents are as described in the compound represented by [Formula A] above.

The compound represented by anyone of [Formula B-1] and [Formula B-2] above may be any one selected from compounds of [D 201] to [D 350] below:

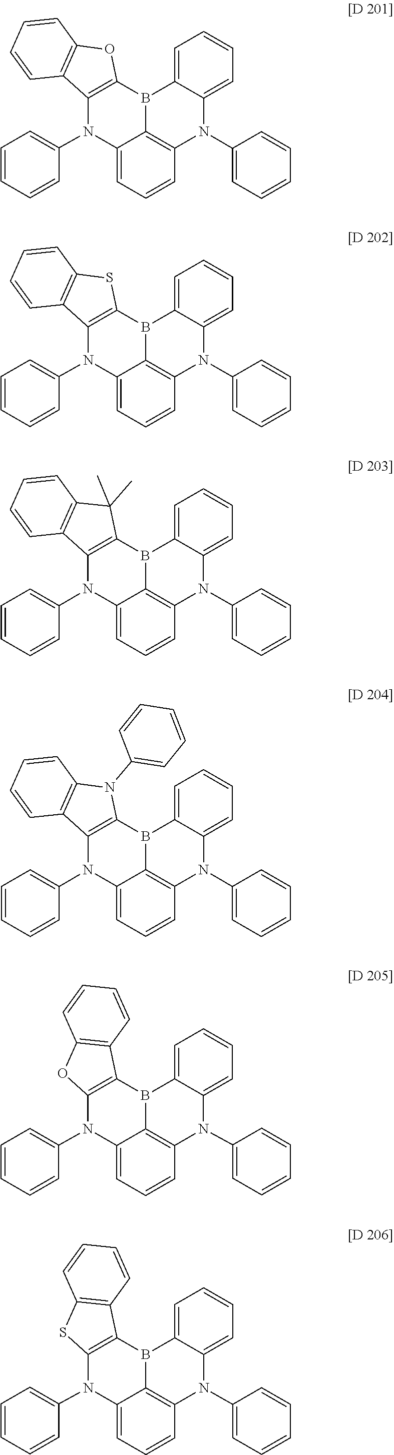 [SMILES: c1ccc(N2c3ccccc3B3c4oc5ccccc5c4N(c4ccccc4)c4cccc2c43)cc1 ; c1ccc(N2c3ccccc3B3c4sc5ccccc5c4N(c4ccccc4)c4cccc2c43)cc1 ; CC1(C)C2=C(c3ccccc31)N(c1ccccc1)c1cccc3c1B2c1ccccc1N3c1ccccc1 ; c1ccc(N2c3ccccc3B3c4c2cccc4N(c2ccccc2)c2c3n(-c3ccccc3)c3ccccc23)cc1 ; c1ccc(N2c3ccccc3B3c4c2cccc4N(c2ccccc2)c2oc4ccccc4c23)cc1 ; c1ccc(N2c3ccccc3B3c4c2cccc4N(c2ccccc2)c2sc4ccccc4c23)cc1]

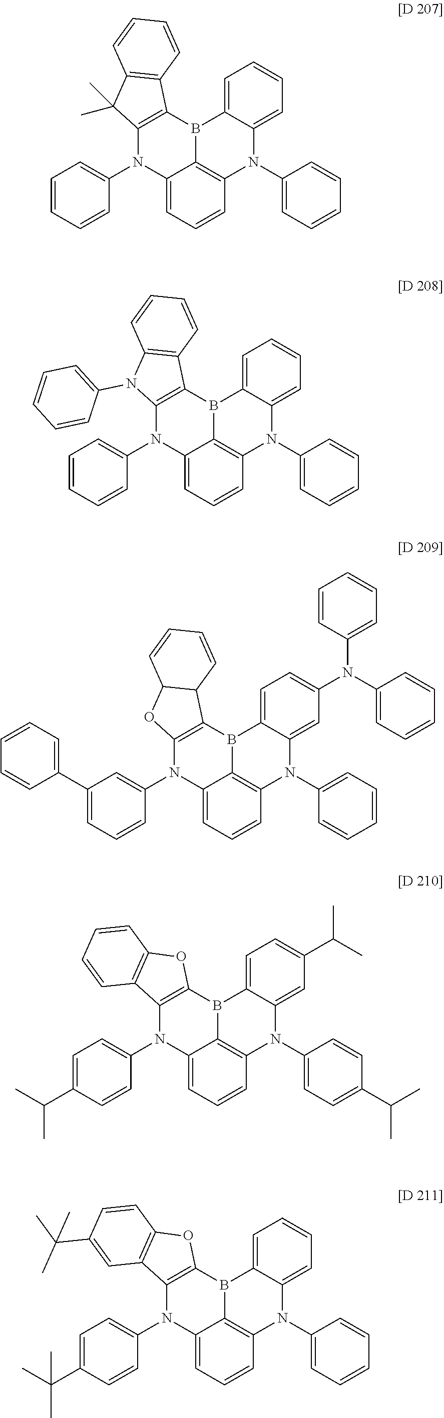

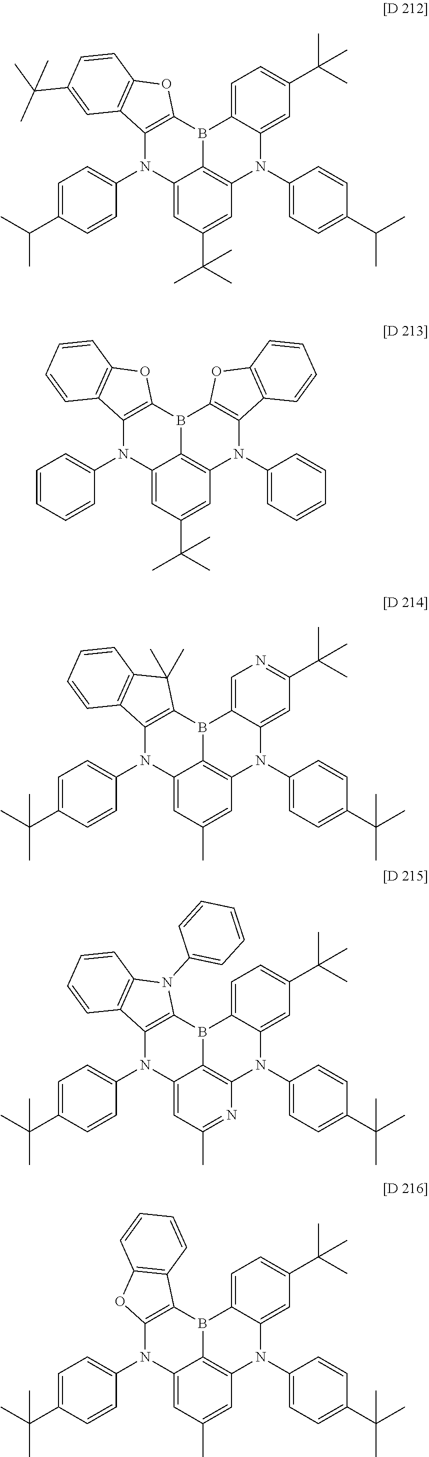

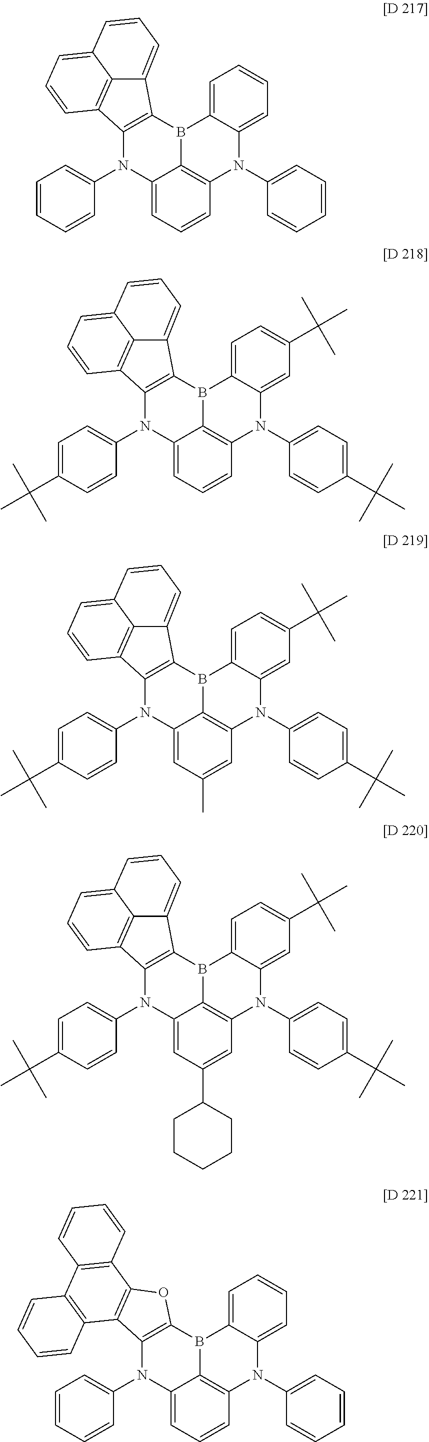

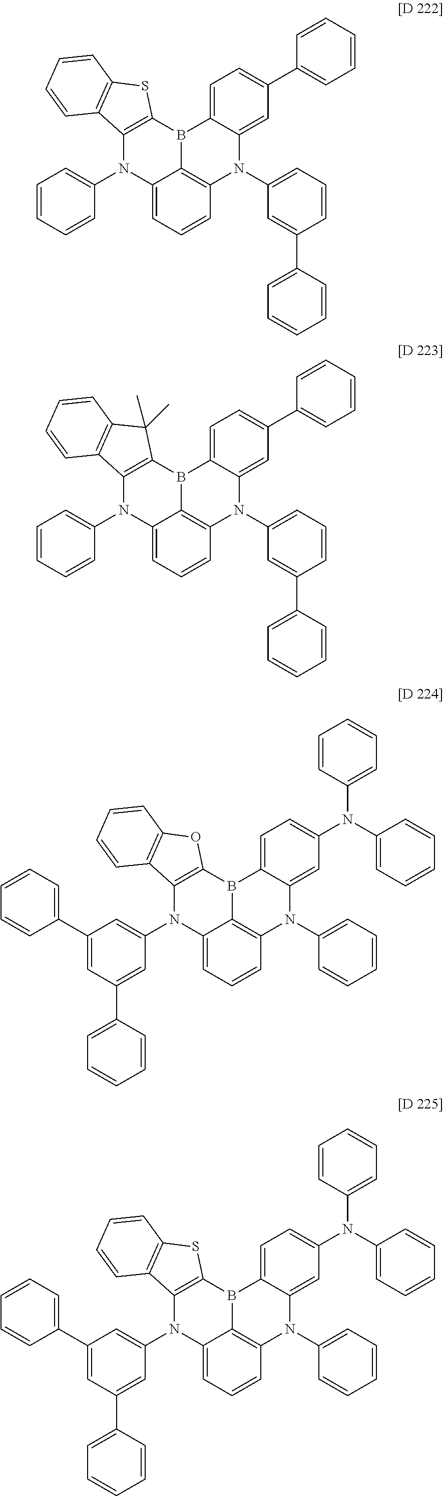

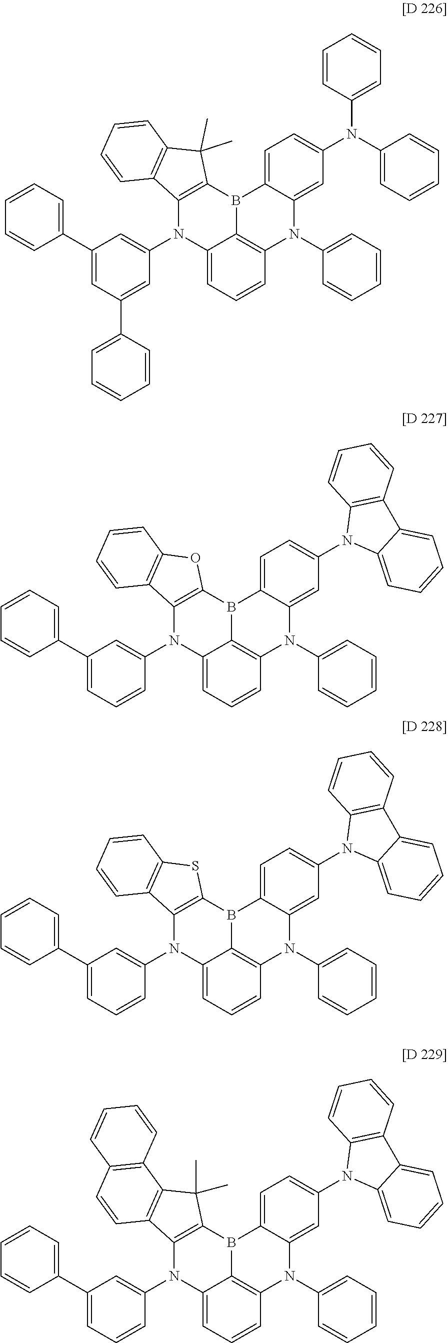 [SMILES: CC1(C)C2=C(c3ccccc31)N(c1cc(-c3ccccc3)cc(-c3ccccc3)c1)c1cccc3c1B2c1ccc(N(c2ccccc2)c2ccccc2)cc1N3c1ccccc1 ; c1ccc(-c2cccc(N3c4cccc5c4B(c4ccc(-n6c7ccccc7c7ccccc76)cc4N5c4ccccc4)c4oc5ccccc5c43)c2)cc1 ; c1ccc(-c2cccc(N3c4cccc5c4B(c4ccc(-n6c7ccccc7c7ccccc76)cc4N5c4ccccc4)c4sc5ccccc5c43)c2)cc1 ; CC1(C)C2=C(c3ccc4ccccc4c31)N(c1cccc(-c3ccccc3)c1)c1cccc3c1B2c1ccc(-n2c4ccccc4c4ccccc42)cc1N3c1ccccc1]

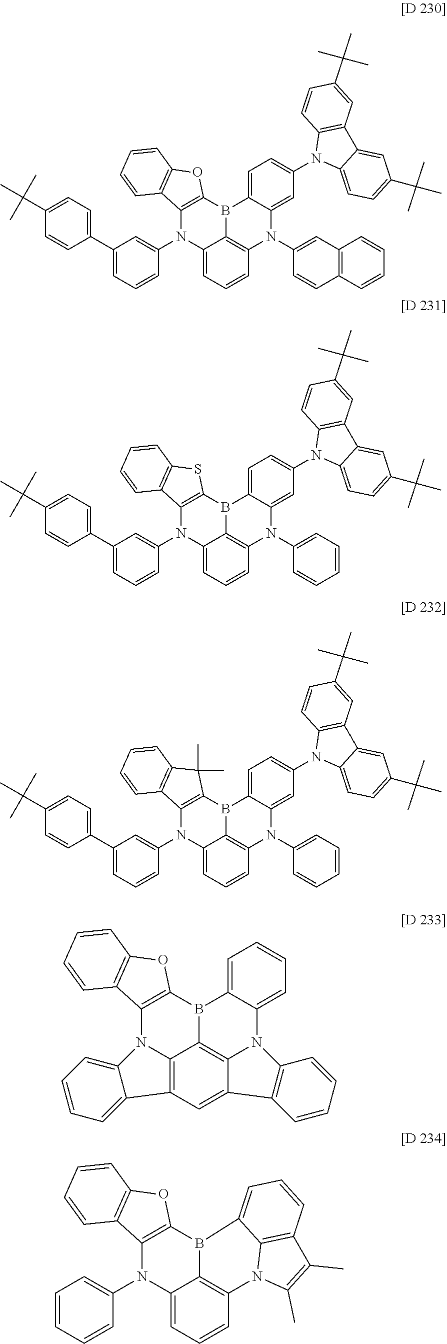

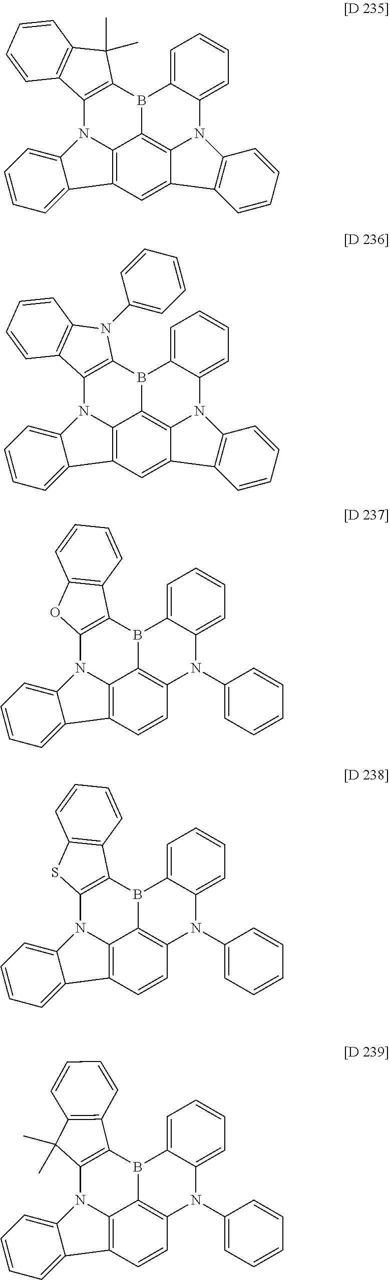

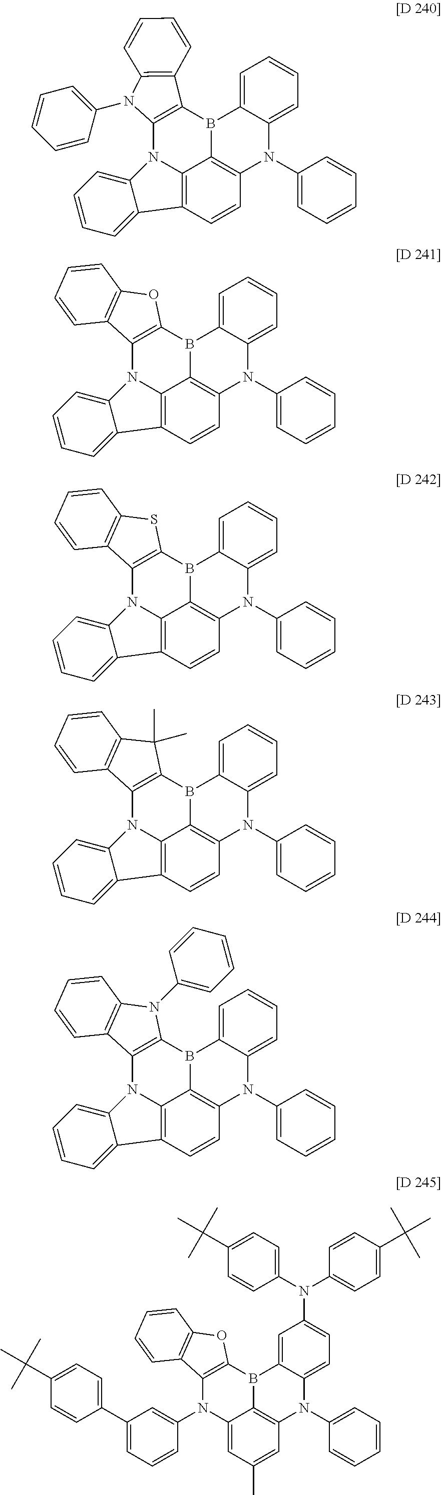

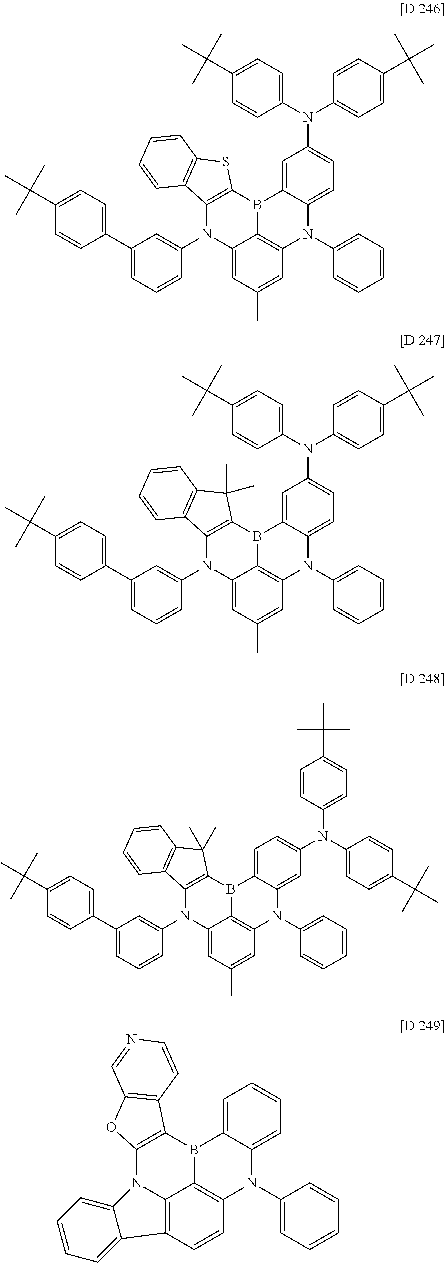

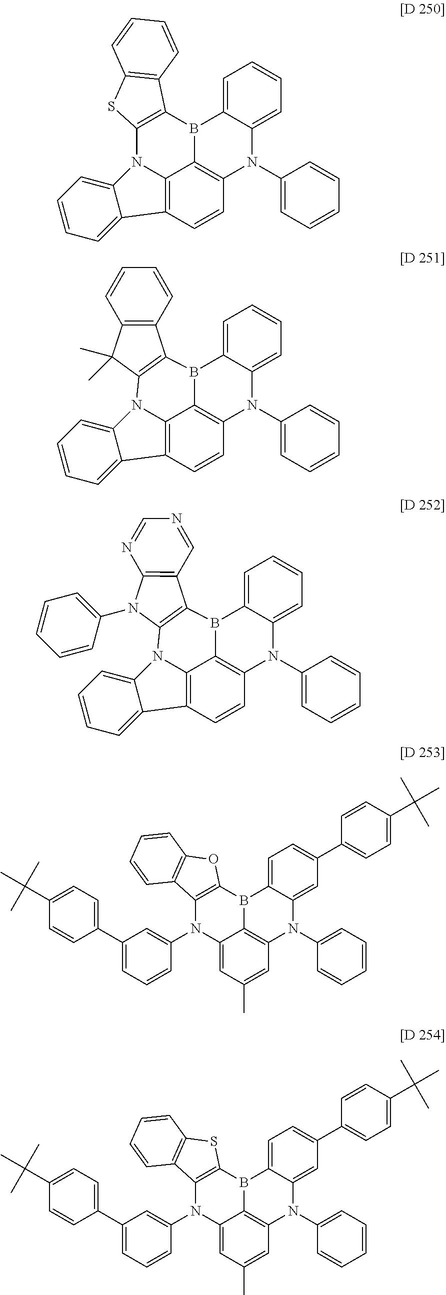

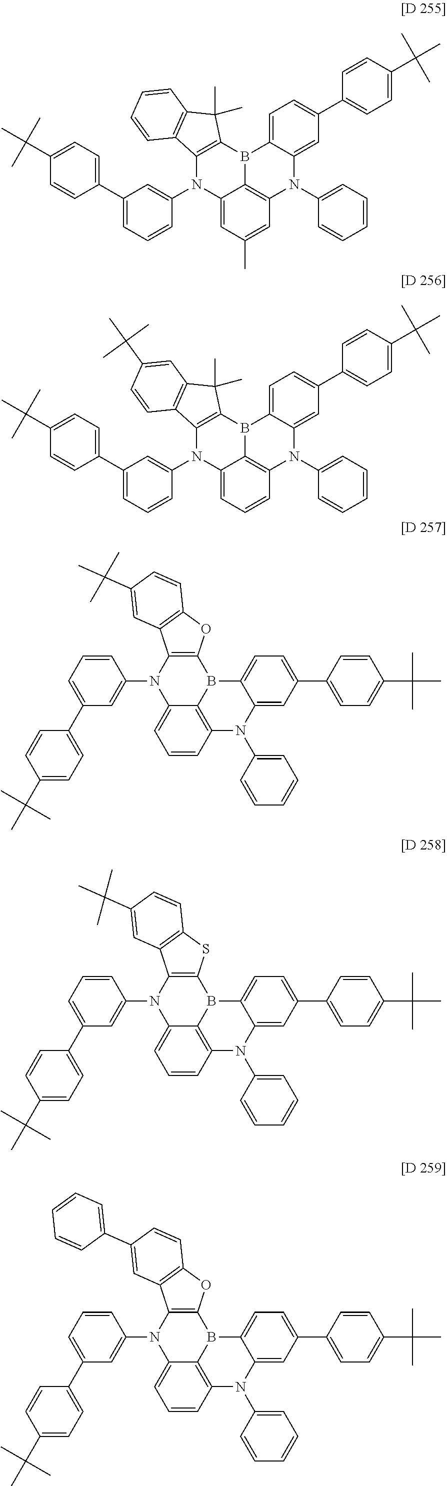

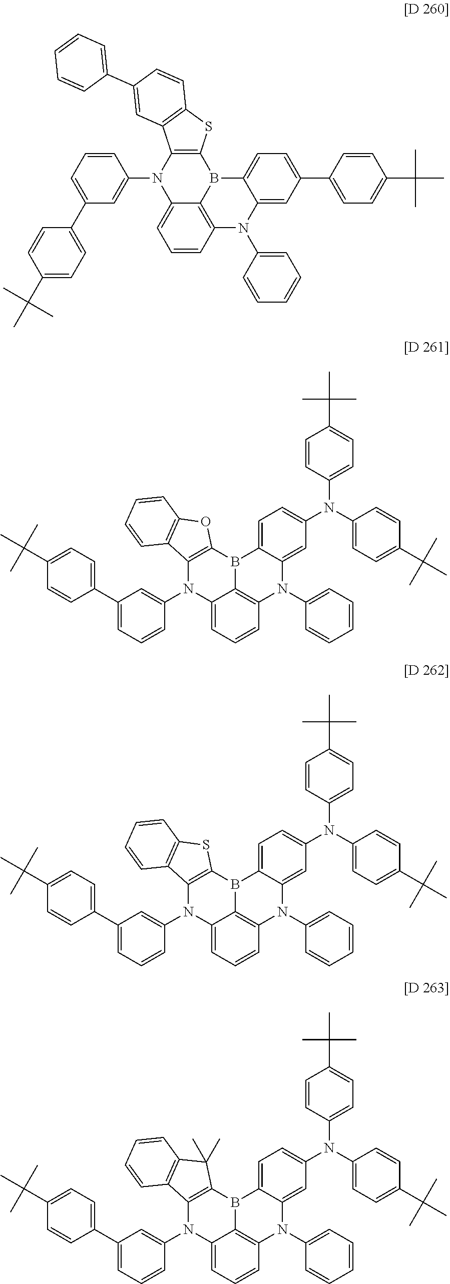

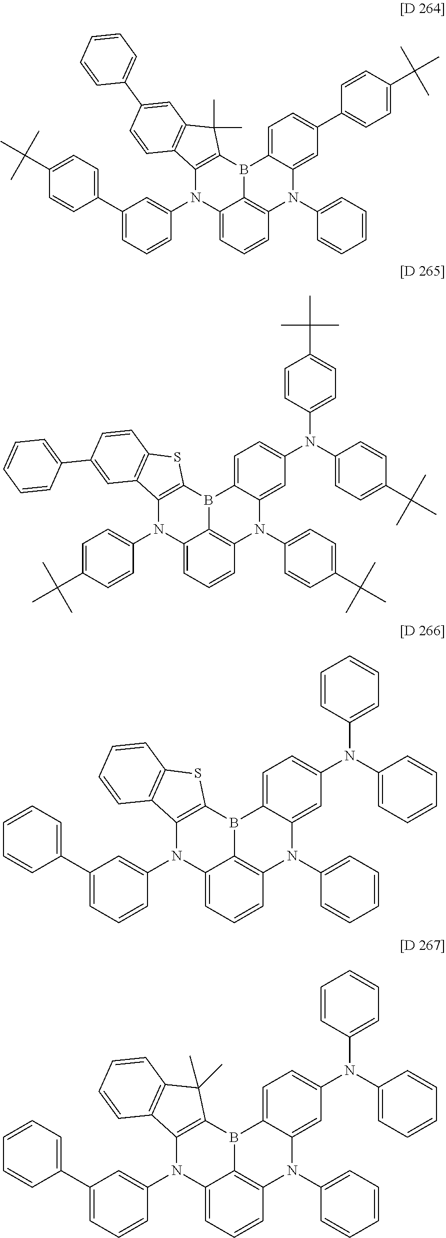 [SMILES: CC(C)(C)c1ccc(-c2cccc(N3C4=C(B5c6ccc(-c7ccc(C(C)(C)C)cc7)cc6N(c6ccccc6)c6cccc3c65)C(C)(C)c3cc(-c5ccccc5)ccc34)c2)cc1 ; CC(C)(C)c1ccc(N(c2ccc(C(C)(C)C)cc2)c2ccc3c(c2)N(c2ccc(C(C)(C)C)cc2)c2cccc4c2B3c2sc3ccc(-c5ccccc5)cc3c2N4c2ccc(C(C)(C)C)cc2)cc1 ; c1ccc(-c2cccc(N3c4cccc5c4B(c4ccc(N(c6ccccc6)c6ccccc6)cc4N5c4ccccc4)c4sc5ccccc5c43)c2)cc1 ; CC1(C)C2=C(c3ccccc31)N(c1cccc(-c3ccccc3)c1)c1cccc3c1B2c1ccc(N(c2ccccc2)c2ccccc2)cc1N3c1ccccc1]

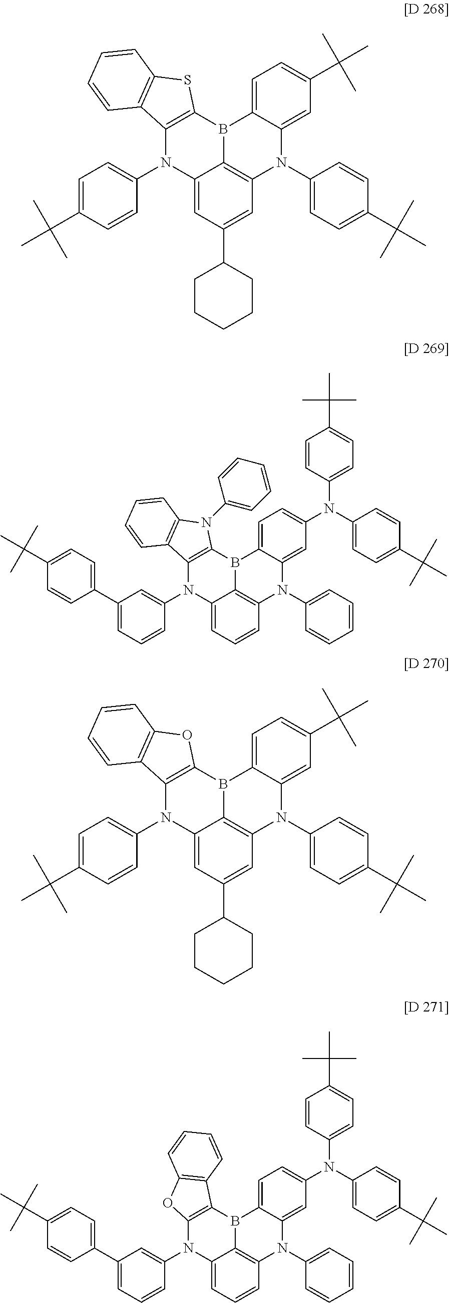

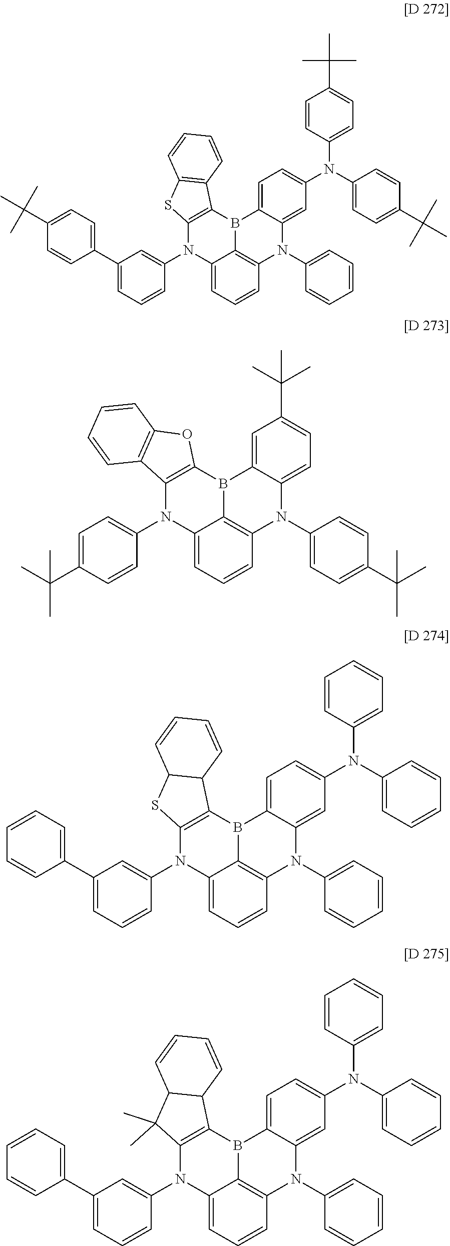

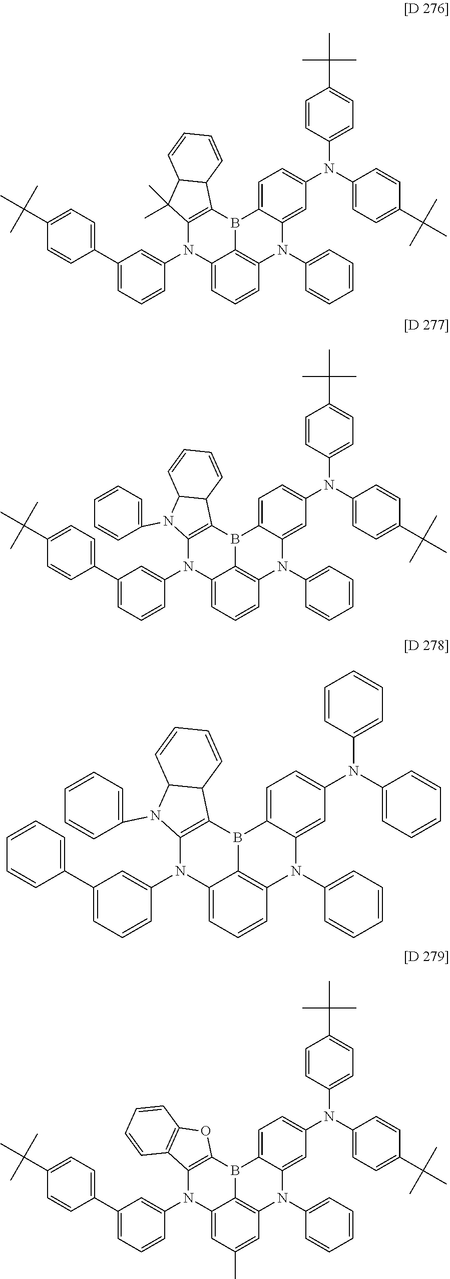

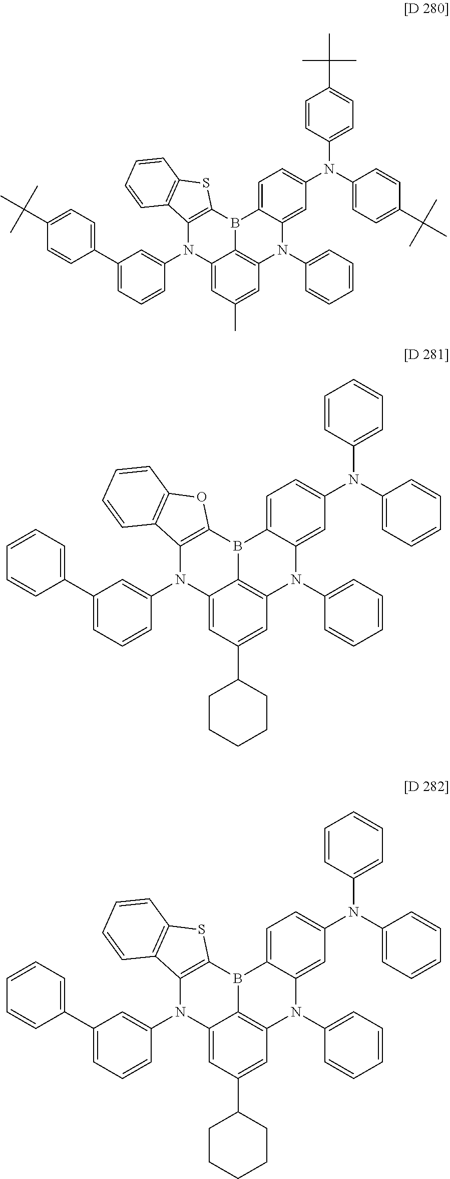 [SMILES: Cc1cc2c3c(c1)N(c1cccc(-c4ccc(C(C)(C)C)cc4)c1)c1c(sc4ccccc14)B3c1ccc(N(c3ccc(C(C)(C)C)cc3)c3ccc(C(C)(C)C)cc3)cc1N2c1ccccc1 ; c1ccc(-c2cccc(N3c4cc(C5CCCCC5)cc5c4B(c4ccc(N(c6ccccc6)c6ccccc6)cc4N5c4ccccc4)c4oc5ccccc5c43)c2)cc1 ; c1ccc(-c2cccc(N3c4cc(C5CCCCC5)cc5c4B(c4ccc(N(c6ccccc6)c6ccccc6)cc4N5c4ccccc4)c4sc5ccccc5c43)c2)cc1]

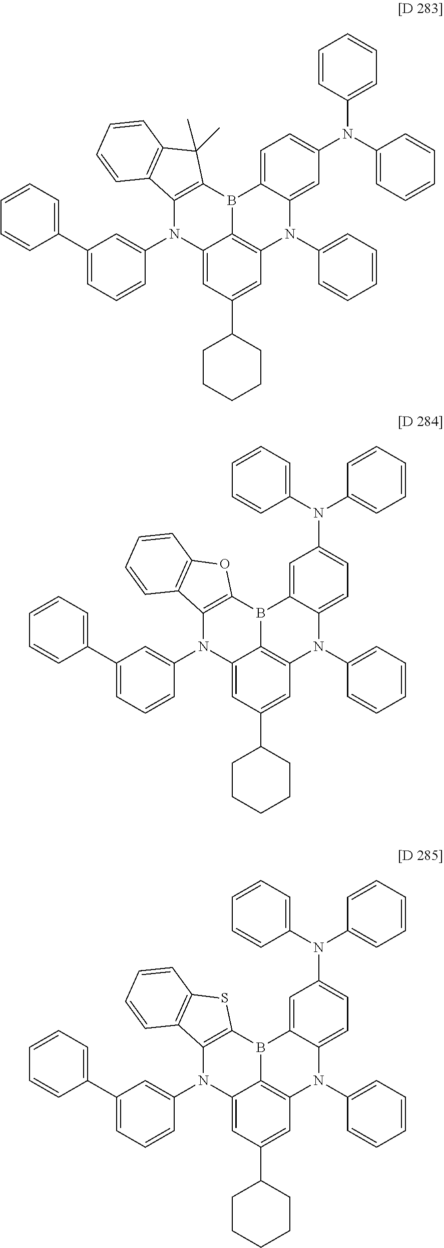 [SMILES: CC1(C)C2=C(c3ccccc31)N(c1cccc(-c3ccccc3)c1)c1cc(C3CCCCC3)cc3c1B2c1ccc(N(c2ccccc2)c2ccccc2)cc1N3c1ccccc1 ; c1ccc(-c2cccc(N3c4cc(C5CCCCC5)cc5c4B(c4cc(N(c6ccccc6)c6ccccc6)ccc4N5c4ccccc4)c4oc5ccccc5c43)c2)cc1 ; c1ccc(-c2cccc(N3c4cc(C5CCCCC5)cc5c4B(c4cc(N(c6ccccc6)c6ccccc6)ccc4N5c4ccccc4)c4sc5ccccc5c43)c2)cc1]

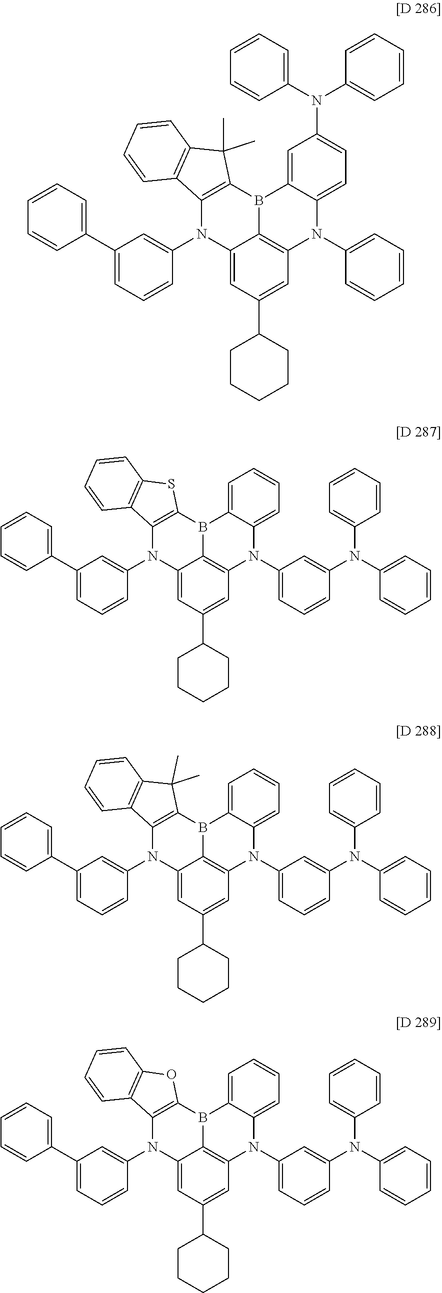 [SMILES: CC1(C)C2=C(c3ccccc31)N(c1cccc(-c3ccccc3)c1)c1cc(C3CCCCC3)cc3c1B2c1cc(N(c2ccccc2)c2ccccc2)ccc1N3c1ccccc1 ; c1ccc(-c2cccc(N3c4cc(C5CCCCC5)cc5c4B(c4ccccc4N5c4cccc(N(c5ccccc5)c5ccccc5)c4)c4sc5ccccc5c43)c2)cc1 ; CC1(C)C2=C(c3ccccc31)N(c1cccc(-c3ccccc3)c1)c1cc(C3CCCCC3)cc3c1B2c1ccccc1N3c1cccc(N(c2ccccc2)c2ccccc2)c1 ; c1ccc(-c2cccc(N3c4cc(C5CCCCC5)cc5c4B(c4ccccc4N5c4cccc(N(c5ccccc5)c5ccccc5)c4)c4oc5ccccc5c43)c2)cc1]

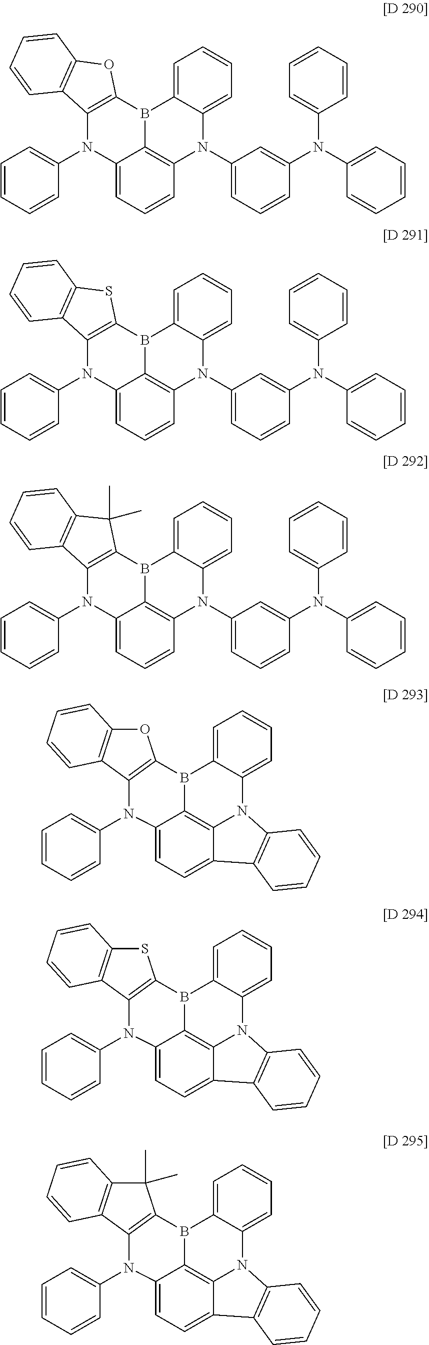

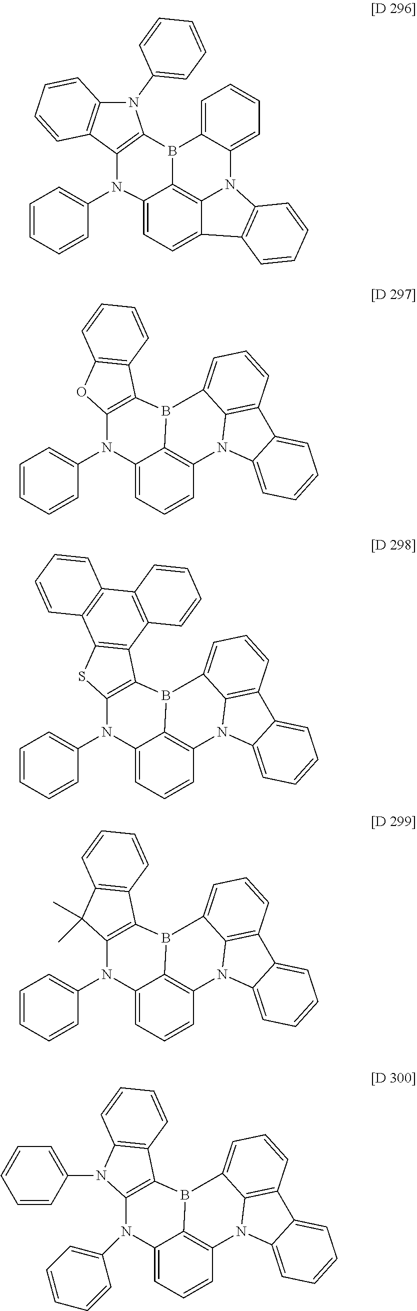

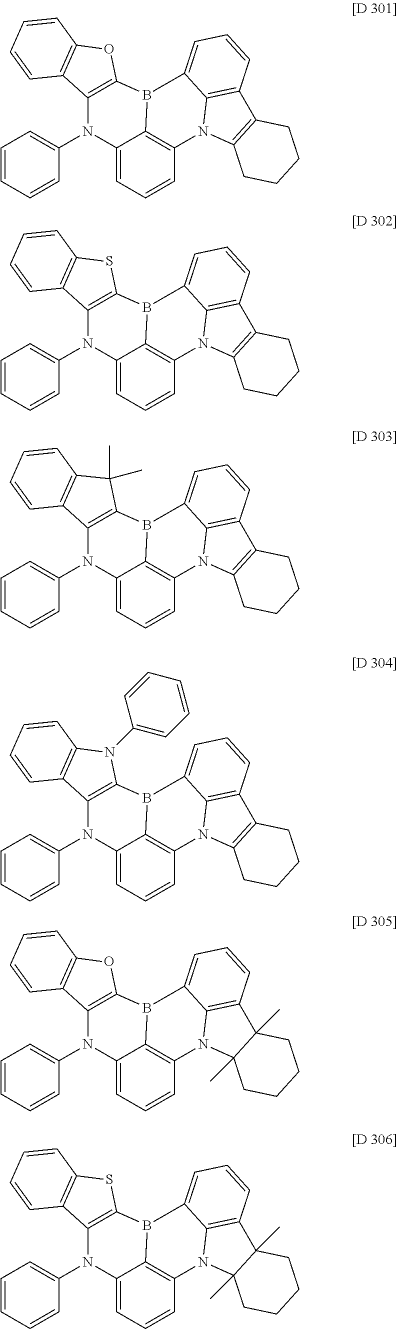

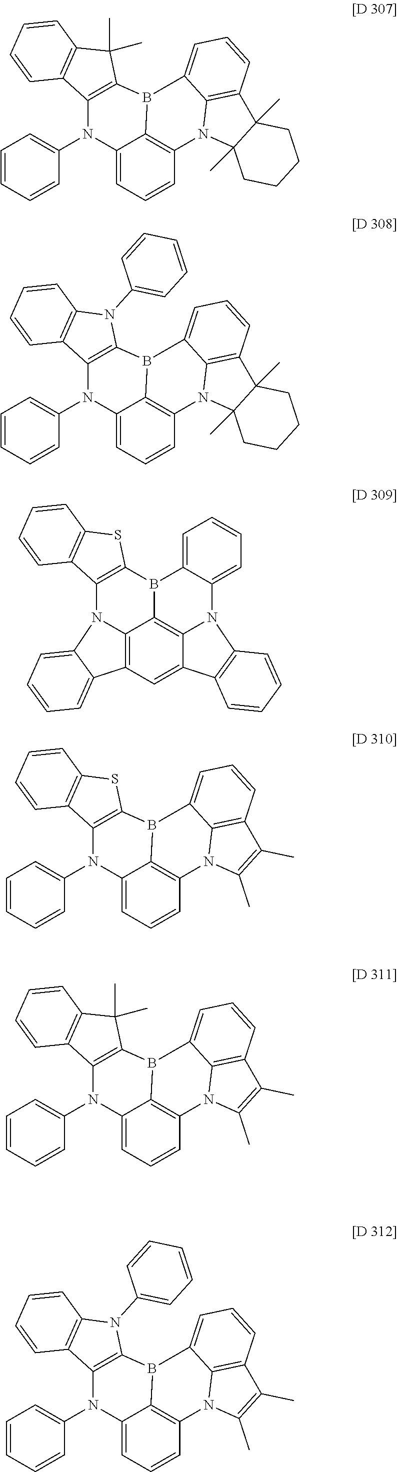

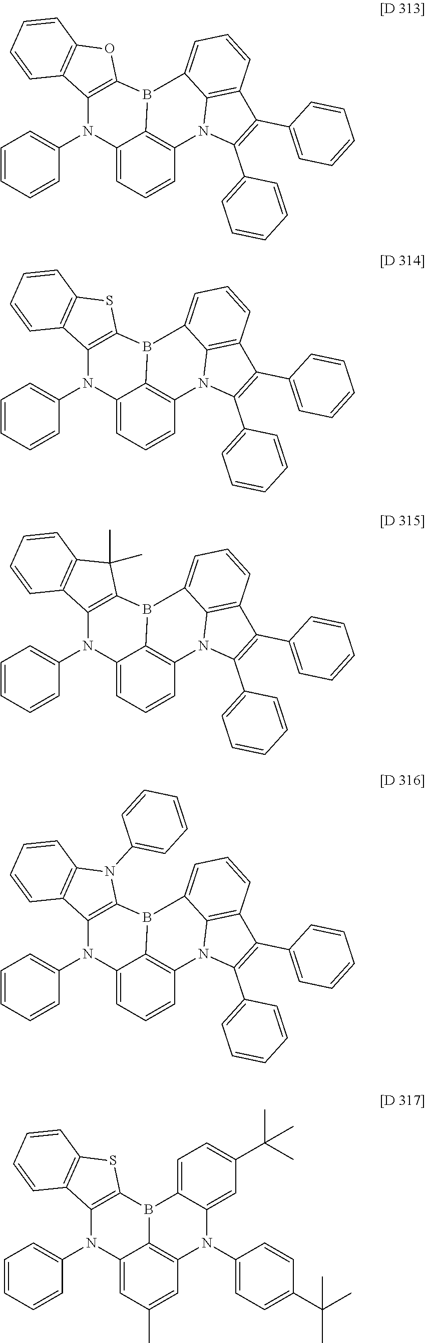 [SMILES: c1ccc(-c2c(-c3ccccc3)n3c4c(cccc24)B2c4oc5ccccc5c4N(c4ccccc4)c4cccc-3c42)cc1 ; c1ccc(-c2c(-c3ccccc3)n3c4c(cccc24)B2c4sc5ccccc5c4N(c4ccccc4)c4cccc-3c42)cc1 ; CC1(C)C2=C(c3ccccc31)N(c1ccccc1)c1cccc3c1B2c1cccc2c(-c4ccccc4)c(-c4ccccc4)n-3c12 ; c1ccc(-c2c(-c3ccccc3)n3c4c(cccc24)B2c4c(cccc4-3)N(c3ccccc3)c3c2n(-c2ccccc2)c2ccccc32)cc1 ; Cc1cc2c3c(c1)N(c1ccccc1)c1c(sc4ccccc14)B3c1ccc(C(C)(C)C)cc1N2c1ccc(C(C)(C)C)cc1]

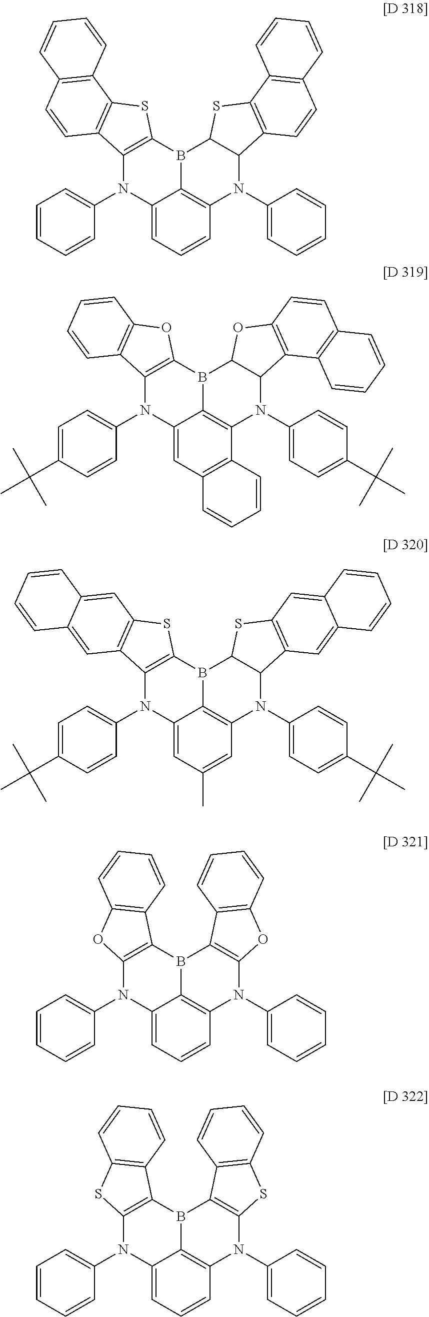

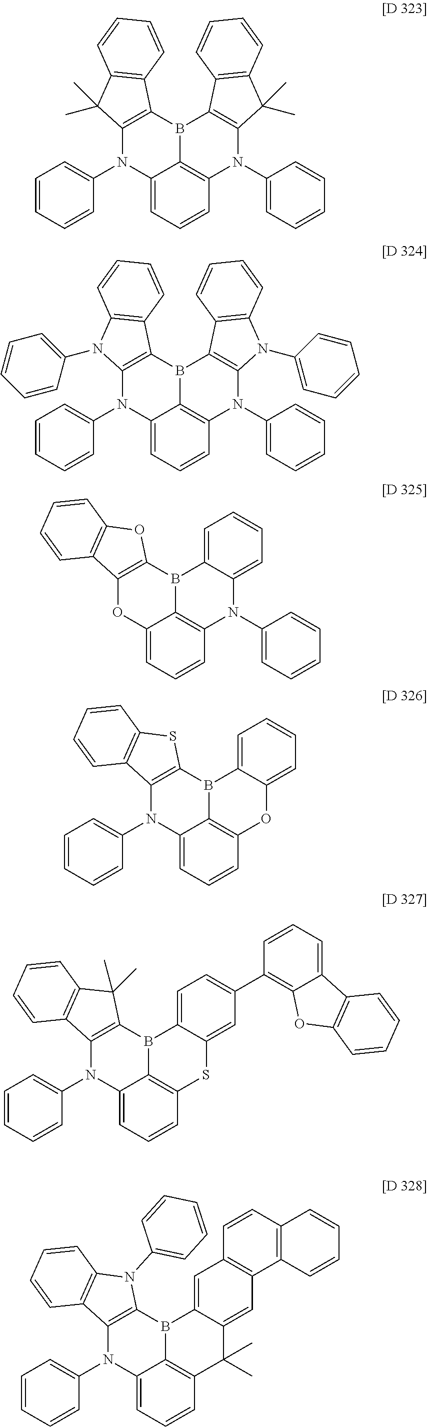

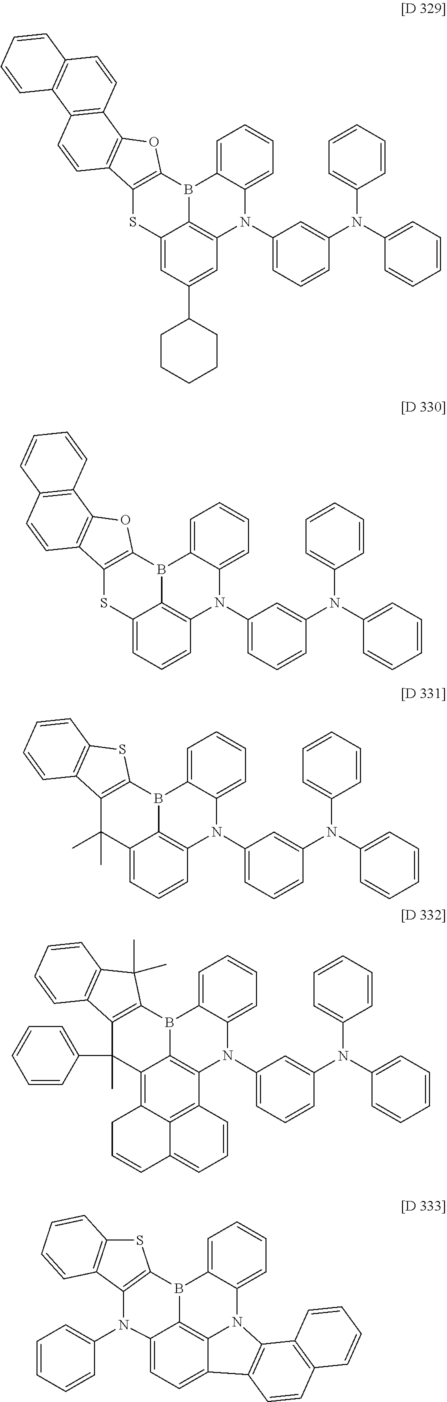 [SMILES: c1ccc(N(c2ccccc2)c2cccc(N3c4ccccc4B4c5oc6c(ccc7c8ccccc8ccc76)c5Sc5cc(C6CCCCC6)cc3c54)c2)cc1 ; c1ccc(N(c2ccccc2)c2cccc(N3c4ccccc4B4c5oc6c(ccc7ccccc76)c5Sc5cccc3c54)c2)cc1 ; CC1(C)c2cccc3c2B(c2ccccc2N3c2cccc(N(c3ccccc3)c3ccccc3)c2)c2sc3ccccc3c21 ; CC1(C)C2=C(c3ccccc31)C(C)(c1ccccc1)c1c3c(c4cccc5c4c1CC=C5)N(c1cccc(N(c4ccccc4)c4ccccc4)c1)c1ccccc1B23 ; c1ccc(N2c3ccc4c5ccc6ccccc6c5n5c4c3B(c3ccccc3-5)c3sc4ccccc4c32)cc1]

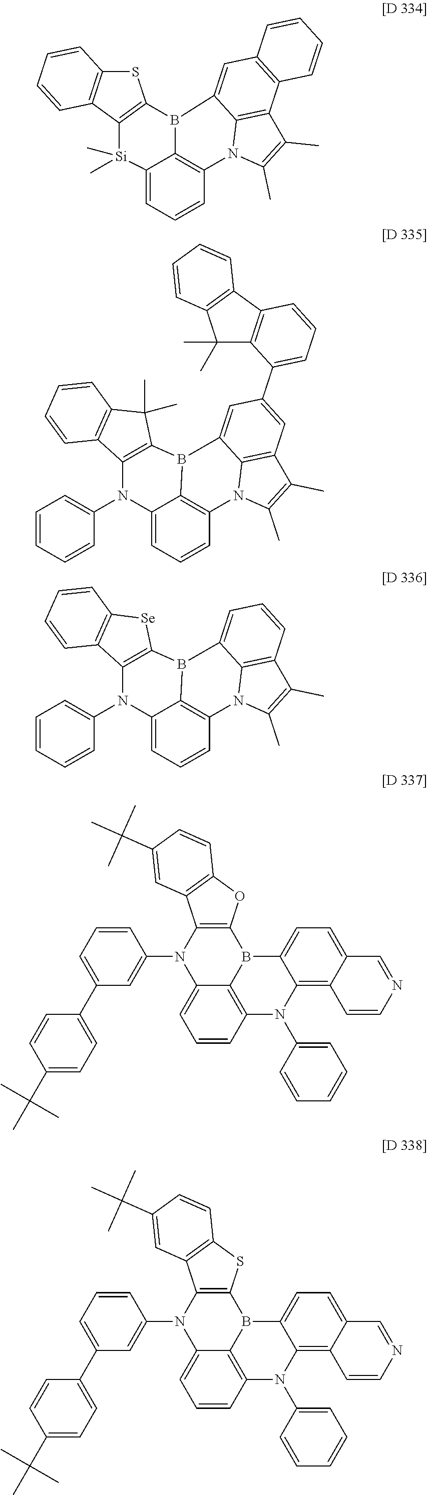

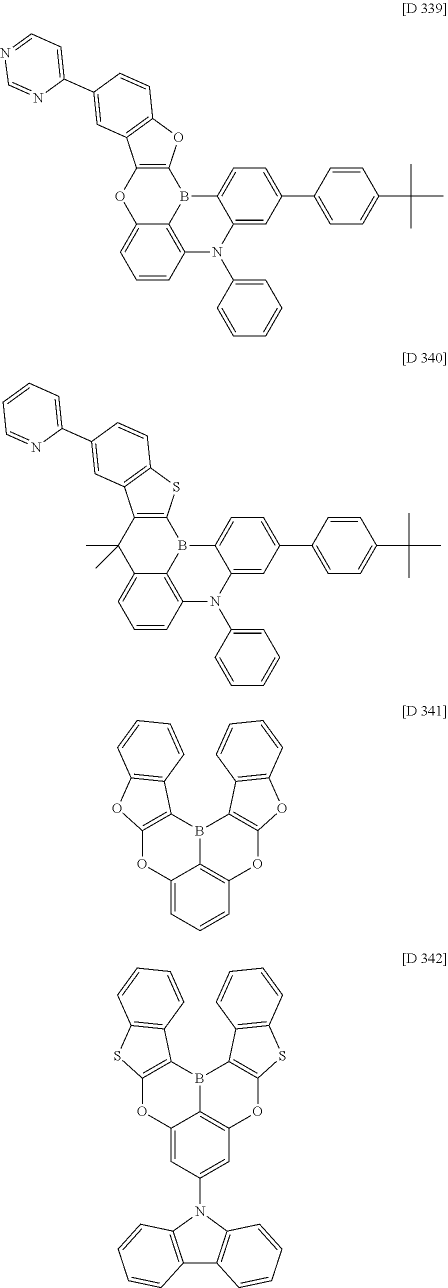

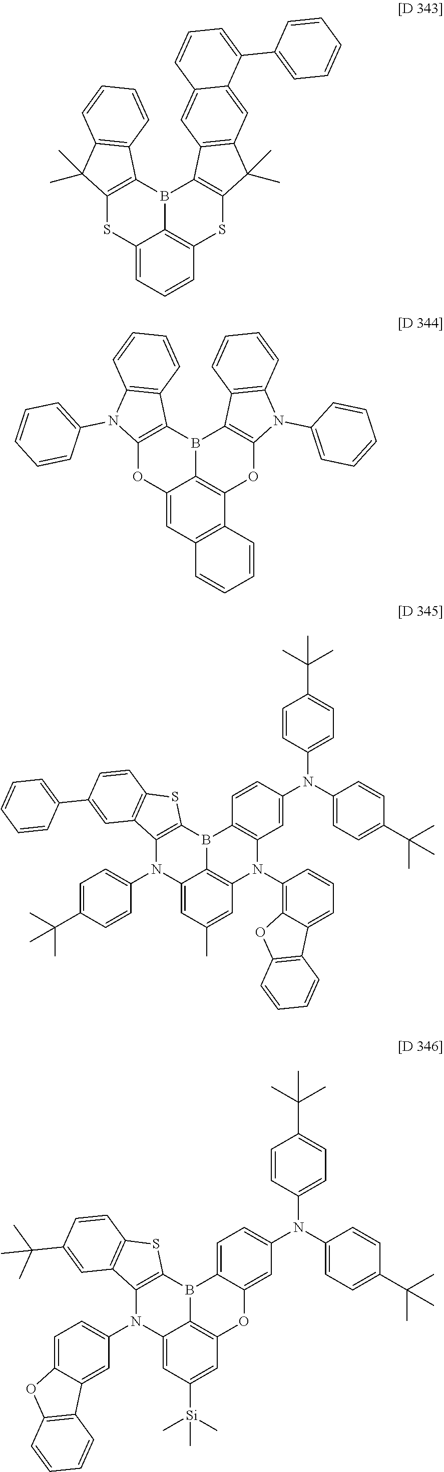

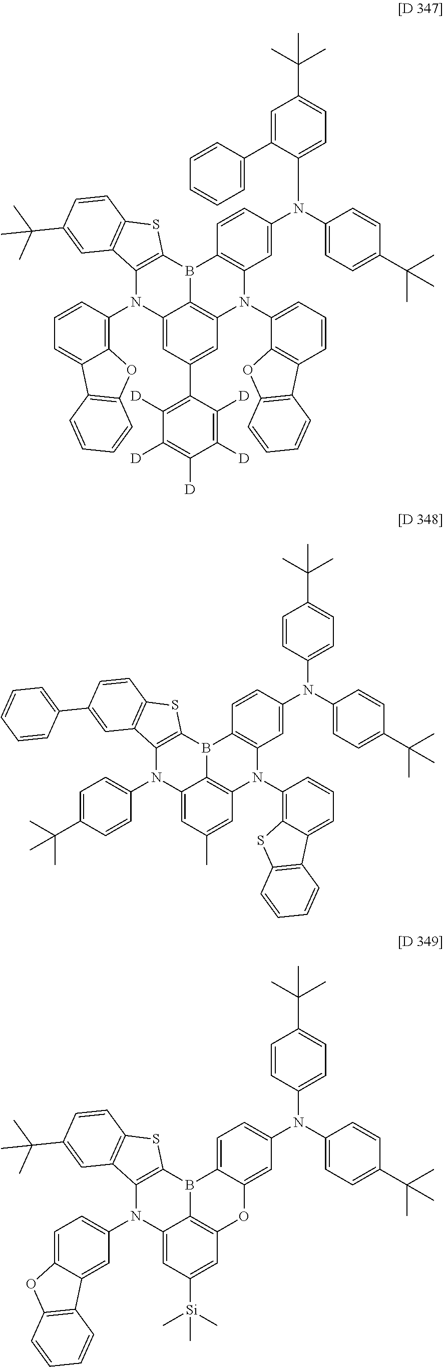

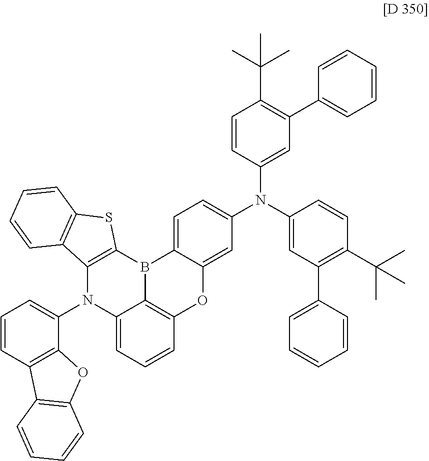 [SMILES: CC(C)(C)c1ccc(N(c2ccc3c(c2)Oc2cccc4c2B3c2sc3ccccc3c2N4c2cccc3c2oc2ccccc23)c2ccc(C(C)(C)C)c(-c3ccccc3)c2)cc1-c1ccccc1]

The amount of the fluorescent or phosphorescent dopant may be 0.01 parts by weight to 20 parts by weight based on 100 parts by weight of the host.

The organic electroluminescent material containing the compound represented by [Formula A] in the solution may be contained in an amount of 0.5% by weight or more, preferably 1.0% by weight or more, and more preferably 2.0% by weight or more, but is not limited thereto.

Hereinafter, a method for manufacturing an organic electroluminescent device according to an embodiment of the present disclosure will be described with reference to FIG. 1.

A substrate 10 may be prepared. The substrate 10 may be an organic substrate or a transparent plastic substrate with excellent transparency, surface smoothness, ease of handling, and waterproofness, but is not limited thereto and may include a substrate commonly used in organic electroluminescent devices.

The first electrode 20 may be formed by coating a material for an anode electrode on a top surface of the substrate 10. The material for an anode electrode may include a material which is transparent and has excellent conductivity, for example, indium tin oxide (ITO), indium zinc oxide (IZO), tin oxide (SnO2), and/or zinc oxide (ZnO).

The hole injection layer 30 may be formed by performing vacuum thermal deposition or spin coating of a hole injection layer material on a top surface of the first electrode 20. The hole transport layer 40 may be formed by performing vacuum thermal evaporation or spin coating of a hole transport layer material on a top surface of the hole injection layer 30.

An electron blocking layer (not shown) may be formed by selectively performing vacuum thermal deposition or spin coating of an electron blocking layer material on a top surface of the hole transport layer 40. The electron blocking layer may prevent electrons injected from the electron injection layer 70 from passing through the light emitting layer 50 and entering the hole transport layer 40, thereby improving the lifespan and efficiency of the device. The electron blocking layer may be formed at an appropriate portion between the light emitting layer 50 and the hole injection layer 30, and preferably between the light emitting layer 50 and the hole transport layer 40.

The light emitting layer 50 may be formed on the top surface of the hole transport layer 40 or the electron blocking layer. The light emitting layer 50 may be formed using a solution containing the organic electroluminescent material and the solvent. More specifically, the light emitting layer 50 may be formed by applying the solution to the top surface of the hole transport layer 40 by any one of a spin coating method, a dip coating method, a doctor blade coating method, a spray coating method, a roll coating method, inkjet printing, and screen printing.

According to one embodiment of the present disclosure, the light emitting layer 50 may have a thickness of 50 Å to 2,000 Å.

A hole blocking layer (not shown) may be selectively formed on a top surface of the light emitting layer 50 by a vacuum deposition method or a spin coating method. The hole blocking layer may serve to prevent holes from passing through the light emitting layer 50 and flowing into the second electrode 80 by comprising a hole blocking material with a very low highest occupied molecular orbital (HOMO) level. This is because when holes pass through the light emitting layer 50 and flow into the second electrode 80, the lifespan and efficiency of the organic electroluminescent device are reduced. The hole blocking material is not particularly limited, but may have a higher ionization potential than the organic electroluminescent material while having an electron transport ability. The hole blocking material may include, for example, BAIq, BCP, TPBI, etc.

The electron injection layer 70 may be formed after depositing the electron transport layer 60 on a top surface of the light emitting layer 50 or the hole blocking layer through a vacuum deposition method or a spin coating method, and the second electrode 80 may be formed by performing vacuum thermal deposition of a metal for a cathode electrode on a top surface of the electron injection layer 70. The metal for a cathode electrode may include, for example, lithium (Li), magnesium (Mg), aluminum (Al), aluminum-lithium (Al—Li), calcium (Ca), magnesium-indium (Mg—In), magnesium-silver (Mg—Ag), etc. When manufacturing a top-emitting organic electroluminescent device, the metal for a cathode electrode may include indium tin oxide (ITO) or indium zinc oxide (IZO).

An organic electroluminescent device according to one embodiment of the present disclosure may be manufactured by the above-described manufacturing method.

Hereinafter, an organic electroluminescent device according to the present disclosure will be described with reference to preferred examples. However, these examples are for illustrating the present disclosure in more detail, and it will be apparent to those skilled in the art that the scope of the present disclosure is not limited thereto.

### Synthesis Example 1: Synthesis of Compound [13]

### Synthesis Example 1-(1): Synthesis of Intermediate 1-a

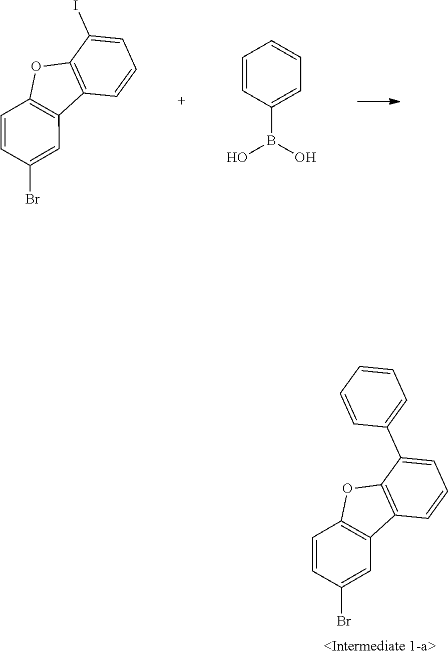 [SMILES: Brc1ccc2oc3c(I)cccc3c2c1 ; OB(O)c1ccccc1 ; Brc1ccc2oc3c(-c4ccccc4)cccc3c2c1]

16.8 g (0.045 mol) of 2-bromo-6-iododibenzofuran, 5.9 g (0.048 mol) of phenylboronic acid, 0.9 g (0.001 mol) of Pd(PPh₃)₄, and 11.1 g (0.08 mol) of potassium carbonate were put into a 2 L round bottom flask, and 100 mL of toluene, 45 mL of ethanol, and 30 mL of water were put thereinto. The reactor was refluxed and stirred to perform stirring overnight. When the reaction was completed, the temperature of the reactor was lowered to room temperature, and the reaction product was extracted with ethyl acetate. The organic layer was concentrated under reduced pressure and then separated by column chromatography. The solid was recrystallized with heptane to obtain 7.8 g (54%) of <Intermediate 1-a>.

### Synthesis Example 1-(2): Synthesis of Intermediate 1-b

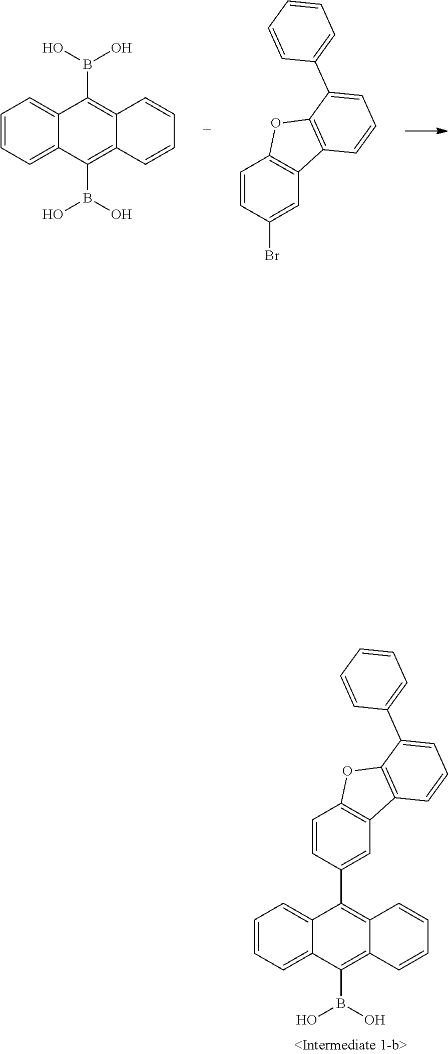 [SMILES: OB(O)c1c2ccccc2c(B(O)O)c2ccccc12 ; Brc1ccc2oc3c(-c4ccccc4)cccc3c2c1 ; OB(O)c1c2ccccc2c(-c2ccc3oc4c(-c5ccccc5)cccc4c3c2)c2ccccc12]

26.5 g (0.082 mol) of Intermediate 1-a, 1.5 g (0.001 mol) of Pd(PPh₃)₄, 18.1 g (0.13 mol) of potassium carbonate, and 18.7 g (0.07 mol) of anthracene-9,10-diboronic acid were put into a 1,000 mL four-neck round bottom flask, 250 mL of toluene, 125 mL of ethanol, and 125 mL of water were put thereinto, and the inside of the reactor was refluxed in a nitrogen atmosphere. The reaction was completed, and excess methanol was poured to filter the resulting solid. The filtered solid was filtered to obtain 20.2 g (62%) of <Intermediate 1-b>.

### Synthesis Example 1-(3): Synthesis of Intermediate 1-c

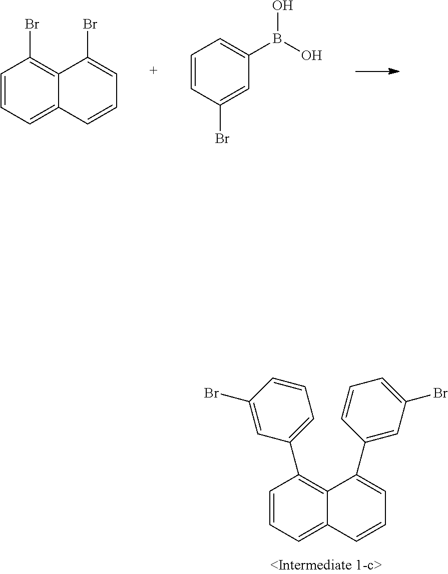 [SMILES: Brc1cccc2cccc(Br)c12 ; OB(O)c1cccc(Br)c1 ; Brc1cccc(-c2cccc3cccc(-c4cccc(Br)c4)c23)c1]

11.5 g (0.04 mol) of 1,8-dibromonaphthalene, 18.5 g (0.092 mol) of 3-bromophenylboronic acid, 0.9 g (0.001 mol) of tetrakis(triphenylphosphine)palladium, 11.1 g (0.08 mol) of potassium carbonate, 100 mL of toluene, 45 mL of methanol, and 30 mL of water were put into in a 500 mL flask. The reactor was refluxed and stirred to perform stirring overnight. When the reaction was completed, the temperature of the reactor was lowered to room temperature, and the reaction product was extracted with ethyl acetate. The organic layer was concentrated under reduced pressure and then separated by column chromatography. The solid was recrystallized with heptane to obtain 9.2 g (52%) of <Intermediate 1-c>.

### Synthesis Example 1-(4): Synthesis of Intermediate 1-d

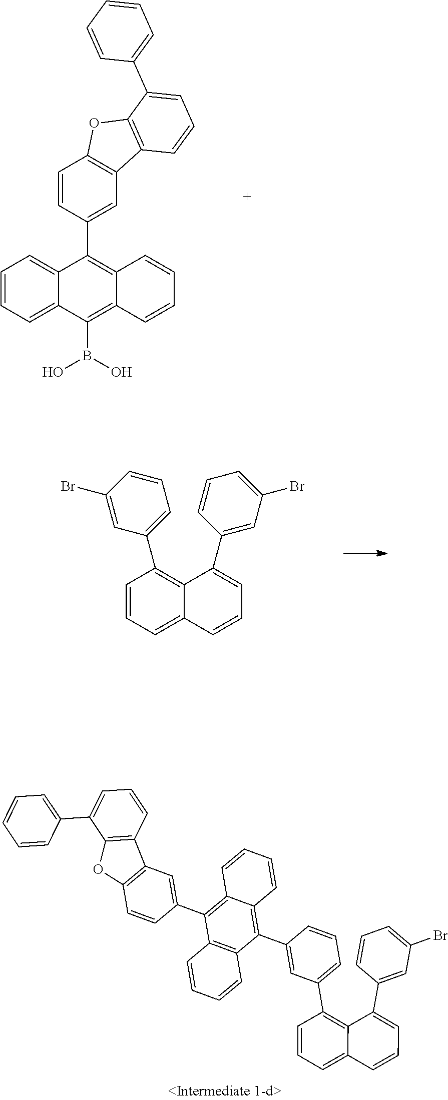 [SMILES: OB(O)c1c2ccccc2c(-c2ccc3oc4c(-c5ccccc5)cccc4c3c2)c2ccccc12 ; Brc1cccc(-c2cccc3cccc(-c4cccc(Br)c4)c23)c1 ; Brc1cccc(-c2cccc3cccc(-c4cccc(-c5c6ccccc6c(-c6ccc7oc8c(-c9ccccc9)cccc8c7c6)c6ccccc56)c4)c23)c1]

32.5 g (0.07 mol) of <Intermediate 1-b>, 32.0 g (0.073 mol) of <Intermediate 1-c>, 1.7 g (0.001 mol) of tetrakis(triphenylphosphine)palladium, 20.09 g (0.145 mol) of potassium carbonate, 125 mL of toluene, 125 mL of ethanol, and 50 mL of water were put into in a 500 mL flask, and the inside of the reactor was refluxed in a nitrogen atmosphere. The reaction was completed, and excess methanol was poured to filter the resulting solid. The filtered solid was filtered to obtain 32.1 g (59%) of <Intermediate 1-d>.

### Synthesis Example 1-(5): Synthesis of [13]

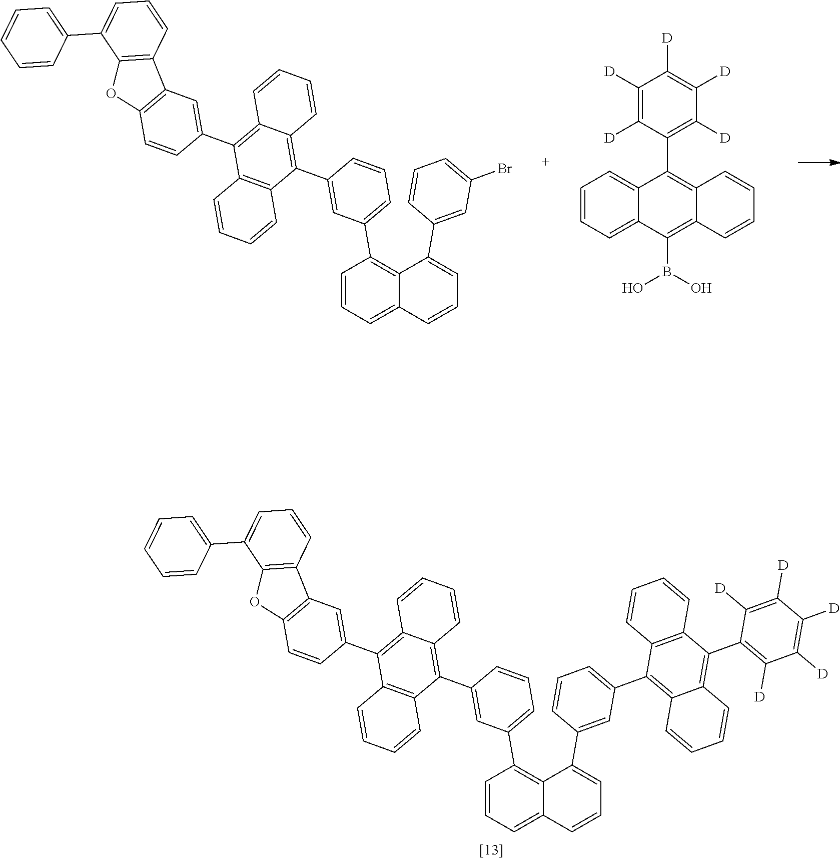 [SMILES: Brc1cccc(-c2cccc3cccc(-c4cccc(-c5c6ccccc6c(-c6ccc7oc8c(-c9ccccc9)cccc8c7c6)c6ccccc56)c4)c23)c1 ; [2H]c1c([2H])c([2H])c(-c2c3ccccc3c(B(O)O)c3ccccc23)c([2H])c1[2H] ; [2H]c1c([2H])c([2H])c(-c2c3ccccc3c(-c3cccc(-c4cccc5cccc(-c6cccc(-c7c8ccccc8c(-c8ccc9oc%10c(-c%11ccccc%11)cccc%10c9c8)c8ccccc78)c6)c45)c3)c3ccccc23)c([2H])c1[2H]]

[13] (yield 75%) was obtained by performing synthesis in the same manner except that B-[10-phenyl(D5)-9-anthracenyl]boronic acid was used instead of <Intermediate 1-b> used in Synthesis Example 1-(4) above, and <Intermediate 1-d> was used instead of <Intermediate 1-c>.

MS (MALDI-TOF): m/z 955.39 [M⁺]

### Synthesis Example 2: Synthesis of [22]

### Synthesis Example 2-(1): Synthesis of Intermediate 2-a

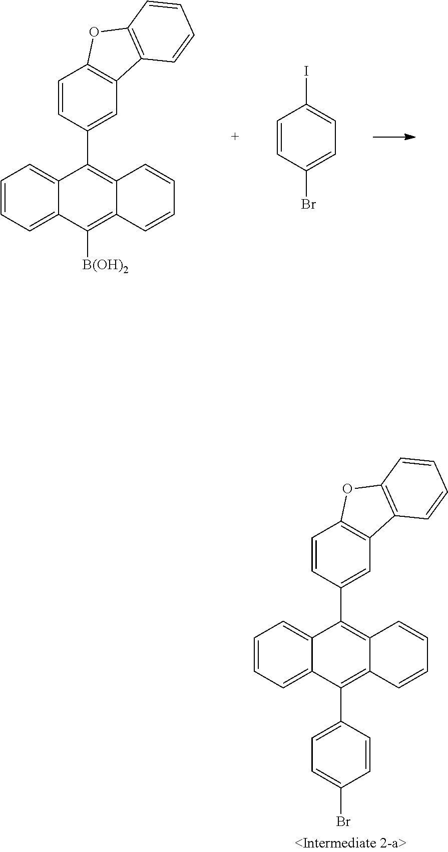 [SMILES: OB(O)c1c2ccccc2c(-c2ccc3oc4ccccc4c3c2)c2ccccc12 ; Brc1ccc(I)cc1 ; Brc1ccc(-c2c3ccccc3c(-c3ccc4oc5ccccc5c4c3)c3ccccc23)cc1]

<Intermediate 2-a> (yield 82%) was obtained by performing synthesis in the same manner except that B-[10-(2-dibenzofuranyl)-9-anthracenyl]boronic acid was used instead of <Intermediate 1-b> used in Synthesis Example 1-(4), and 1-bromo-4-iodobenzene was used instead of <Intermediate 1-c>.

### Synthesis Example 2-(2): Synthesis of Intermediate 2-b

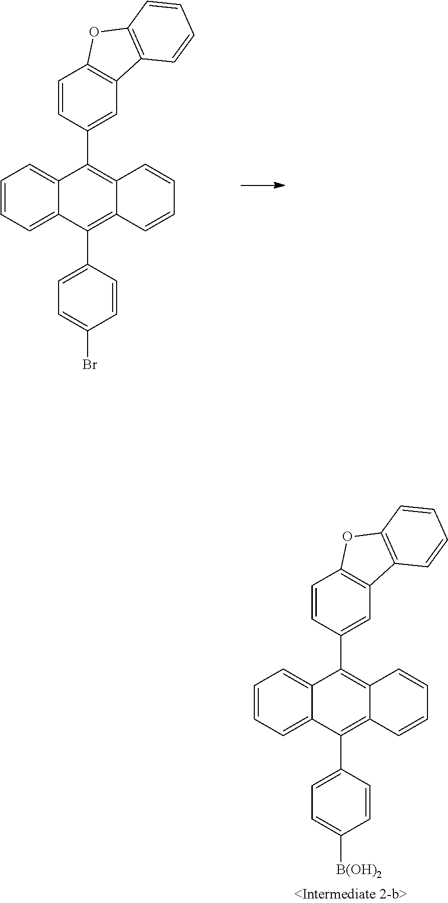 [SMILES: Brc1ccc(-c2c3ccccc3c(-c3ccc4oc5ccccc5c4c3)c3ccccc23)cc1 ; OB(O)c1ccc(-c2c3ccccc3c(-c3ccc4oc5ccccc5c4c3)c3ccccc23)cc1]

22.5 g (0.045 mol) of <Intermediate 2-a> and 145.6 mL of tetrahydrofuran were put into a 1 L flask, and the inside of the reactor was cooled to −78° C. in a nitrogen atmosphere to perform stirring. 32 mL of 1.6 M butyllithium was added dropwise, and the reaction mixture was stirred at the same temperature for 1 hour. 8 mL of trimethylborate was added dropwise, and the reaction solution was stirred at room temperature for 2 hours. The reaction was completed, 100 mL of 2 M hydrochloric acid aqueous solution was poured into the reaction product and stirred, the reaction product was extracted with 50 mL of ethyl acetate and concentrated under reduced pressure, and then excess heptane was poured thereinto, and the resulting solid was filtered to obtain 15.3 g (73%) of <Intermediate 2-b>.

### Synthesis Example 2-(3): Synthesis of Intermediate 2-c

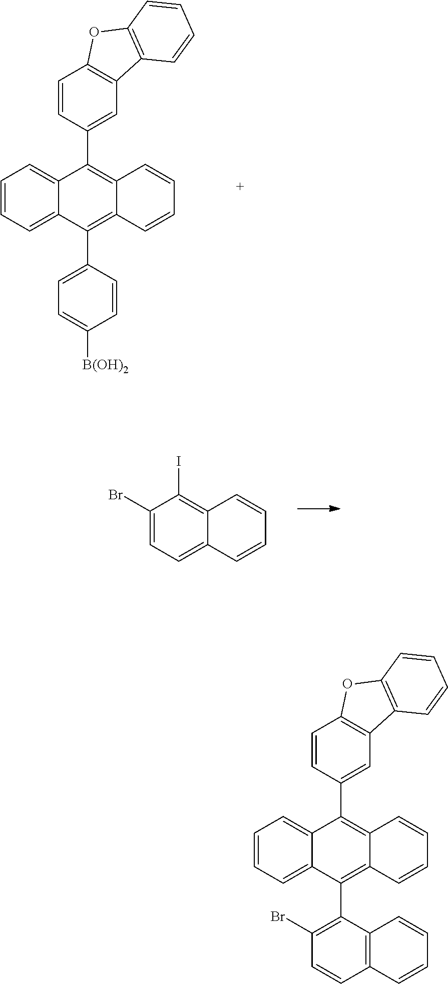 [SMILES: OB(O)c1ccc(-c2c3ccccc3c(-c3ccc4oc5ccccc5c4c3)c3ccccc23)cc1 ; Brc1ccc2ccccc2c1I ; Brc1ccc2ccccc2c1-c1c2ccccc2c(-c2ccc3oc4ccccc4c3c2)c2ccccc12]

### Intermediate 2-c

<Intermediate 2-c> (55% yield) was obtained by performing synthesis in the same manner except that <Intermediate 2-b> was used instead of <Intermediate 1-b> used in Synthesis Example 1-(4) above, and 2-bromo-1-iodonaphthalene was used instead of <Intermediate 1-c>.

### Synthesis Example 2-(4): Synthesis of Intermediate 2-d

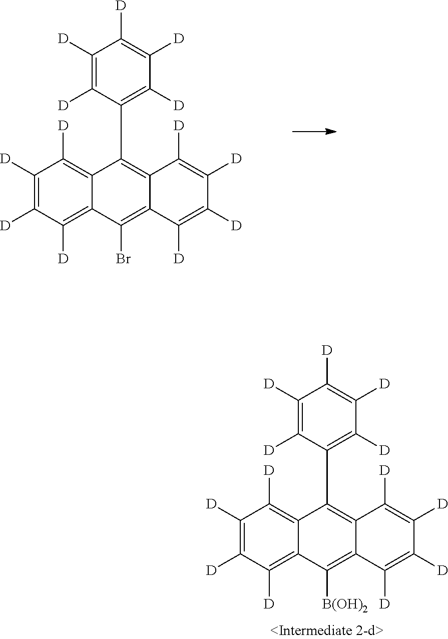 [SMILES: [2H]c1c([2H])c([2H])c(-c2c3c([2H])c([2H])c([2H])c([2H])c3c(Br)c3c([2H])c([2H])c([2H])c([2H])c23)c([2H])c1[2H] ; [2H]c1c([2H])c([2H])c(-c2c3c([2H])c([2H])c([2H])c([2H])c3c(B(O)O)c3c([2H])c([2H])c([2H])c([2H])c23)c([2H])c1[2H]]

<Intermediate 2-d> (yield 71%) was obtained by performing synthesis in the same manner except that 9-bromo-10-(phenyl(D5))anthracene (D8) was used instead of <Intermediate 2-a> used in Synthesis Example 2-(2) above.

### Synthesis Example 2-(5): Synthesis of Intermediate 2-e

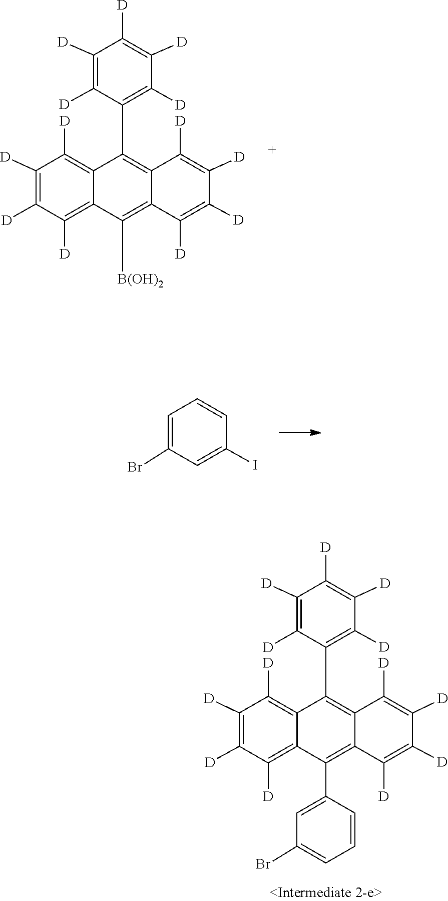 [SMILES: [2H]c1c([2H])c([2H])c(-c2c3c([2H])c([2H])c([2H])c([2H])c3c(B(O)O)c3c([2H])c([2H])c([2H])c([2H])c23)c([2H])c1[2H] ; Brc1cccc(I)c1 ; [2H]c1c([2H])c([2H])c(-c2c3c([2H])c([2H])c([2H])c([2H])c3c(-c3cccc(Br)c3)c3c([2H])c([2H])c([2H])c([2H])c23)c([2H])c1[2H]]

<Intermediate 2-e> (yield 80%) was obtained by performing synthesis in the same manner except that <Intermediate 2-d> was used instead of <Intermediate 1-b> used in Synthesis Example 1-(4) above, and 1-bromo-3-iodobenzene was used instead of <Intermediate 1-c>.

### Synthesis Example 2-(6): Synthesis of Intermediate 2-f

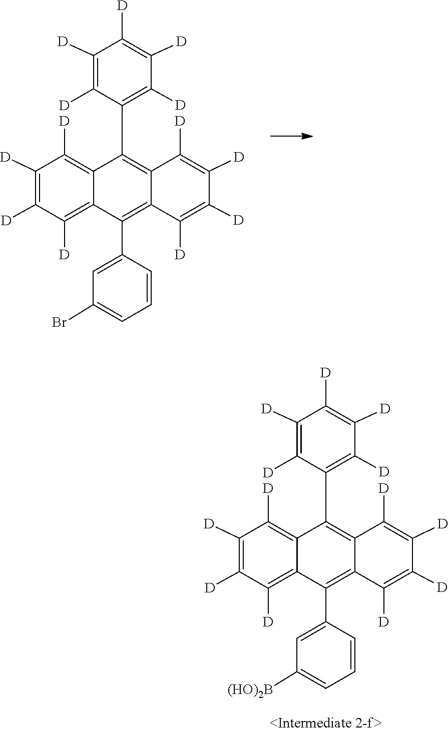 [SMILES: [2H]c1c([2H])c([2H])c(-c2c3c([2H])c([2H])c([2H])c([2H])c3c(-c3cccc(Br)c3)c3c([2H])c([2H])c([2H])c([2H])c23)c([2H])c1[2H] ; [2H]c1c([2H])c([2H])c(-c2c3c([2H])c([2H])c([2H])c([2H])c3c(-c3cccc(B(O)O)c3)c3c([2H])c([2H])c([2H])c([2H])c23)c([2H])c1[2H]]

<Intermediate 2-f> (yield 70%) was obtained by performing synthesis in the same manner except that <Intermediate 2-e> was used instead of <Intermediate 2-a> used in Synthesis Example 2-(2) above.

### Synthesis Example 2-(7): Synthesis of [22]

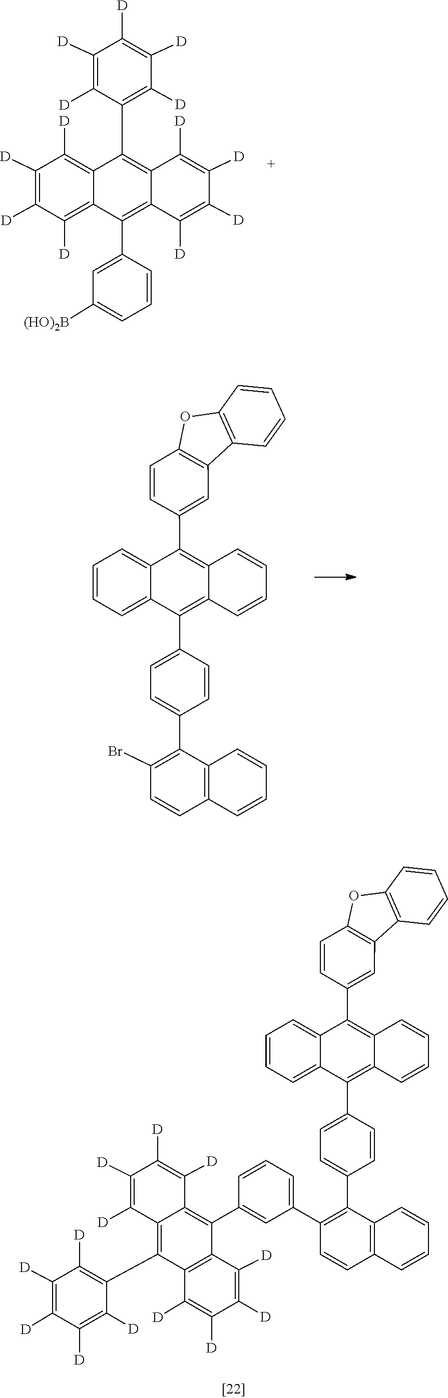 [SMILES: [2H]c1c([2H])c([2H])c(-c2c3c([2H])c([2H])c([2H])c([2H])c3c(-c3cccc(B(O)O)c3)c3c([2H])c([2H])c([2H])c([2H])c23)c([2H])c1[2H] ; Brc1ccc2ccccc2c1-c1ccc(-c2c3ccccc3c(-c3ccc4oc5ccccc5c4c3)c3ccccc23)cc1 ; [2H]c1c([2H])c([2H])c(-c2c3c([2H])c([2H])c([2H])c([2H])c3c(-c3cccc(-c4ccc5ccccc5c4-c4ccc(-c5c6ccccc6c(-c6ccc7oc8ccccc8c7c6)c6ccccc56)cc4)c3)c3c([2H])c([2H])c([2H])c([2H])c23)c([2H])c1[2H]]

[22] (yield 74%) was obtained by performing synthesis in the same manner except that <Intermediate 2-f> was used instead of <Intermediate 1-b> used in Synthesis Example 1-(4) above, and <Intermediate 2-c> was used instead of <Intermediate 1-c>.

MS (MALDI-TOF): m/z 887.41 [M⁺]

### Synthesis Example 3: Synthesis of [24]

### Synthesis Example 3-(1): Synthesis of Intermediate 3-a

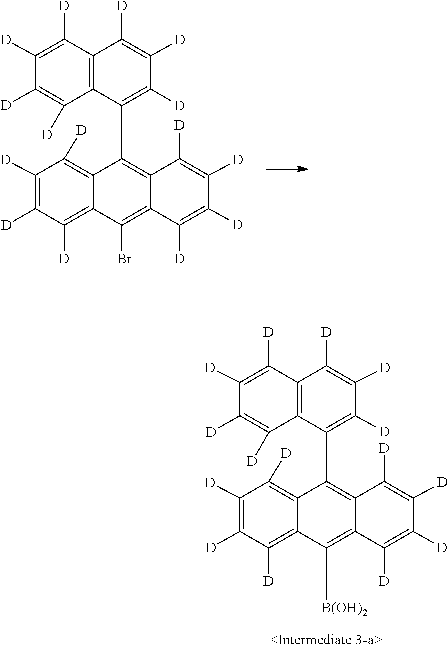 [SMILES: [2H]c1c([2H])c([2H])c2c(-c3c4c([2H])c([2H])c([2H])c([2H])c4c(Br)c4c([2H])c([2H])c([2H])c([2H])c34)c([2H])c([2H])c([2H])c2c1[2H] ; [2H]c1c([2H])c([2H])c2c(-c3c4c([2H])c([2H])c([2H])c([2H])c4c(B(O)O)c4c([2H])c([2H])c([2H])c([2H])c34)c([2H])c([2H])c([2H])c2c1[2H]]

<Intermediate 3-a> (yield 70%) was obtained by performing synthesis in the same manner except that 9-bromo-10-(1-naphthalenyl(D7))anthracene (D8) was used instead of <Intermediate 2-a> used in Synthesis Example 2-(2) above.

### Synthesis Example 3-(2): Synthesis of Intermediate 3-b

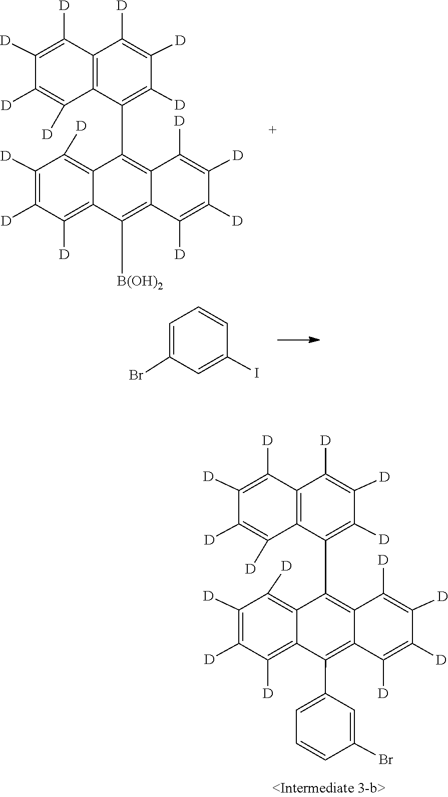 [SMILES: [2H]c1c([2H])c([2H])c2c(-c3c4c([2H])c([2H])c([2H])c([2H])c4c(B(O)O)c4c([2H])c([2H])c([2H])c([2H])c34)c([2H])c([2H])c([2H])c2c1[2H] ; Brc1cccc(I)c1 ; [2H]c1c([2H])c([2H])c2c(-c3c4c([2H])c([2H])c([2H])c([2H])c4c(-c4cccc(Br)c4)c4c([2H])c([2H])c([2H])c([2H])c34)c([2H])c([2H])c([2H])c2c1[2H]]

<Intermediate 3-b> (yield 81%) was obtained by performing synthesis in the same manner except that <Intermediate 3-a> was used instead of <Intermediate 2-d> used in Synthesis Example 2-(5) above.

### Synthesis Example 3-(3): Synthesis of Intermediate 3-c

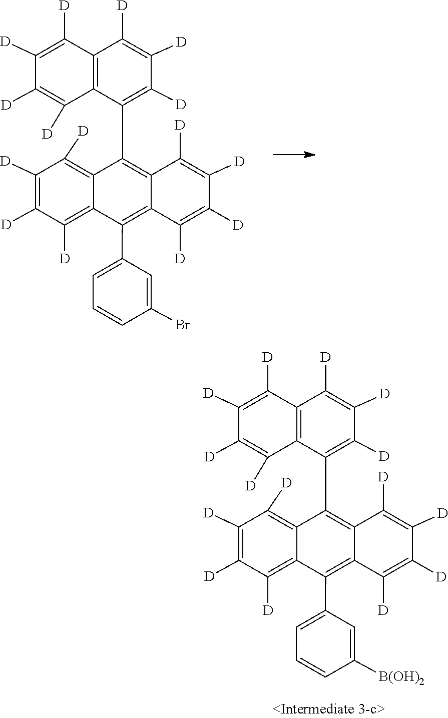 [SMILES: [2H]c1c([2H])c([2H])c2c(-c3c4c([2H])c([2H])c([2H])c([2H])c4c(-c4cccc(Br)c4)c4c([2H])c([2H])c([2H])c([2H])c34)c([2H])c([2H])c([2H])c2c1[2H] ; [2H]c1c([2H])c([2H])c2c(-c3c4c([2H])c([2H])c([2H])c([2H])c4c(-c4cccc(B(O)O)c4)c4c([2H])c([2H])c([2H])c([2H])c34)c([2H])c([2H])c([2H])c2c1[2H]]

<Intermediate 3-c> (yield 71%) was obtained by performing synthesis in the same manner except that <Intermediate 3-b> was used instead of <Intermediate 2-a> used in Synthesis Example 2-(2) above.

### Synthesis Example 3-(4): Synthesis of Intermediate 3-d

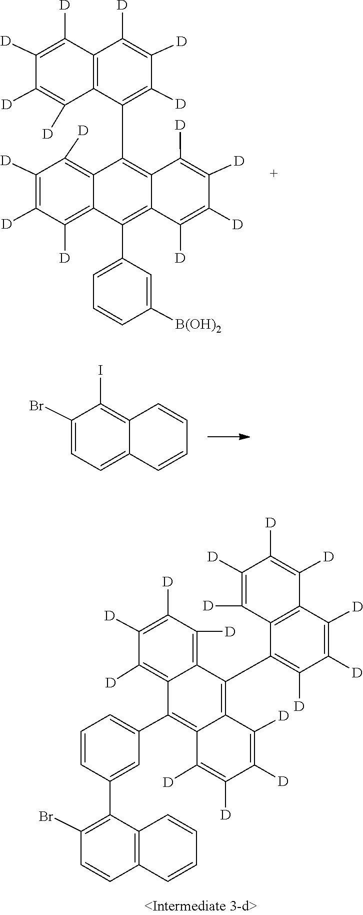 [SMILES: [2H]c1c([2H])c([2H])c2c(-c3c4c([2H])c([2H])c([2H])c([2H])c4c(-c4cccc(B(O)O)c4)c4c([2H])c([2H])c([2H])c([2H])c34)c([2H])c([2H])c([2H])c2c1[2H] ; Brc1ccc2ccccc2c1I ; [2H]c1c([2H])c([2H])c2c(-c3c4c([2H])c([2H])c([2H])c([2H])c4c(-c4cccc(-c5c(Br)ccc6ccccc56)c4)c4c([2H])c([2H])c([2H])c([2H])c34)c([2H])c([2H])c([2H])c2c1[2H]]

<Intermediate 3-d> (yield 53%) was obtained by performing synthesis in the same manner except that <Intermediate 3-c> was used instead of <Intermediate 2-b> used in Synthesis Example 2-(3) above.

### Synthesis Example 3-(5): Synthesis of Intermediate 3-e

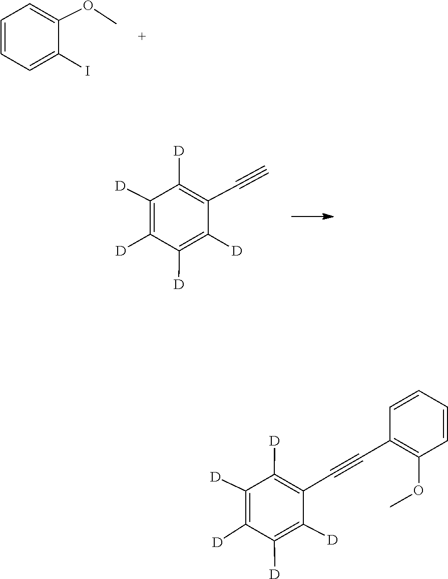

### Intermediate 3-e

100.0 g (0.43 mol) of 1-iodoanisole, 91.1 g (0.85 mol) of phenyl-d5-acetylene, 14.8 g (0.013 mol) of tetrakis(triphenylphosphine)palladium, 4.1 g (0.021 mol) of copper iodide, 2.2 g (0.009 mol) of triphenylphosphine, and 1,000 mL of triethylamine were put into a 2 L round bottom flask and refluxed for 6 hours. When the reaction was completed, the reaction solution was cooled to room temperature, filtered through Celite, and the filtrate was concentrated under reduced pressure to obtain 81.6 g (yield 89%) of <Intermediate 3-e> using column chromatography.

### Synthesis Example 3-(6): Synthesis of Intermediate 3-f

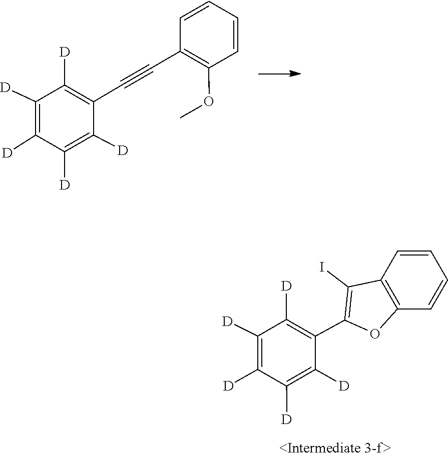 [SMILES: [2H]c1c([2H])c([2H])c(C#Cc2ccccc2OC)c([2H])c1[2H] ; [2H]c1c([2H])c([2H])c(-c2oc3ccccc3c2I)c([2H])c1[2H]]

81.0 g (0.38 mol) of <Intermediate 3-e> and 790 mL of dichloromethane were put into a 2,000 ml round bottom flask and stirred at room temperature. During stirring, 73.9 g of iodomonochloride was added dropwise at room temperature and then stirred at room temperature until the reaction was completed. A saturated sodium thiosulfate aqueous solution was put into the reaction solution in which the reaction was completed, stirred for 20 minutes, and extracted with dichloromethane and water. After concentrating the organic layer, 84.0 g (yield 68%) of <Intermediate 3-f> was obtained using column chromatography.

### Synthesis Example 3-(7): Synthesis of Intermediate 3-q

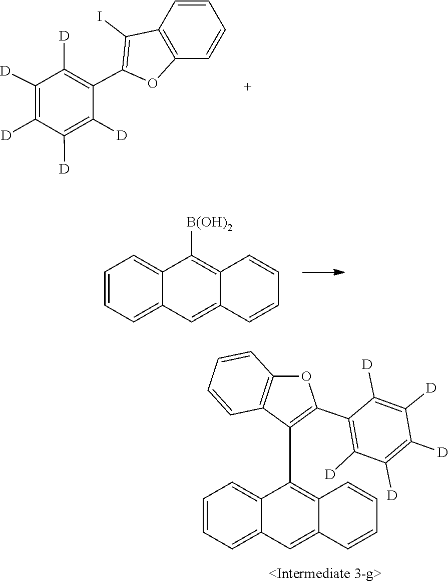

3.6 g (0.011 mol) of <Intermediate 3-f>, 2.9 g (0.013 mol) of 9-anthraceneboronic acid, 3.01 g (0.022 mol) of potassium carbonate, 0.5 g of palladium(II) acetate, and 0.2 g of 2-dicyclohexylphosphino-2′,6′-dimethoxybiphenyl were put into a round bottom flask, and 50 mL of toluene, 50 mL of 1,4-dioxane, and 15 mL of water were put thereinto and refluxed for 12 hours. After completion of the reaction, the reaction product was cooled to room temperature, 50 mL of methanol was put thereinto, stirred, and then filtered under reduced pressure. The solid was recrystallized from toluene and acetone to obtain 3.2 g (yield 68%) of <Intermediate 3-g>.

### Synthesis Example 3-(8): Synthesis of Intermediate 3-h

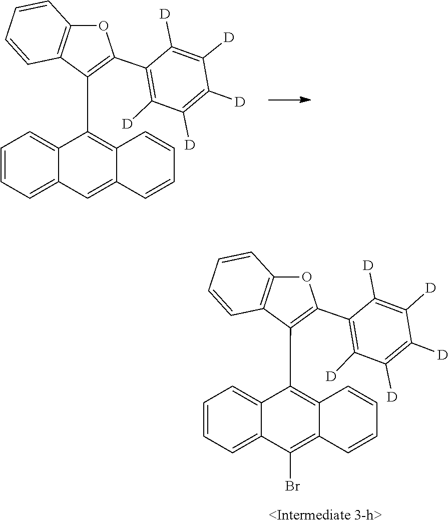 [SMILES: [2H]c1c([2H])c([2H])c(-c2oc3ccccc3c2-c2c3ccccc3cc3ccccc23)c([2H])c1[2H] ; [2H]c1c([2H])c([2H])c(-c2oc3ccccc3c2-c2c3ccccc3c(Br)c3ccccc23)c([2H])c1[2H]]

75.1 g (0.2 mol) of <Intermediate 3-g> was put into a 2 L 4-neck round bottom flask, and 700 mL of dimethylformamide was put thereinto and dissolved. Afterwards, 70.7 g (0.4 mol) of NBS was dissolved in 200 mL of dimethylformamide. The NBS solution was slowly added dropwise. After the dropwise addition was completed, the mixture was stirred for 2 hours. When the reaction was completed, the reaction solution was precipitated in water to obtain 87.2 g (yield 96%) of <Intermediate 3-h>.

### Synthesis Example 3-(9): Synthesis of Intermediate 3-i

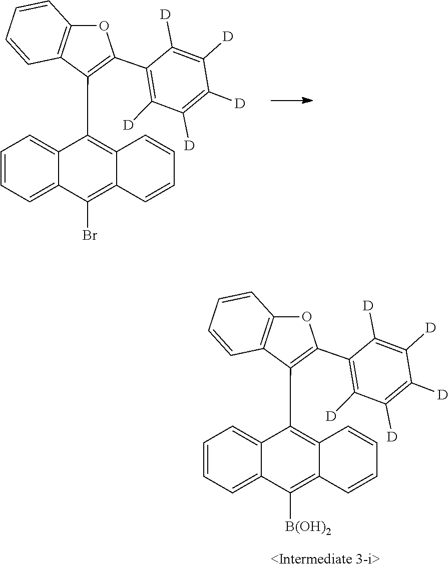 [SMILES: [2H]c1c([2H])c([2H])c(-c2oc3ccccc3c2-c2c3ccccc3c(Br)c3ccccc23)c([2H])c1[2H] ; [2H]c1c([2H])c([2H])c(-c2oc3ccccc3c2-c2c3ccccc3c(B(O)O)c3ccccc23)c([2H])c1[2H]]

<Intermediate 3-i> (yield 70%) was obtained by performing synthesis in the same manner except that <Intermediate 3-h> was used instead of <Intermediate 2-a> in Synthesis Example 2-(2) above.

### Synthesis Example 3-(10): Synthesis of Intermediate 3-i

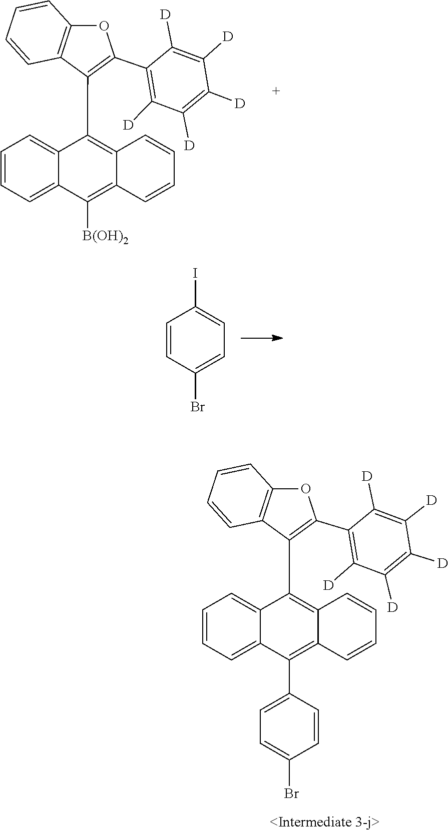 [SMILES: [2H]c1c([2H])c([2H])c(-c2oc3ccccc3c2-c2c3ccccc3c(B(O)O)c3ccccc23)c([2H])c1[2H] ; Brc1ccc(I)cc1 ; [2H]c1c([2H])c([2H])c(-c2oc3ccccc3c2-c2c3ccccc3c(-c3ccc(Br)cc3)c3ccccc23)c([2H])c1[2H]]

<Intermediate 3-j> (yield 78%) was obtained by performing synthesis in the same manner except that <Intermediate 3-i> was used instead of B-[10-(2-dibenzofuranyl)-9-anthracenyl]boronic acid used in Synthesis Example 2-(1) above.

### Synthesis Example 3-(11): Synthesis of Intermediate 3-k

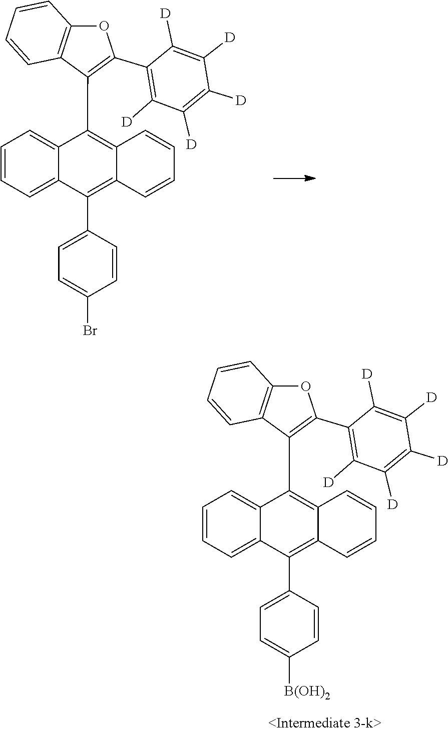 [SMILES: [2H]c1c([2H])c([2H])c(-c2oc3ccccc3c2-c2c3ccccc3c(-c3ccc(Br)cc3)c3ccccc23)c([2H])c1[2H] ; [2H]c1c([2H])c([2H])c(-c2oc3ccccc3c2-c2c3ccccc3c(-c3ccc(B(O)O)cc3)c3ccccc23)c([2H])c1[2H]]

<Intermediate 3-k> (yield 71%) was obtained by performing synthesis in the same manner except that <Intermediate 3-j> was used instead of <Intermediate 2-a> in Synthesis Example 2-(2) above.

### Synthesis Example 3-(12): Synthesis of [24]

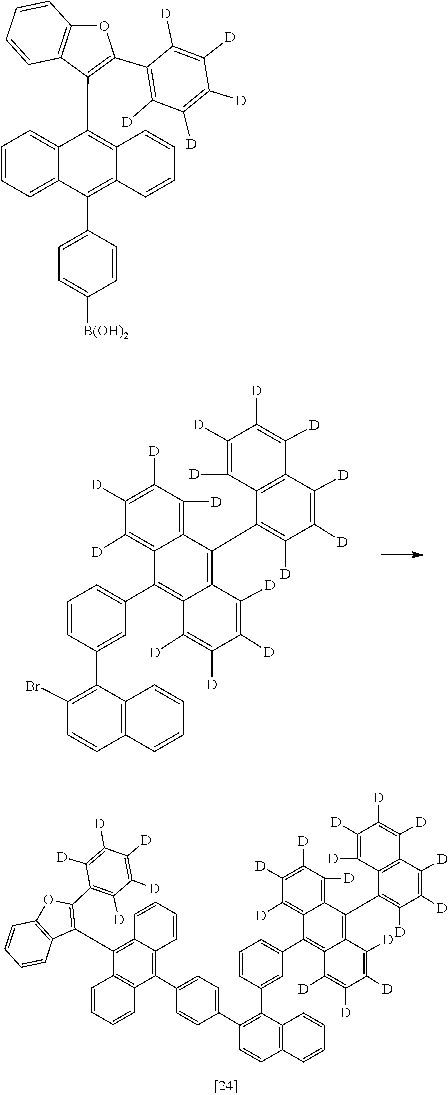 [SMILES: [2H]c1c([2H])c([2H])c(-c2oc3ccccc3c2-c2c3ccccc3c(-c3ccc(B(O)O)cc3)c3ccccc23)c([2H])c1[2H] ; [2H]c1c([2H])c([2H])c2c(-c3c4c([2H])c([2H])c([2H])c([2H])c4c(-c4cccc(-c5c(Br)ccc6ccccc56)c4)c4c([2H])c([2H])c([2H])c([2H])c34)c([2H])c([2H])c([2H])c2c1[2H] ; [2H]c1c([2H])c([2H])c(-c2oc3ccccc3c2-c2c3ccccc3c(-c3ccc(-c4ccc5ccccc5c4-c4cccc(-c5c6c([2H])c([2H])c([2H])c([2H])c6c(-c6c([2H])c([2H])c([2H])c7c([2H])c([2H])c([2H])c([2H])c67)c6c([2H])c([2H])c([2H])c([2H])c56)c4)cc3)c3ccccc23)c([2H])c1[2H]]

[24] (yield 76%) was obtained by performing synthesis in the same manner except that <Intermediate 3-k> was used instead of <Intermediate 1-b> used in Synthesis Example 1-(4) above, and <Intermediate 3-d> was used instead of <Intermediate 1-c>.

MS (MALDI-TOF): m/z 970.48 [M⁺]

### Synthesis Example 4: Synthesis of [26]

### Synthesis Example 4-(1): Synthesis of Intermediate 4-a

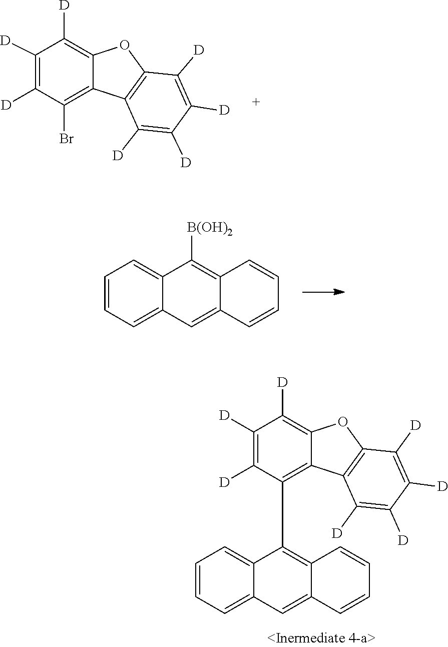 [SMILES: [2H]c1c([2H])c([2H])c2c(oc3c([2H])c([2H])c([2H])c(Br)c32)c1[2H] ; OB(O)c1c2ccccc2cc2ccccc12 ; [2H]c1c([2H])c([2H])c2c(oc3c([2H])c([2H])c([2H])c(-c4c5ccccc5cc5ccccc45)c32)c1[2H]]

<Intermediate 4-a> (yield 72%) was obtained by performing synthesis in the same manner except that 9-anthraceneboronic acid was used instead of 3-bromophenylboronic acid used in Synthesis Example 1-(3) above, and 1-bromo-dibenzofuran (D7) was used instead of 1,8-dibromonaphthalene.

### Synthesis Example 4-(2): Synthesis of Intermediate 4-b

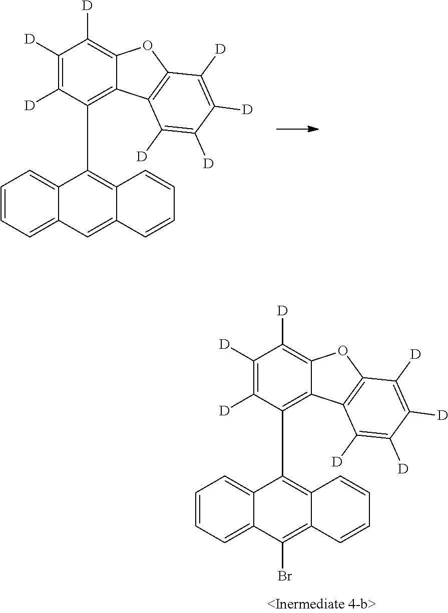 [SMILES: [2H]c1c([2H])c([2H])c2c(oc3c([2H])c([2H])c([2H])c(-c4c5ccccc5cc5ccccc45)c32)c1[2H] ; [2H]c1c([2H])c([2H])c2c(oc3c([2H])c([2H])c([2H])c(-c4c5ccccc5c(Br)c5ccccc45)c32)c1[2H]]

<Intermediate 4-b> (yield 95%) was obtained by performing synthesis in the same manner except that <Intermediate 4-a> was used instead of <Intermediate 3-g> used in Synthesis Example 3-(8) above.

### Synthesis Example 4-(3): Synthesis of Intermediate 4-c

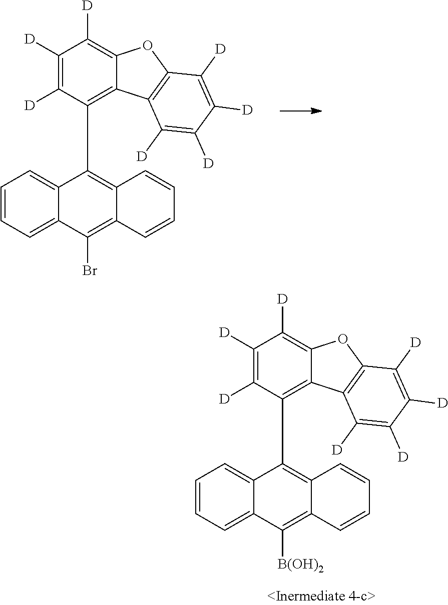 [SMILES: [2H]c1c([2H])c([2H])c2c(oc3c([2H])c([2H])c([2H])c(-c4c5ccccc5c(Br)c5ccccc45)c32)c1[2H] ; [2H]c1c([2H])c([2H])c2c(oc3c([2H])c([2H])c([2H])c(-c4c5ccccc5c(B(O)O)c5ccccc45)c32)c1[2H]]

<Intermediate 4-c> (yield 73%) was obtained by performing synthesis in the same manner except that <Intermediate 4-b> was used instead of <Intermediate 2-a> in Synthesis Example 2-(2) above.

### Synthesis Example 4-(4): Synthesis of Intermediate 4-d

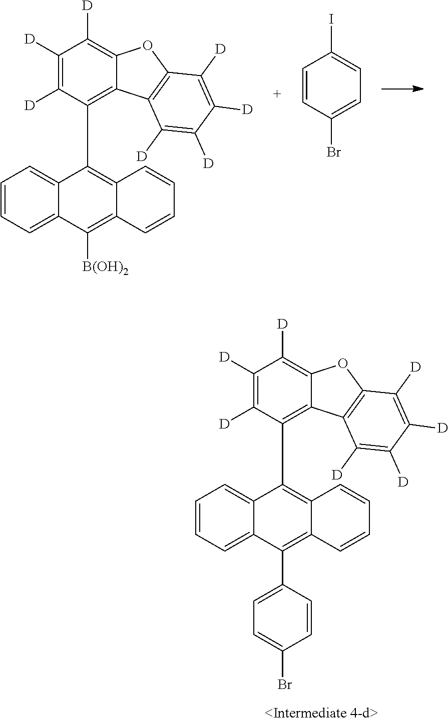 [SMILES: [2H]c1c([2H])c([2H])c2c(oc3c([2H])c([2H])c([2H])c(-c4c5ccccc5c(B(O)O)c5ccccc45)c32)c1[2H] ; Brc1ccc(I)cc1 ; [2H]c1c([2H])c([2H])c2c(oc3c([2H])c([2H])c([2H])c(-c4c5ccccc5c(-c5ccc(Br)cc5)c5ccccc45)c32)c1[2H]]

<Intermediate 4-d> (yield 75%) was obtained by performing synthesis in the same manner except that <Intermediate 4-c> was used instead of B-[10-(2-dibenzofuranyl)-9-anthracenyl]boronic acid used in Synthesis Example 2-(1) above.

### Synthesis Example 4-(5): Synthesis of Intermediate 4-e

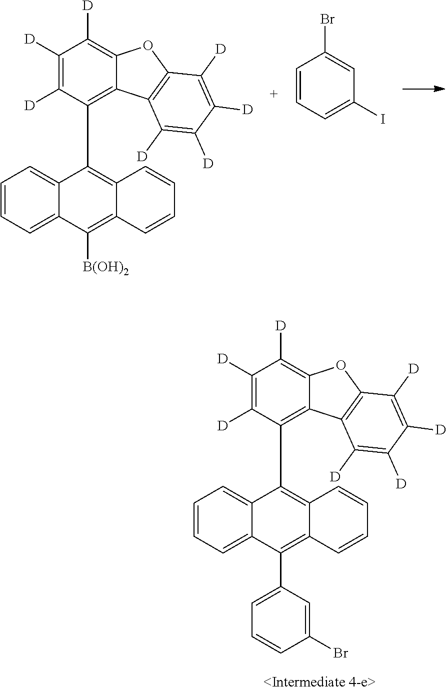 [SMILES: [2H]c1c([2H])c([2H])c2c(oc3c([2H])c([2H])c([2H])c(-c4c5ccccc5c(B(O)O)c5ccccc45)c32)c1[2H] ; Brc1cccc(I)c1 ; [2H]c1c([2H])c([2H])c2c(oc3c([2H])c([2H])c([2H])c(-c4c5ccccc5c(-c5cccc(Br)c5)c5ccccc45)c32)c1[2H]]

<Intermediate 4-e> (yield 73%) was obtained by performing synthesis in the same manner except that <Intermediate 4-c> was used instead of <Intermediate 2-d> used in Synthesis Example 2-(5) above.

### Synthesis Example 4-(6): Synthesis of Intermediate 4-f

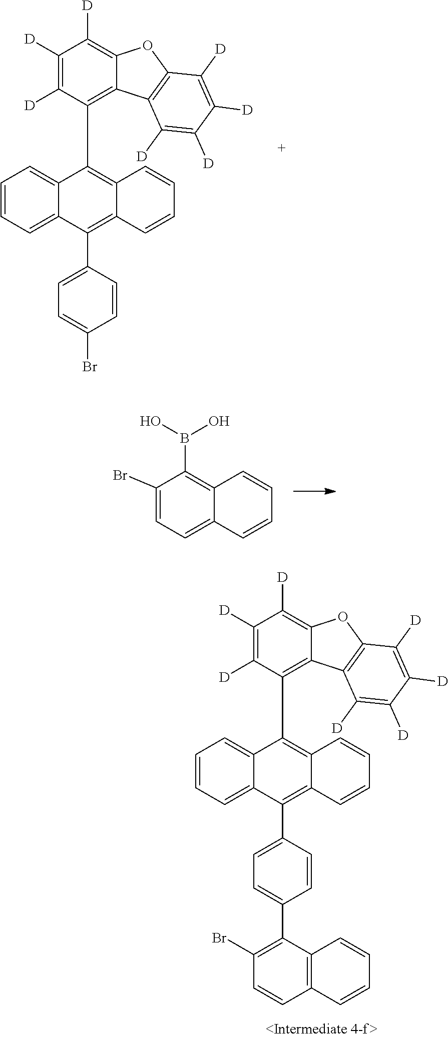 [SMILES: [2H]c1c([2H])c([2H])c2c(oc3c([2H])c([2H])c([2H])c(-c4c5ccccc5c(-c5ccc(Br)cc5)c5ccccc45)c32)c1[2H] ; OB(O)c1c(Br)ccc2ccccc12 ; [2H]c1c([2H])c([2H])c2c(oc3c([2H])c([2H])c([2H])c(-c4c5ccccc5c(-c5ccc(-c6c(Br)ccc7ccccc67)cc5)c5ccccc45)c32)c1[2H]]

<Intermediate 4-f> (yield 40%) was obtained by performing synthesis in the same manner except that B-(2-bromo-1-naphthalenyl)boronic acid was used instead of 3-bromophenylboronic acid used in Synthesis Example 1-(3) above, and <Intermediate 4-d> was used instead of 1,8-dibromonaphthalene.

### Synthesis Example 4-(7): Synthesis of Intermediate 4-q

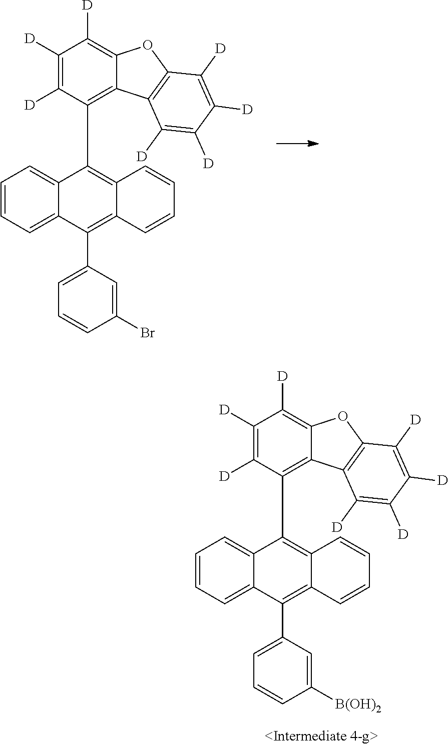 [SMILES: [2H]c1c([2H])c([2H])c2c(oc3c([2H])c([2H])c([2H])c(-c4c5ccccc5c(-c5cccc(Br)c5)c5ccccc45)c32)c1[2H] ; [2H]c1c([2H])c([2H])c2c(oc3c([2H])c([2H])c([2H])c(-c4c5ccccc5c(-c5cccc(B(O)O)c5)c5ccccc45)c32)c1[2H]]

<Intermediate 4-g> (yield 72%) was obtained by performing synthesis in the same manner except that <Intermediate 4-e> was used instead of <Intermediate 2-a> used in Synthesis Example 2-(2) above.

### Synthesis Example 4-(8): Synthesis of [26]

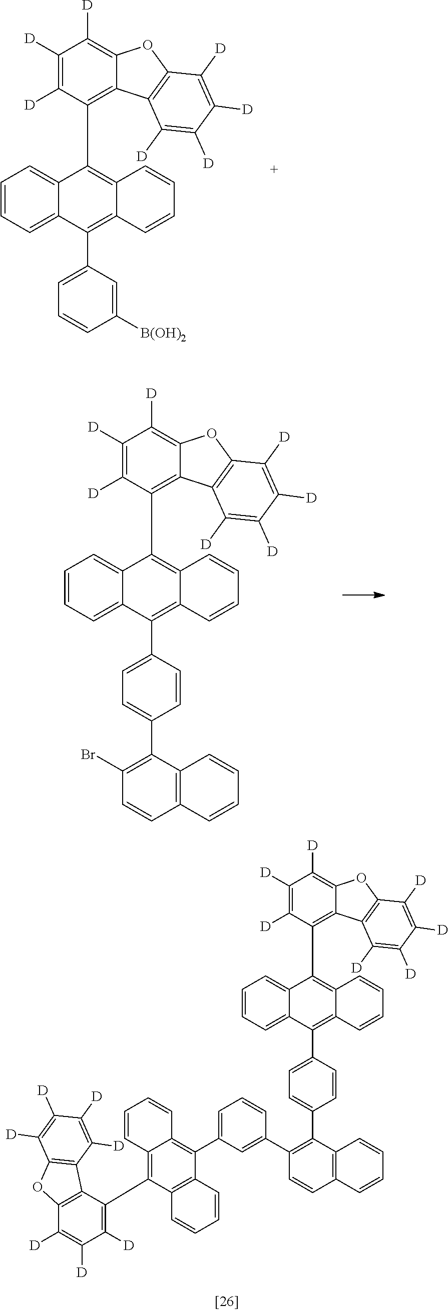 [SMILES: [2H]c1c([2H])c([2H])c2c(oc3c([2H])c([2H])c([2H])c(-c4c5ccccc5c(-c5cccc(B(O)O)c5)c5ccccc45)c32)c1[2H] ; [2H]c1c([2H])c([2H])c2c(oc3c([2H])c([2H])c([2H])c(-c4c5ccccc5c(-c5ccc(-c6c(Br)ccc7ccccc67)cc5)c5ccccc45)c32)c1[2H] ; [2H]c1c([2H])c([2H])c2c(oc3c([2H])c([2H])c([2H])c(-c4c5ccccc5c(-c5ccc(-c6c(-c7cccc(-c8c9ccccc9c(-c9c([2H])c([2H])c([2H])c%10oc%11c([2H])c([2H])c([2H])c([2H])c%11c9%10)c9ccccc89)c7)ccc7ccccc67)cc5)c5ccccc45)c32)c1[2H]]

[26] (yield 75%) was obtained by performing synthesis in the same manner except that <Intermediate 4-g> was used instead of <Intermediate 1-b> used in Synthesis Example 1-(4) above, and <Intermediate 4-f> was used instead of <Intermediate 1-c>.

MS (MALDI-TOF): m/z 978.42 [M⁺]

### Synthesis Example 5: Synthesis of [28]

### Synthesis Example 5-(1): Synthesis of Intermediate 5-a

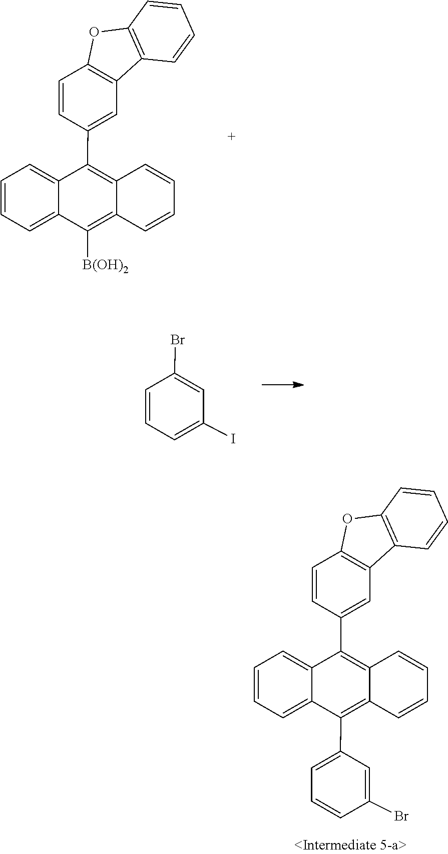 [SMILES: OB(O)c1c2ccccc2c(-c2ccc3oc4ccccc4c3c2)c2ccccc12 ; Brc1cccc(I)c1 ; Brc1cccc(-c2c3ccccc3c(-c3ccc4oc5ccccc5c4c3)c3ccccc23)c1]

<Intermediate 5-a> (yield 77%) was obtained by performing synthesis in the same manner except that B-[10-(2-dibenzofuranyl)-9-anthracenyl]boronic acid was used instead of <Intermediate 2-d> used in Synthesis Example 2-(5) above.

### Synthesis Example 5-(2): Synthesis of Intermediate 5-b

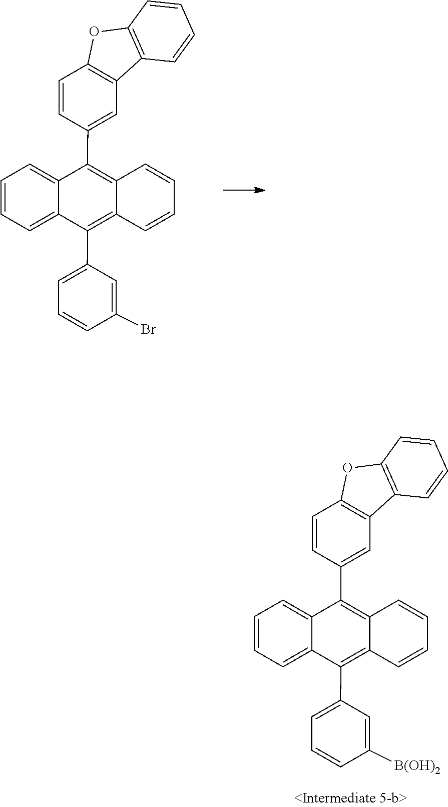 [SMILES: Brc1cccc(-c2c3ccccc3c(-c3ccc4oc5ccccc5c4c3)c3ccccc23)c1 ; OB(O)c1cccc(-c2c3ccccc3c(-c3ccc4oc5ccccc5c4c3)c3ccccc23)c1]

<Intermediate 5-b> (yield 74%) was obtained by performing synthesis in the same manner except that <Intermediate 5-a> was used instead of <Intermediate 2-a> used in Synthesis Example 2-(2) above.

### Synthesis Example 5-(3): Synthesis of Intermediate 5-c

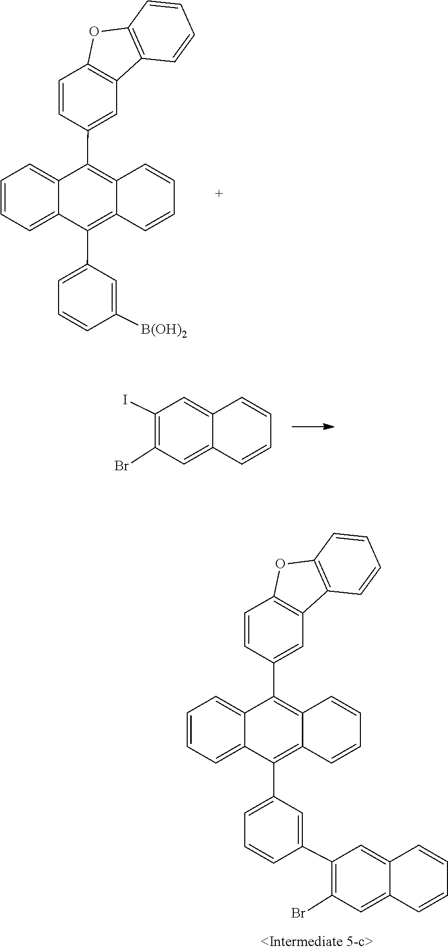 [SMILES: OB(O)c1cccc(-c2c3ccccc3c(-c3ccc4oc5ccccc5c4c3)c3ccccc23)c1 ; Brc1cc2ccccc2cc1I ; Brc1cc2ccccc2cc1-c1cccc(-c2c3ccccc3c(-c3ccc4oc5ccccc5c4c3)c3ccccc23)c1]

<Intermediate 5-c> (yield 57%) was obtained by performing synthesis in the same manner except that <Intermediate 5-b> was used instead of <Intermediate 1-b> used in Synthesis Example 1-(4) above, and 2-bromo-3-iodonaphthalene was used instead of <Intermediate 1-c>.

### Synthesis Example 5-(4): Synthesis of [28]

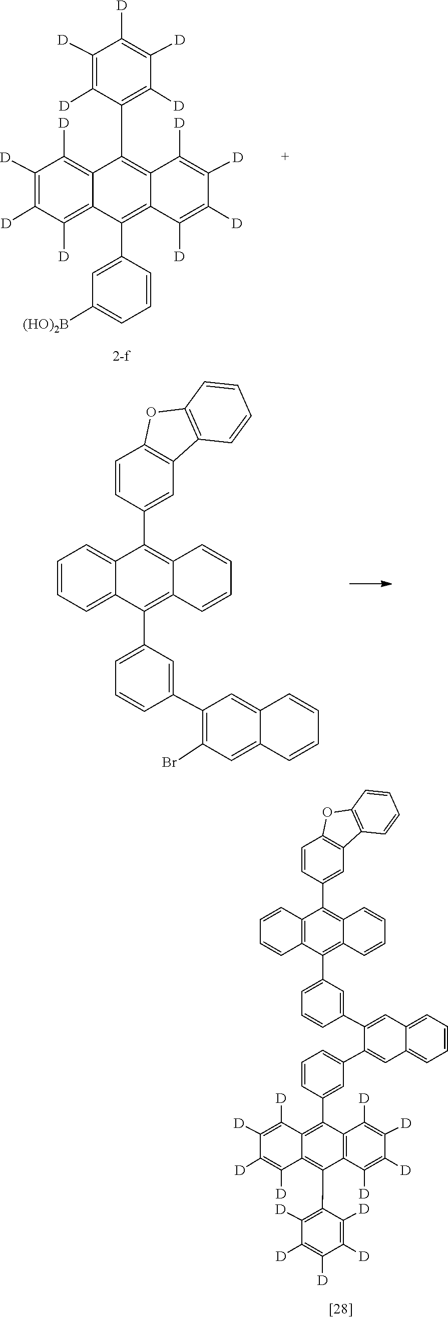 [SMILES: [2H]c1c([2H])c([2H])c(-c2c3c([2H])c([2H])c([2H])c([2H])c3c(-c3cccc(B(O)O)c3)c3c([2H])c([2H])c([2H])c([2H])c23)c([2H])c1[2H] ; Brc1cc2ccccc2cc1-c1cccc(-c2c3ccccc3c(-c3ccc4oc5ccccc5c4c3)c3ccccc23)c1 ; [2H]c1c([2H])c([2H])c(-c2c3c([2H])c([2H])c([2H])c([2H])c3c(-c3cccc(-c4cc5ccccc5cc4-c4cccc(-c5c6ccccc6c(-c6ccc7oc8ccccc8c7c6)c6ccccc56)c4)c3)c3c([2H])c([2H])c([2H])c([2H])c23)c([2H])c1[2H]]

[28] (yield 78%) was obtained by performing synthesis in the same manner except that <Intermediate 2-f> was used instead of <Intermediate 1-b> used in Synthesis Example 1-(4) above, and <Intermediate 5-c> was used instead of <Intermediate 1-c>.

MS (MALDI-TOF): m/z 887.41 [M⁺]

### Synthesis Example 6: Synthesis of [35]

### Synthesis Example 6-(1): Synthesis of Intermediate 6-a

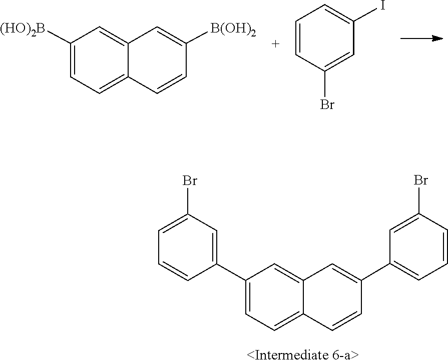 [SMILES: OB(O)c1ccc2ccc(B(O)O)cc2c1 ; Brc1cccc(I)c1 ; Brc1cccc(-c2ccc3ccc(-c4cccc(Br)c4)cc3c2)c1]

<Intermediate 6-a> (yield 54%) was obtained by performing synthesis in the same manner except that 2,7-naphthalene-diboronic acid was used instead of B-[10-(2-dibenzofuranyl)-9-anthracenyl]boronic acid used in Synthesis Example 2-(1) above, and 1-bromo-3-iodobenzene was used instead of 1-bromo-4-iodobenzene.

### Synthesis Example 6-(2): Synthesis of Intermediate 6-b

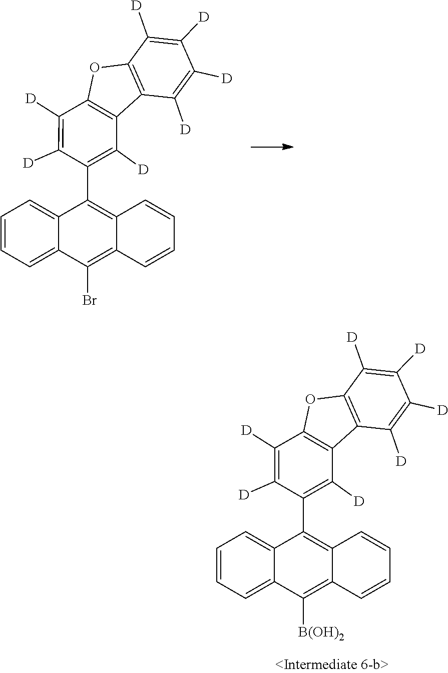 [SMILES: [2H]c1c([2H])c([2H])c2c(oc3c([2H])c([2H])c(-c4c5ccccc5c(Br)c5ccccc45)c([2H])c32)c1[2H] ; [2H]c1c([2H])c([2H])c2c(oc3c([2H])c([2H])c(-c4c5ccccc5c(B(O)O)c5ccccc45)c([2H])c32)c1[2H]]

<Intermediate 6-b> (yield 75%) was obtained by performing synthesis in the same manner except that 8-(10-bromo-9-anthracenyl)dibenzofuran (D7) was used instead of <Intermediate 2-a> in Synthesis Example 2-(2) above.

### Synthesis Example 6-(3): Synthesis of [35]

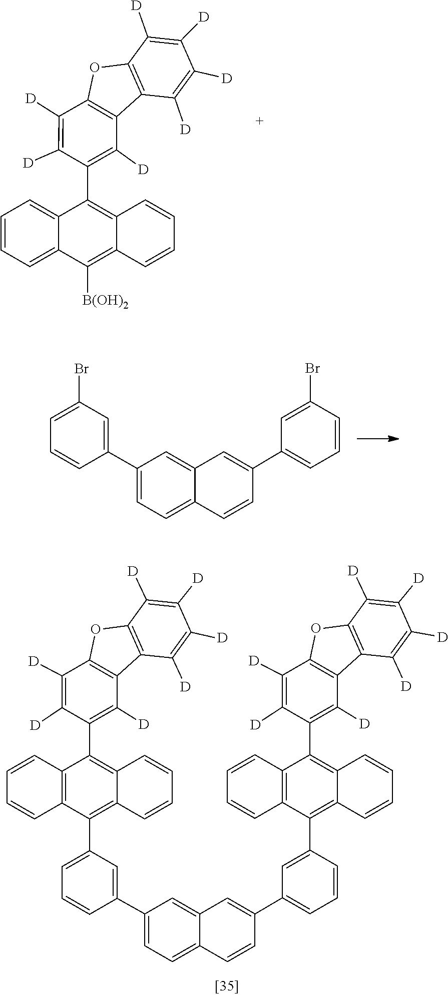 [SMILES: [2H]c1c([2H])c([2H])c2c(oc3c([2H])c([2H])c(-c4c5ccccc5c(B(O)O)c5ccccc45)c([2H])c32)c1[2H] ; Brc1cccc(-c2ccc3ccc(-c4cccc(Br)c4)cc3c2)c1 ; [2H]c1c([2H])c([2H])c2c(oc3c([2H])c([2H])c(-c4c5ccccc5c(-c5cccc(-c6ccc7ccc(-c8cccc(-c9c%10ccccc%10c(-c%10c([2H])c([2H])c%11oc%12c([2H])c([2H])c([2H])c([2H])c%12c%11c%10[2H])c%10ccccc9%10)c8)cc7c6)c5)c5ccccc45)c([2H])c32)c1[2H]]

[35] (yield 68%) was obtained by performing synthesis in the same manner except that <Intermediate 6-b> was used instead of <Intermediate 1-b> used in Synthesis Example 1-(4) above, and Intermediate <6-a> was used instead of <Intermediate 1-c>.

MS (MALDI-TOF): m/z 978.42 [M⁺]

### Synthesis Example 7: Synthesis of [D-265]

Referring to the method for synthesizing dopant compounds as described in Registered Patent Publication No. 10-2148296, the compound [D-265] below was prepared.

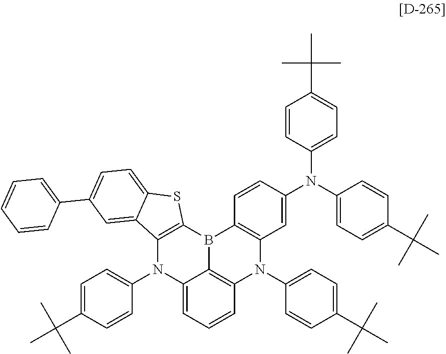 [SMILES: CC(C)(C)c1ccc(N(c2ccc(C(C)(C)C)cc2)c2ccc3c(c2)N(c2ccc(C(C)(C)C)cc2)c2cccc4c2B3c2sc3ccc(-c5ccccc5)cc3c2N4c2ccc(C(C)(C)C)cc2)cc1]

### Examples 1 to 5

Poly(3,4-ethylenedioxythiophene):poly(styrenesulfonate) (AI4083), which is widely used as a hole injection layer, was spin-coated on an ITO transparent electrode to form a film to a thickness of 60 nm, and then baked at 200° C. for 30 minutes to form a hole injection layer.

TFB was spin-coated on the hole injection layer to form a film to a thickness of 20 nm, and then baked at 130° C. for 10 minutes to form a hole transport layer.

A solution in which the host compound according to the present disclosure shown in Table 1 below and the dopant [D 265] (the host and the dopant have a weight ratio of 97:3) were dissolved in methyl benzoate at a concentration of 2% wt/v was spin-coated on the hole transport layer to form a film to a thickness of 30 nm, and then baked at 180° C. for 30 minutes to form a light emitting layer. After baking this at 130° C. for 10 minutes in a nitrogen gas atmosphere, [E-1] and [E-2] were deposited at a ratio of (1:1) as an electron transport layer to form a film to a thickness of 25 nm.

[E-2] was deposited as an electron injection layer on the electron transport layer to form a film to a thickness of 1 nm.

Finally, aluminum was deposited as a cathode on the electron injection layer to a thickness of 100 nm to manufacture organic electroluminescent devices.

The emission characteristics of the organic electroluminescent devices were measured at 10 mA/cm².

### Comparative Examples 1 to 2

The organic electroluminescent devices for the Comparative Examples were manufactured in the same manner except that [BH1] and [BH2] were used instead of the compounds according to the present disclosure in the device structures of the above Examples, and the emission characteristics of the organic electroluminescent devices were 1 measured at 10 mA/cm².

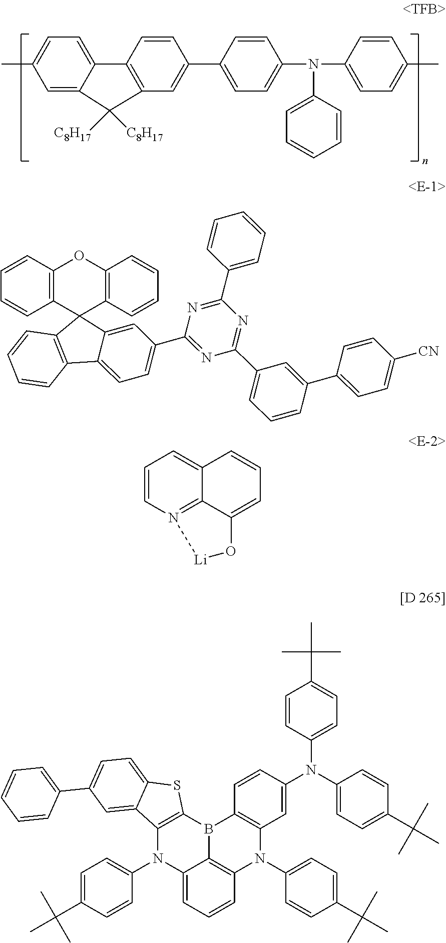

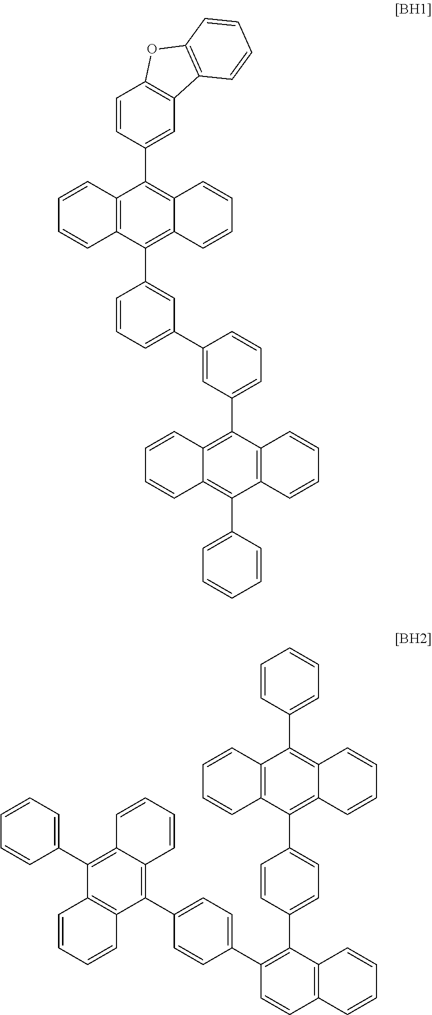

TABLE 1

| | | Driving | Efficiency | |
|---|---|---|---|---|
| | Host | Voltage (V) | (cd/A) | T95 (hr) |
| Example 1 | [13] | 4.4 | 4.8 | 50 |
| Example 2 | [22] | 4.5 | 4.9 | 56 |
| Example 3 | [24] | 4.6 | 5.2 | 52 |
| Example 4 | [26] | 4.2 | 4.7 | 55 |
| Example 5 | [28] | 4.5 | 4.7 | 56 |
| Example 6 | [35] | 4.3 | 4.6 | 58 |
| Comparative | [BH1] | 4.6 | 4.5 | 46 |
| Example 1 | | | | |
| Comparative | [BH2] | 4.4 | 4.6 | 41 |
| Example 2 | | | | |

It was confirmed that the devices of the Examples using the compounds of the present disclosure exhibited good driving voltages and efficiencies, and had improved lifespan characteristics compared to those of the devices of the Comparative Examples.

### EXPLANATION OF REFERENCE NUMERALS

10: Substrate
20: First electrode
30: Hole injection layer
40: Hole transport layer
50: Light emitting layer
60: Electron transport layer
70: Electron injection layer
80: Second electrode

1. An organic electroluminescent device comprising:
a first electrode;
a second electrode; and
an organic layer formed between the first electrode and the second electrode,
wherein the organic layer comprises a light emitting layer formed using a solution containing an organic electroluminescent material and a solvent,
wherein the organic electroluminescent material comprises a host and a dopant, and
wherein the host is one or more compounds represented by [Formula A] below: 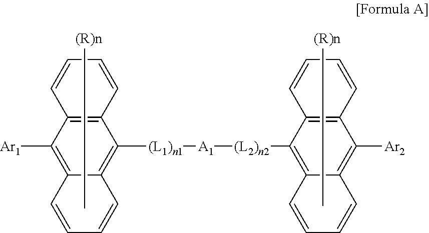
wherein in [Formula A],
L₁ to L₂ are the same as or different from each other, and each independently selected from the group consisting of a substituted or unsubstituted alkylene group having 1 to 20 carbon atoms, a substituted or unsubstituted arylene group having 6 to 30 carbon atoms, and a substituted or unsubstituted heteroarylene group having 3 to 30 carbon atoms,
R is the same as or different from each other, and each independently selected from the group consisting of a hydrogen atom, a deuterium atom, a substituted or unsubstituted alkyl group having 1 to 30 carbon atoms, a substituted or unsubstituted alkenyl group having 2 to 30 carbon atoms, a substituted or unsubstituted cycloalkyl group having 3 to 30 carbon atoms, a substituted or unsubstituted cycloalkenyl group having 5 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 6 to 30 carbon atoms, a substituted or unsubstituted alkylamine group having 1 to 30 carbon atoms, a substituted or unsubstituted arylamine group having 6 to 30 carbon atoms, a substituted or unsubstituted aryl group having 6 to 50 carbon atoms, a substituted or unsubstituted heteroaryl group having 3 to 50 carbon atoms, a substituted or unsubstituted alkylsilyl group having 1 to 30 carbon atoms, and a substituted or unsubstituted arylsilyl group having 6 to 30 carbon atoms,
Ar₁ and Ar₂ are the same as or different from each other, and each independently selected from the group consisting of a substituted or unsubstituted alkyl group having 1 to 30 carbon atoms, a substituted or unsubstituted cycloalkyl group having 3 to 30 carbon atoms, a substituted or unsubstituted aryl group having 6 to 50 carbon atoms, and a substituted or unsubstituted heteroaryl group having 3 to 50 carbon atoms, provided that at least one of Ar₁ and Ar₂ is not a substituted or unsubstituted aryl group having 6 to 50 carbon atoms,
n is an integer of 0 to 8, but when n is 2 or more, respective R is the same as or different from each other,
n1 and n2 are each independently an integer of 1 to 3, and
A₁ is a substituted or unsubstituted aryl group having 10 to 30 carbon atoms, and
wherein “Substituted” in the “substituted or unsubstituted” means being substituted with one or more substituents selected from the group consisting of deuterium, a cyano group, a halogen group, a hydroxy group, a nitro group, an alkyl group having 1 to 24 carbon atoms, an alkynyl group having 1 to 24 carbon atoms, a cycloalkyl group having 3 to 24 carbon atoms, a heteroalkyl group having 1 to 24 carbon atoms, an aryl group having 6 to 24 carbon atoms, an arylalkyl group having 7 to 24 carbon atoms, an alkylaryl group having 7 to 24 carbon atoms, a heteroaryl group having 2 to 24 carbon atoms, a heteroarylalkyl group having 2 to 24 carbon atoms, an alkoxy group having 1 to 24 carbon atoms, an alkylamino group having 1 to 24 carbon atoms, a diarylamino group having 12 to 24 carbon atoms, a diheteroarylamino group having 2 to 24 carbon atoms, an aryl(heteroaryl)amino group having 7 to 24 carbon atoms, an alkylsilyl group having 1 to 24 carbon atoms, an arylsilyl group having 6 to 24 carbon atoms, an aryloxy group having 6 to 24 carbon atoms, and an arylthionyl group having 6 to 24 carbon atoms.

2. The organic electroluminescent device of claim 1, wherein A₁ is any one selected from groups represented by [Formula A-1] to [Formula A-4] below: 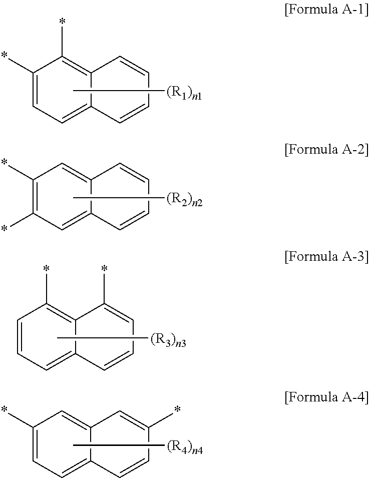
wherein in [Formula A-1] to [Formula A-4],
R₁ to R₄ are the same as or different from each other, and each independently selected from the group consisting of a deuterium atom, a substituted or unsubstituted alkyl group having 1 to 30 carbon atoms, a substituted or unsubstituted alkenyl group having 2 to 30 carbon atoms, a substituted or unsubstituted cycloalkyl group having 3 to 30 carbon atoms, a substituted or unsubstituted cycloalkenyl group having 5 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 6 to 30 carbon atoms, a substituted or unsubstituted alkylamine group having 1 to 30 carbon atoms, a substituted or unsubstituted arylamine group having 6 to 30 carbon atoms, a substituted or unsubstituted aryl group having 6 to 50 carbon atoms, a substituted or unsubstituted heteroaryl group having 3 to 50 carbon atoms, a substituted or unsubstituted alkylsilyl group having 1 to 30 carbon atoms, and a substituted or unsubstituted arylsilyl group having 6 to 30 carbon atoms, and
n1 to n4 are integers of 0 to 6, but when n is 2 or more, respective R₁ to R₄ are the same as or different from each other.

3. The organic electroluminescent device of claim 1, wherein at least one of Ar and Ar₂ is selected from groups represented by [Formula Ar-1] or [Formula Ar-2] below: 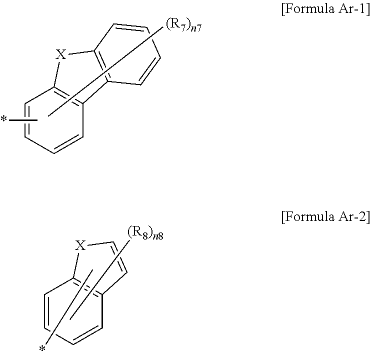
wherein in [Formula Ar-1] and [Formula Ar-2],
X is selected from the group consisting of O, S, NR′, and Si(R′)₂,
R₇, R₈, and R′ are the same as or different from each other, and each independently selected from the group consisting of a hydrogen atom, a deuterium atom, a substituted or unsubstituted alkyl group having 1 to 30 carbon atoms, a substituted or unsubstituted alkenyl group having 2 to 30 carbon atoms, a substituted or unsubstituted cycloalkyl group having 3 to 30 carbon atoms, a substituted or unsubstituted cycloalkenyl group having 5 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 6 to 30 carbon atoms, a substituted or unsubstituted alkylamine group having 1 to 30 carbon atoms, a substituted or unsubstituted arylamine group having 6 to 30 carbon atoms, a substituted or unsubstituted aryl group having 6 to 50 carbon atoms, a substituted or unsubstituted heteroaryl group having 3 to 50 carbon atoms, a substituted or unsubstituted alkylsilyl group having 1 to 30 carbon atoms, and a substituted or unsubstituted arylsilyl group having 6 to 30 carbon atoms,
n7 is an integer of 0 to 7, and n8 is an integer of 0 to 5, but when n7 and n8 are 2 or more, respective R₇ and R₈ are the same as or different from each other.

4. The organic electroluminescent device of claim 1, wherein L₁ and L₂ each independently are a substituted or unsubstituted phenylene group.

5. The organic electroluminescent device of claim 1, wherein the compound represented by [Formula A] is substituted with at least one deuterium.

6. The organic electroluminescent device of claim 5, wherein the compound represented by [Formula A] has a degree of deuteration of 30% or more.

7. The organic electroluminescent device of claim 1, wherein the compound represented by [Formula A] has a molecular weight of 650 or more.

8. The organic electroluminescent device of claim 1, wherein the solvent comprises at least one of a chlorine-based solvent, an ether-based solvent, an aromatic solvent, an aliphatic solvent, a ketone-based solvent, an ester-based solvent, an alcohol-based solvent, an amide-based solvent, and a benzoate-based solvent.

9. The organic electroluminescent device of claim 1, wherein the host is dissolved in an amount of 1% by weight or more in the solvent.

10. The organic electroluminescent device of claim 1, wherein the host is represented by any one of [1] to [36] below:

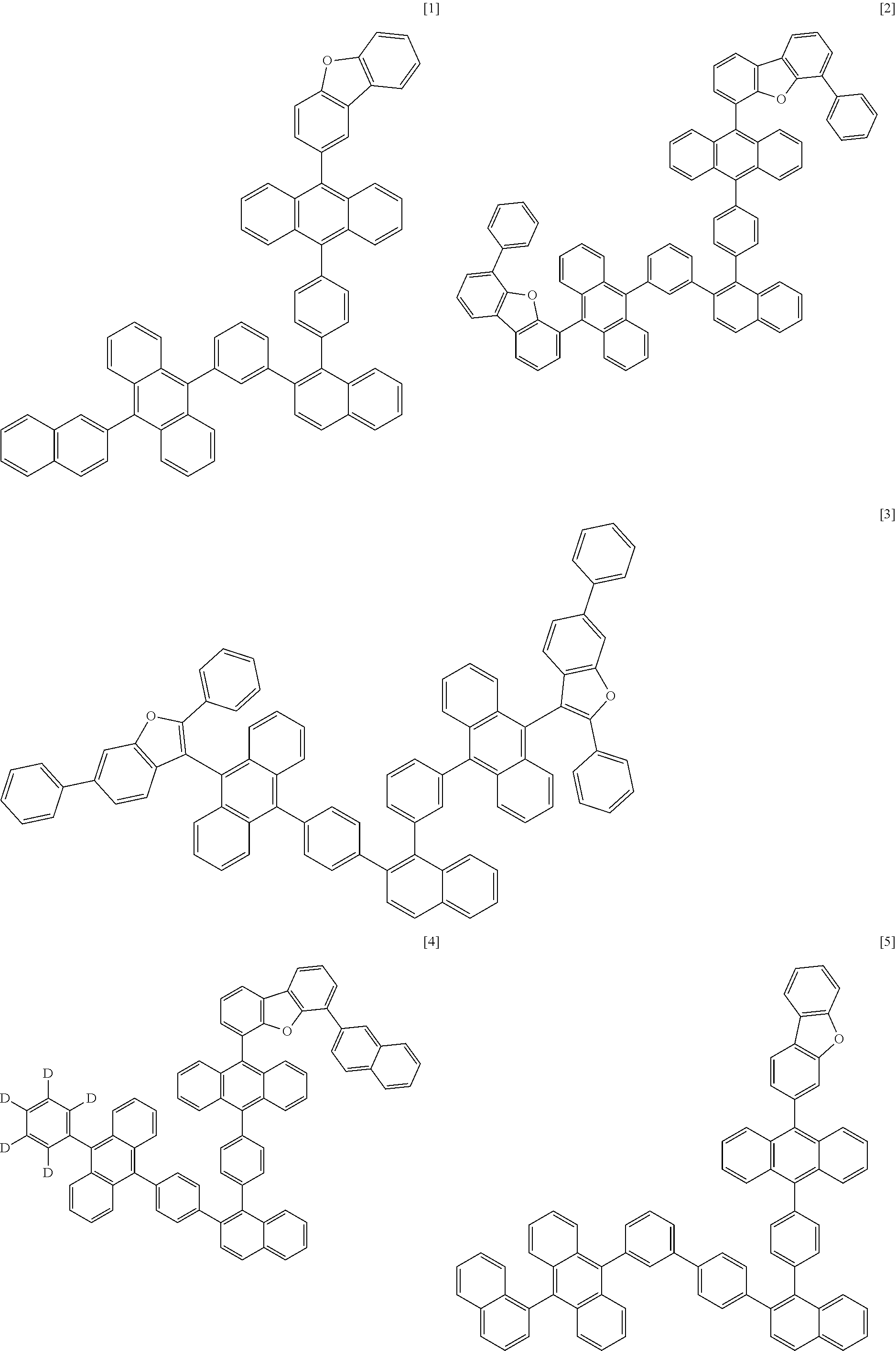

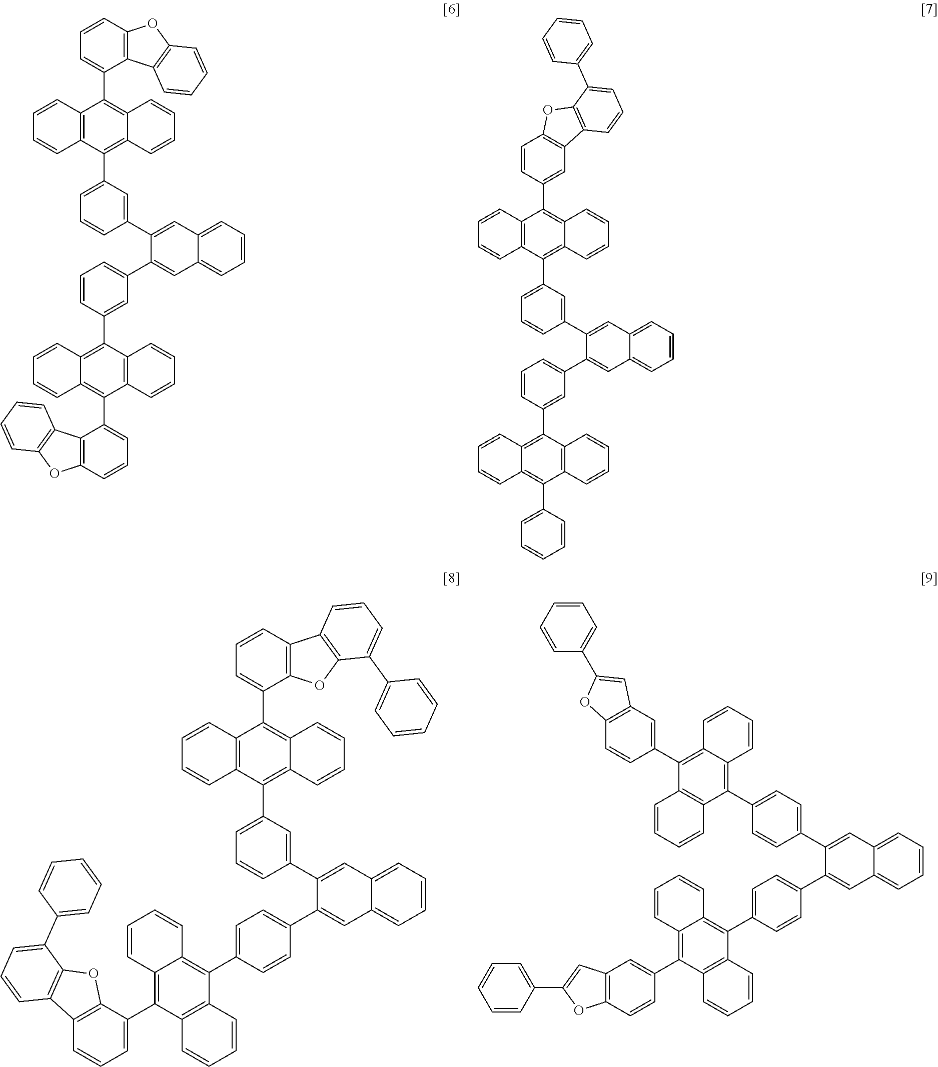

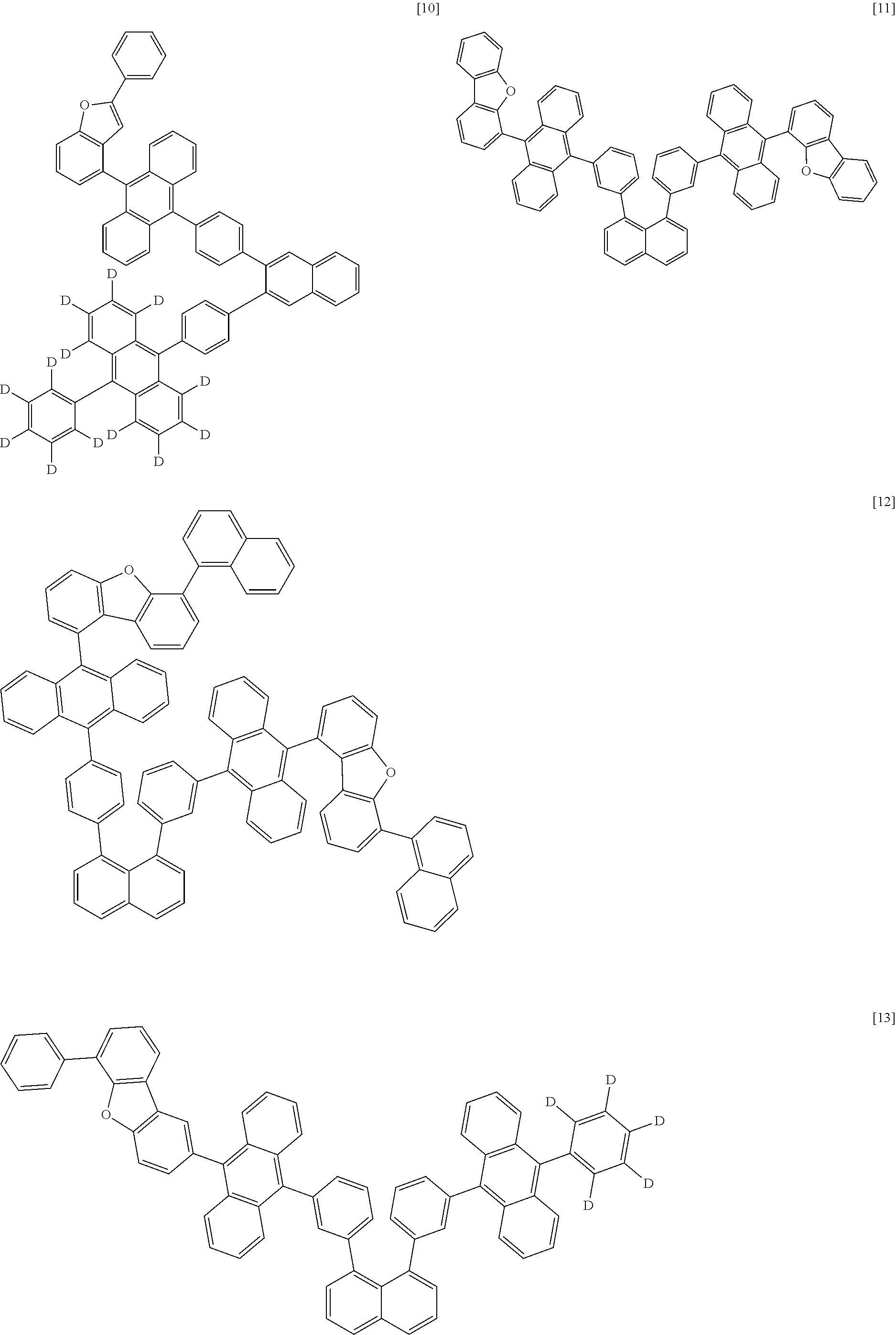

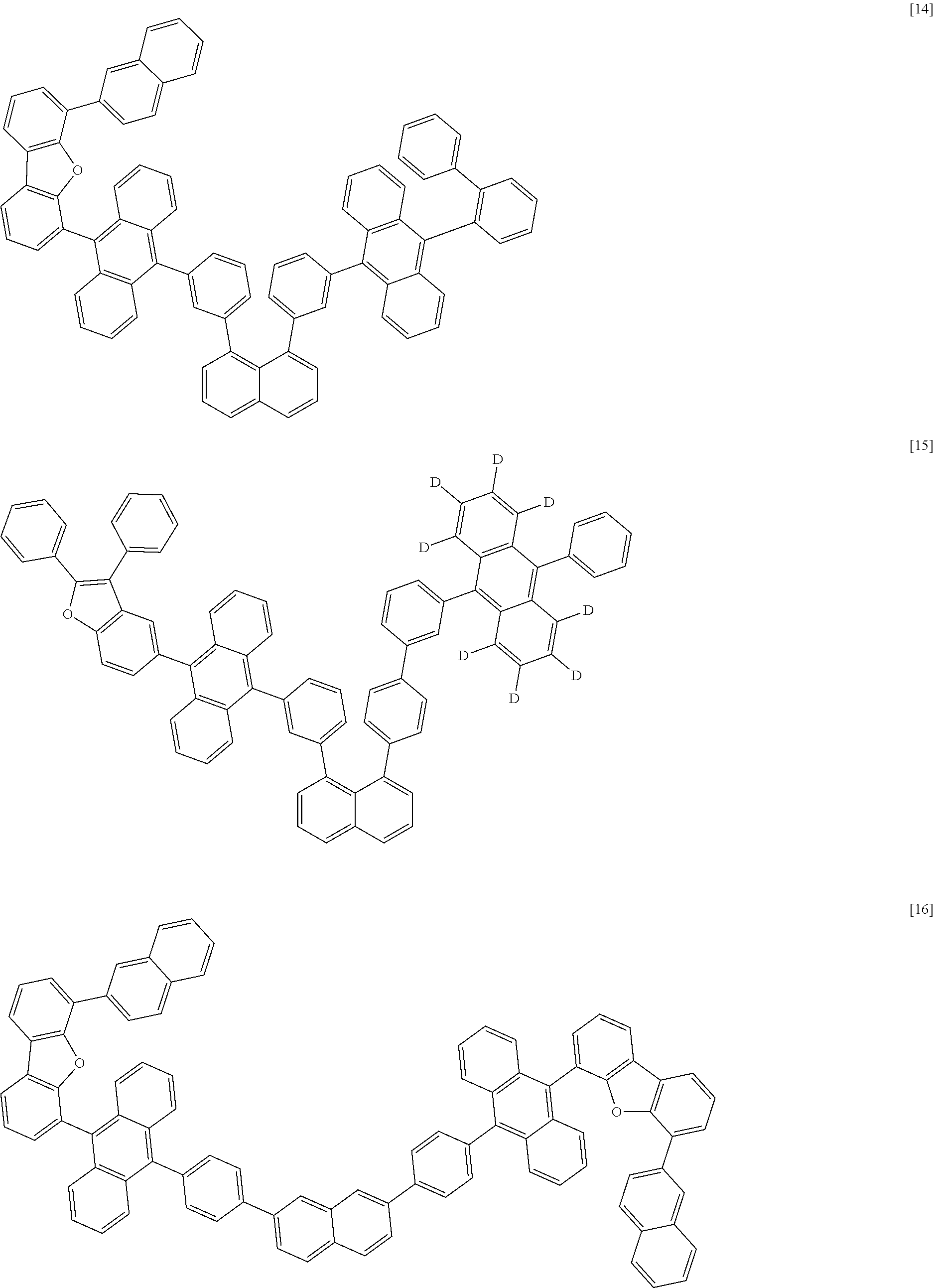

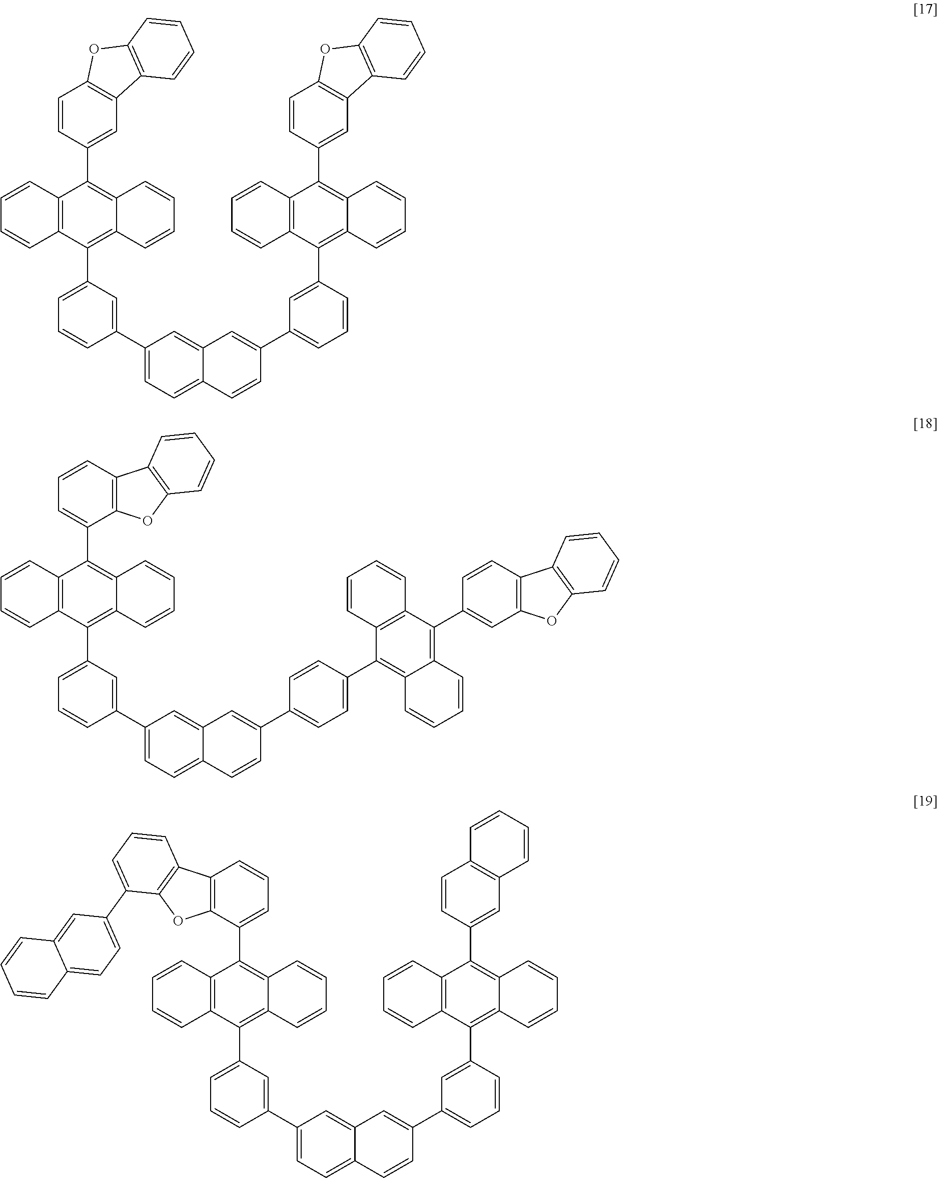

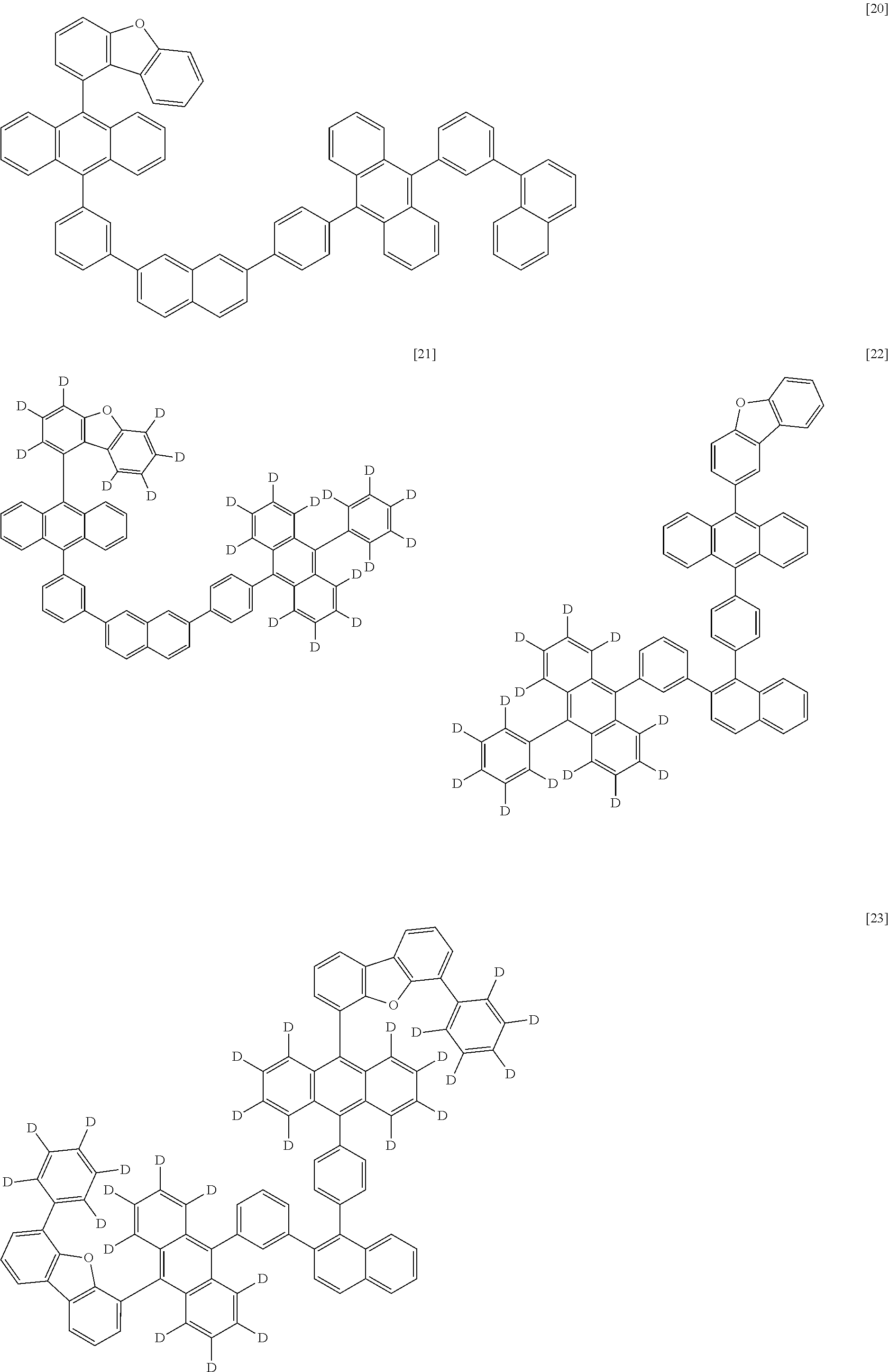

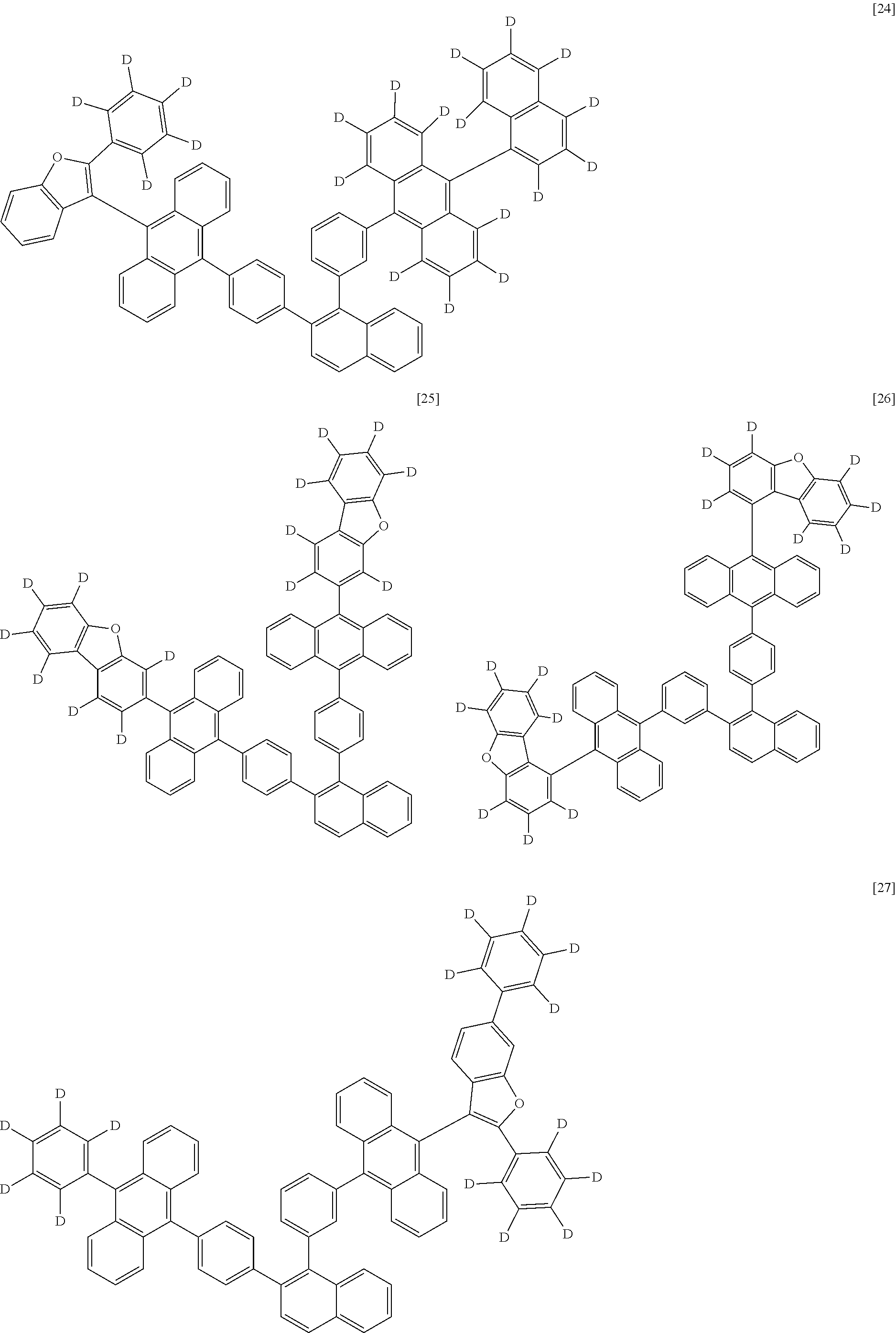

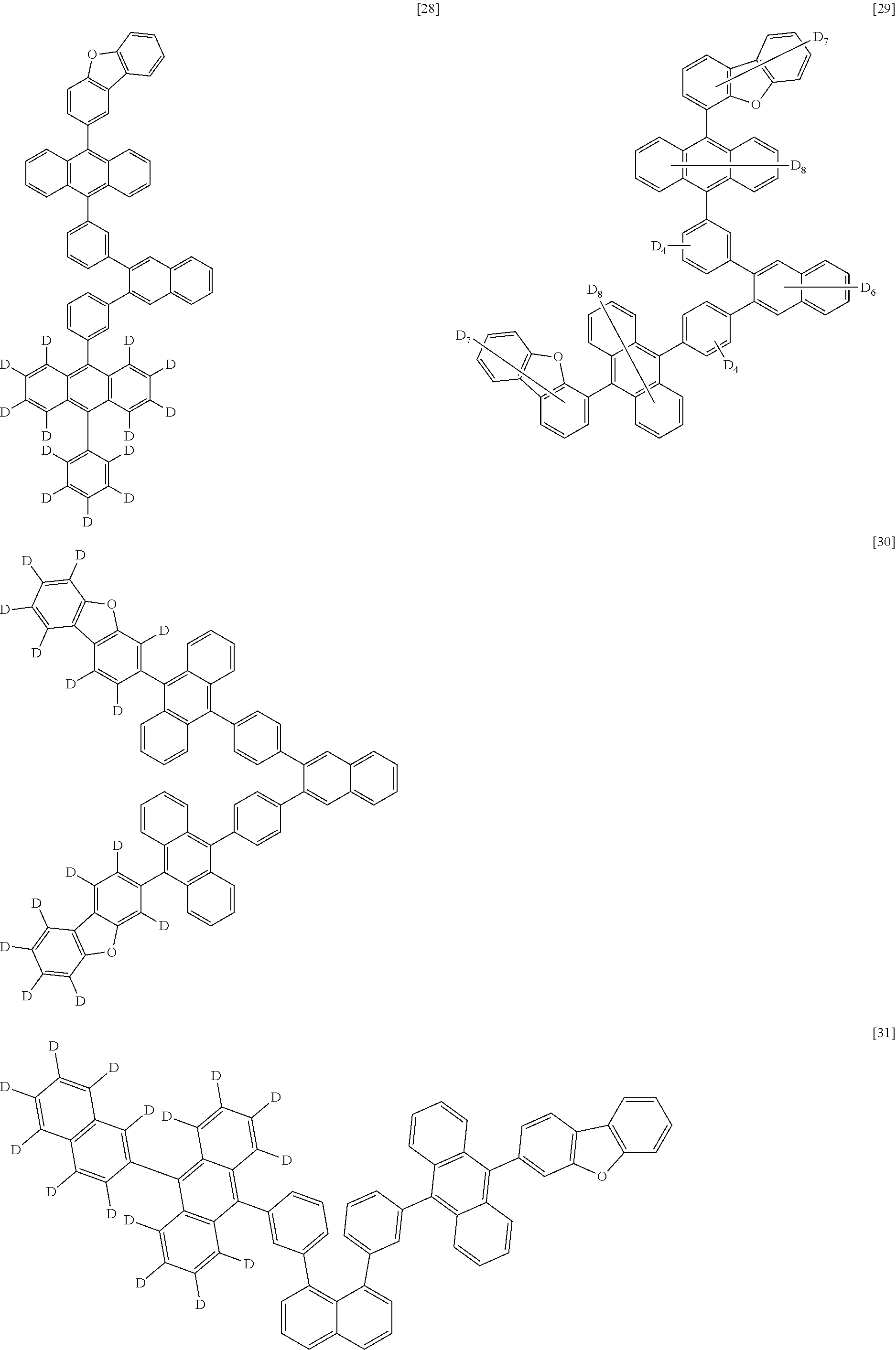

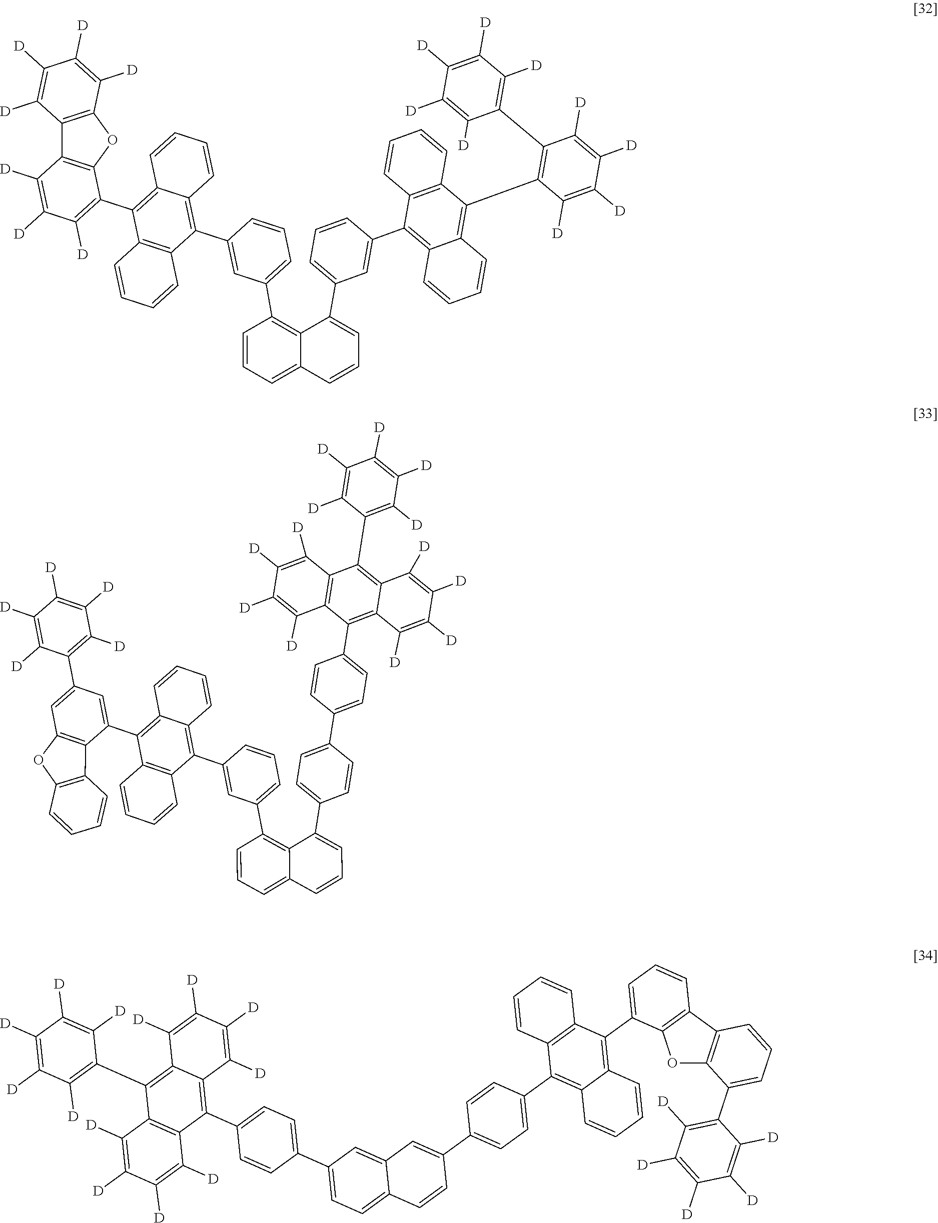

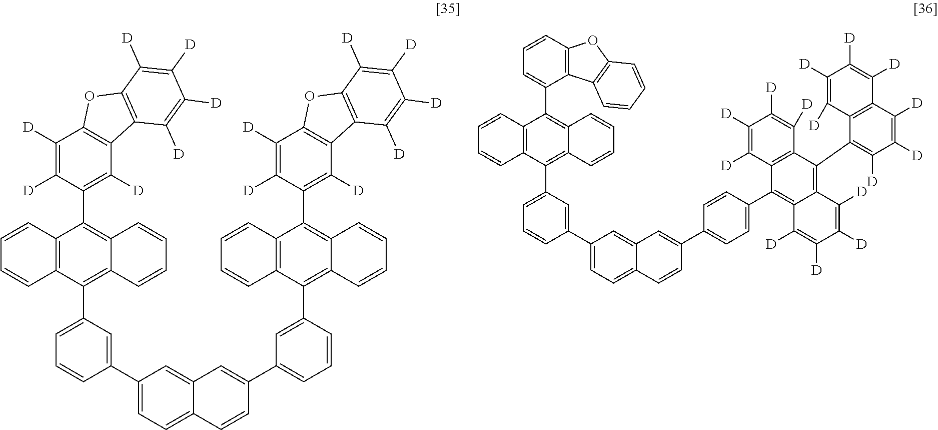 [SMILES: [2H]c1c([2H])c([2H])c2c(oc3c([2H])c([2H])c(-c4c5ccccc5c(-c5cccc(-c6ccc7ccc(-c8cccc(-c9c%10ccccc%10c(-c%10c([2H])c([2H])c%11oc%12c([2H])c([2H])c([2H])c([2H])c%12c%11c%10[2H])c%10ccccc9%10)c8)cc7c6)c5)c5ccccc45)c([2H])c32)c1[2H] ; [2H]c1c([2H])c([2H])c2c(-c3c4c([2H])c([2H])c([2H])c([2H])c4c(-c4ccc(-c5ccc6ccc(-c7cccc(-c8c9ccccc9c(-c9cccc%10oc%11ccccc%11c9%10)c9ccccc89)c7)cc6c5)cc4)c4c([2H])c([2H])c([2H])c([2H])c34)c([2H])c([2H])c([2H])c2c1[2H]]

11. The organic electroluminescent device of claim 1, wherein the dopant is a boron-based compound represented by [Formula B-1] or [Formula B-2] below: 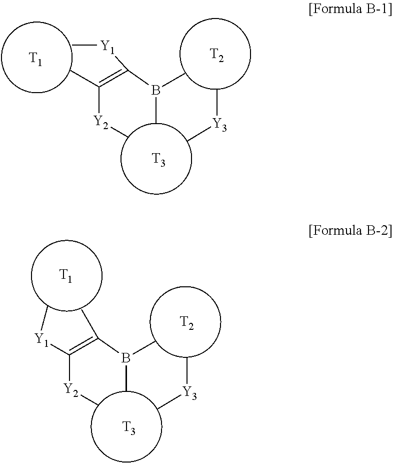
wherein in [Formula B-1] and [Formula B-2],
T₁ to T₃ above are respectively the same as or different from each other and are each independently a substituted or unsubstituted aromatic ring having 6 to 50 carbon atoms, or a substituted or unsubstituted aromatic heterocycle having 2 to 40 carbon atoms,
Y₁ is any one selected from N—R₁₁, CR₁₂R₁₃, O, S, and SiR₁₄R₁₅,
Y₂ is any one selected from N—R₁₆, CR₁₇R₁₈, O, S, and SiR₁₉R₂₀,
Y₃ is any one selected from N—R₂₁, CR₂₂R₂₃, O, S, and SiR₂₄R₂₅,
R₁₁ to R₂₅ above are respectively the same as or different from each other, and are each independently any one selected from hydrogen, deuterium, a substituted or unsubstituted alkyl group having 1 to 30 carbon atoms, a substituted or unsubstituted aryl group having 6 to 50 carbon atoms, a substituted or unsubstituted cycloalkyl group having 3 to 30 carbon atoms, a substituted or unsubstituted heteroaryl group having 2 to 50 carbon atoms, a substituted or unsubstituted alkoxy group having 1 to 30 carbon atoms, a substituted or unsubstituted aryloxy group having 6 to 30 carbon atoms, a substituted or unsubstituted alkylthioxy group having 1 to 30 carbon atoms, a substituted or unsubstituted arylthioxy group having 5 to 30 carbon atoms, a substituted or unsubstituted alkylamine group having 1 to 30 carbon atoms, a substituted or unsubstituted arylamine group having 5 to 30 carbon atoms, a substituted or unsubstituted alkylsilyl group having 1 to 30 carbon atoms, a substituted or unsubstituted arylsilyl group having 5 to 30 carbon atoms, a cyano group, and a halogen group, and R₁ to R₂₅ above are each combined with one or more rings selected from T1 to T3 above to additionally form an alicyclic or aromatic mono- or polycyclic ring.

12. The organic electroluminescent device of claim 1, wherein the organic layer comprises at least one of a hole injection layer, a hole transport layer, a functional layer having both a hole injection function and a hole transport function at the same time, an electron transport layer, and an electron injection layer in addition to a light emitting layer.

13. The organic electroluminescent device of claim 1, wherein the organic layer is formed by any one of a spin coating method, a dip coating method, a doctor blade coating method, a spray coating method, a roll coating method, inkjet printing, and screen printing.
